(19) United States
(12) Patent Application Publication
(10) Pub. No.: US 2023/0340269 A1
(43) Pub. Date: Oct. 26, 2023

(54) NEAR-INFRARED ABSORBING COMPOSITION, NEAR-INFRARED ABSORBING FILM, NEARINFRARED ABSORBING FILTER AND IMAGE SENSOR FOR SOLID-STATE IMAGING ELEMENTS

(71) Applicant: Konica Minolta, Inc., Tokyo (JP)

(72) Inventors: Koji DAIFUKU, Fukuroi-shi, Shizuoka (JP); Natsumi KIRIISHI, Hino-shi, Tokyo (JP); Takayuki SUZUKI, Kokubunji-shi, Tokyo (JP); Kiyoshi FUKUSAKA, Fussa-shi, Tokyo (JP)

(21) Appl. No.: 18/247,844

(22) PCT Filed: Sep. 16, 2021
(86) PCT No.: PCT/JP2021/034110

§ 371 Date: Apr. 4, 2023

(30) Foreign Application Priority Data
Oct. 9, 2020 (JP) 2020-170838

(51) Int. Cl. C09B 23/08; G02B 5/20; C09B 23/01; C09B 23/14; C07F 9/42; C07F 9/38

(52) U.S. Cl. CPC C09B 23/083; G02B 5/208; C09B 23/0066; C09B 23/0075; C09B 23/146; C07F 9/42; C07F 9/3826; C07F 9/3834; H01L 27/14623

(57) ABSTRACT

A near-infrared absorbing composition includes: an organic dye; and a metal compound. The organic dye includes: at least one of a squarylium dye (A) or a cyanine dye (B) each having an absorption maximum in a range of 680 to 740 nm; and a cyanine dye (C) having an absorption maximum at 760 nm or higher. The metal compound includes at least a phosphonic acid and a copper ion, or a copper phosphonate complex formed from a phosphonic acid and a copper ion.

### TECHNICAL FIELD

The present invention relates to a near-infrared absorbing composition, and a near-infrared-absorbing film, a near-infrared-absorbing filter, and an image sensor for a solid-state imaging element using the same. Mom specifically, the present invention relates to a near infrared absorbing composition having both transmittance in a visible range and absorbance in a near infrared range, excellent heat resistance over time, and excellent light resistance.

### BACKGROUND ART

CCD or CMOS image sensors, which are solid-state imaging elements for color images, are used in video cameras, digital still cameras, mobile phones with a camera function, and the like. In such solid-state imaging elements, a silicon photodiode having sensitivity to light in a near-infrared wavelength region is used in a light-receiving portion thereof. Therefore, it is necessary to perform luminosity correction, and a near infrared absorbing filter is used for this reason.

Further weight reduction is required for portable devices, and weight reduction is also required for near-infrared absorbing filters.

In recent years, near-infrared absorption filters in which a dye or a metal compound is added to a resin and which are lightweight and readily produced and processed, have attracted attention and are being developed.

With respect to such dyes, Patent Documents 1 and 2 disclose techniques using a squarylium dye and a cyanine dye.

The squarylium dyes used in Patent Document 1 have a triple fused ring structure and show a steep absorption peak in a region of 630 to 700 nm. Therefore, the squarylium dyes exhibit absorptivity in a specific range within the near-infrared region while maintaining transmittance in the visible light region.

Patent Document 2 discloses an optical filter using a squarylium-based compound having an absorption maximum in a specific range and a cyanine-based compound having an absorption maximum in a wavelength region longer than the specific range and less than 760 nm. Squarylium-based compounds generally have fluorescence emission properties due to the molecular structure, but the generation of fluorescence can be suppressed when they are used in combination with cyanine-based compounds having a specific structure.

However, although the near-infrared absorption filters based on these techniques have good spectral absorption waveform but have low light absorption at the wavelength of 850 nm or more. This requires a combination with a technique such as blue plate glasses or dielectric laminated films, and the light resistance and heat resistance of the filters are not satisfactory.

On the other hand, optical materials using specific absorption characteristics of copper ions have been studied. Patent Document 3 discloses a technique of improving processability, more specifically, chemical stability in thermoforming while maintaining absorption characteristics by using a phosphonic acid and copper ions. However, near-infrared absorbing filters based on this technique have high light absorption at the wavelength of 800 nm or mom, but suffer from low absorption performance for near-infrared light having a shorter wavelength.

In this regard, Patent Document 4 discloses an infrared cut filter composed of two absorption layers of an organic dye-containing layer and a copper phosphonate-containing layer. However, them are few specific examples of organic dyes, and the spectral absorption waveforms described in the examples reveals low transmittance for visible light of 500 nm or less. Therefore, them is room for further improvement.

### CITATION LIST

### Patent Literature

[Patent Document 1]: Japanese Patent No. 6183041

[Patent Document 2]: Japanese Patent No. 6331392

[Patent Document 3]: Japanese Patent No. 4684393

[Patent Document 4]: Japanese Patent No. 6281023

### SUMMARY OF INVENTION

### Technical Problem

The present invention has been made in consideration of the above-described problems and situations, and an object thereof is to provide a near-infrared absorbing composition that has both transmittance in the visible light region and absorptivity in the near-infrared region and has excellent heat resistance over time and furthermore has excellent light resistance. Another object is to provide a near-infrared absorbing film, a near-infrared absorbing filter, and an image sensor for a solid-state imaging element using the same.

### Solution to Problem

In order to solve the above-described problems, the present inventors conducted various studies on the factors causing the above-described problems from the viewpoint of the transmittance in the visible light region, the absorption in the near-infrared region, and the like. As a result, they found that the problem can be solved by using a near-infrared absorbing composition that contains a squarylium compound or cyanine compound having a specific structure, and furthermore contains at least a combination of a phosphonic acid and a copper ion, or a copper phosphonate complex formed from a phosphonic acid and a copper ion. The present invention has been thus completed.

That is, the aforementioned problem relating to the present invention is solved by the following means.

1. A near-infrared absorbing composition containing an organic dye; a metal compound, characterized by containing:
at least one of a squarylium dye (A) or a cyanine dye (B) each having an absorption maximum in a range of 680 to 740 nm, and
a cyanine dye (C) having an absorption maximum at 760 nm or higher, wherein
the squarylium dye (A) is a compound having a structure represented by any one of General Formulae (A1) to (A4) (respectively, a dye A1, a dye A2, a dye A3, and a dye A4),
the cyanine dye (B) is a compound having a structure represented by the following General Formula (B1) (a dye B1),
the cyanine dye (C) is a compound having a structure represented by any one of General Formulae (C1) and (C2) (a dye C1 and a dye C2, respectively), and
the near-infrared absorbing composition further contains at least a phosphonic acid and a copper ion, or a copper phosphonate complex formed from a phosphonic acid and a copper ion.

Squarylium Dye (A)

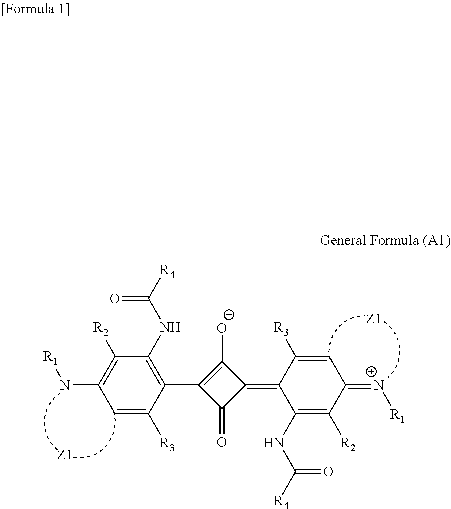

In the formula, R₁ represents an alkyl, aryl, or heterocyclic group. R₂ and R₃ each independently represent a hydrogen atom, a halogen atom, or an alkyl group. R₄ represents an alkyl, alkoxy, aryl or heterocyclic group having 1 to 4 carbon atoms. Z1 represents an atomic group necessary for forming a 5- or 6-membered ring.

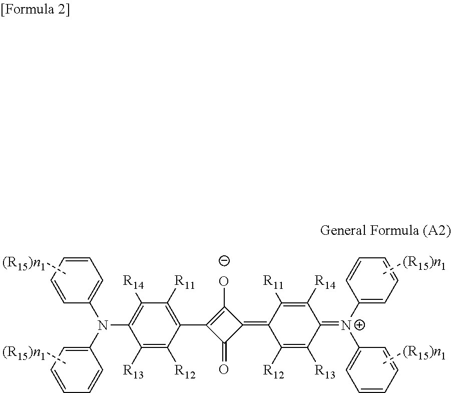

In the formula, R₁₁ and R₁₂ each independently represent a hydrogen atom, a hydroxy group, —NHCOR₁₆, or —NHSO₂R₁₇, and are not hydrogen atoms at the same time. R₁₃ and R₁₄ each independently represent a hydrogen atom, a halogen atom, or an alkyl group. R₁₅ represents a substituent. N, represents an integer of 0 to 5. R₁₆ and R₁₇ each independently represent an alkyl, aryl, or heterocyclic group having 1 to 4 carbon atoms.

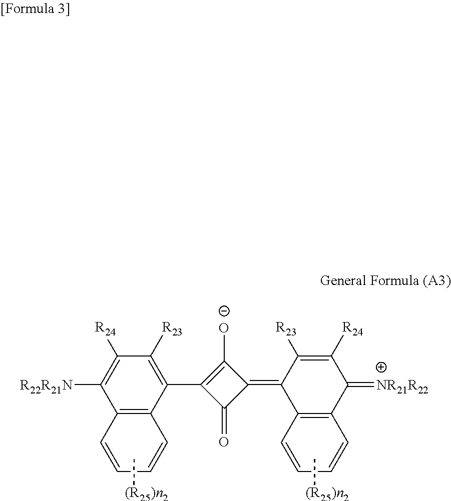

R₂₁ and R₂₂ each independently represent a hydrogen atom, an alkyl group, an aryl group, or a heterocyclic group. R₂₃ each independently represents a hydroxy group, —NHCOR₆, or —NHSO₂R₂₇. R₂₄ each independently represents a hydrogen atom or a substituent. R₂₅ each independently represents a substituent. n₂ represents an integer of 0 to 4. R₂₆ and R₂₇ each independently represent an alkyl, aryl, or heterocyclic group having 1 to 4 carbon atoms.

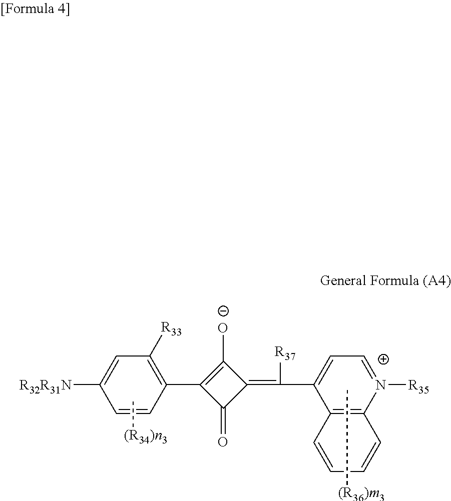

R₃₁ and R₃₂ each independently represent a hydrogen atom, an alkyl group, an aryl group, or a heterocyclic group. R₃₃ represents a hydroxy group, —NHCOR₃₈ or —NHSO₂R₃₉. R₃₄ and R₃₆ each independently represent a halogen atom or a substituent. R₃₅ represents an alkyl, aryl or heterocyclic group. n₃ represents an integer of 0 to 3. m₃ represents an integer of 0 to 6. R₃₇ represents a hydrogen atom, a halogen atom, or an alkyl group. R₃₈ and R₃, each independently represent an alkyl, aryl, or heterocyclic group having 1 to 4 carbon atoms.

Cyanine Dye (B)

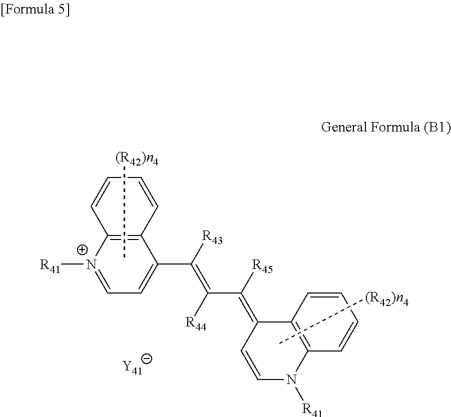

In the formula, R₄₁ each independently represents an alkyl, aryl, or heterocyclic group. R₄₂ each independently represents a halogen atom or a substituent. R₄₃ to R₄₅ each independently represent a hydrogen atom, a halogen atom, an alkyl group, or an aryl group. n₄ each independently represents an integer of 0 to 6. Y₄₁ represents a halogen ion or an anionic atomic group.

Cyanine Dye (C)

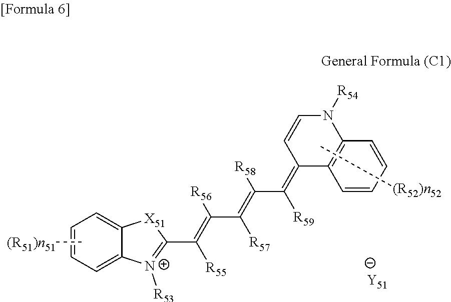

In the formula, R₅₁ and R₅₂ each independently represent a halogen atom or a substituent, and adjacent substituents may form a 5- or 6-membered ring. n₅₁ and n₅₂ each represent an integer of 0 to 4 and 0 to 5, respectively. R₅₃ and R₅₄ each independently represent an alkyl, aryl, or heterocyclic group. R₅₅ to R₅₉ each independently represent a hydrogen atom, a halogen atom, an alkyl group, an aryl groups, or a heterocyclic group. R₅₅ and R₅₇, R₅₆ and R₅₈ or R₅₇ and R₅₉ may be bound to each other form a 5- or 6-membered ring. X₅₁ represents —S— or —CR₅₁₁R₅₁₂. Y₅₁ represents an anionic atom or an anionic atomic group. R₅₁₁ and R₅₁₂ each independently represent a hydrogen atom, an alkyl group, or an aryl group.

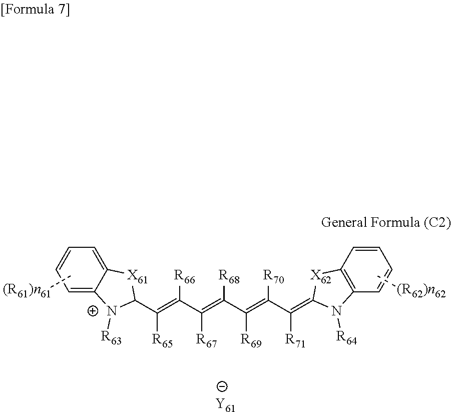

In the formula, R₆₁ and R₆₂ each independently represent a halogen atom or a substituent, and adjacent substituents may form a 5- or 6-membered ring. n₆₁ and n₆₂ each independently represent an integer of 0 to 4. R₆₃ and R₆₄ each independently represent a hydrogen atom, an alkyl group, an aryl group, or a heterocyclic group. R₆₅ to R₇₁ each independently represent a hydrogen atom, a halogen atom, an alkyl group, an aryl group, or a heterocyclic group. R₆₅ and R₆₇, R₆₆ and R₆₈, R₆₇ and R₆₉, R₆₈ and R₇₀, or R₆₉ and R₇₁ may be bonded to each other to form a 5- or 6-membered ring. X₆₁ and X₆₂ each independently represent —O—, —S—, or —CR₆₁₁R₆₁₂—. Y₆₁ represents an anionic atom or an anionic atomic group. R₆₁₁ and R₆₁₂ each independently represent a hydrogen atom or an alkyl group.

2. The near-infrared absorbing composition according to item 1, wherein the organic dye includes at least a combination of the dye A1 and the dye C2 or a combination of the dye A4 and the dye C2.

3. The near-infrared absorbing composition according to item 1, wherein the organic dye includes at least a combination of the dye B1 and the dye C2.

4. The near-infrared absorbing composition according to any one of items 1 to 3, wherein the phosphonic acid is an alkylphosphonic acid; and
the near-infrared absorbing composition further comprises a compound having a structure represented by the following General Formula (I) and a copper ion, or a copper complex formed from the compound having the structure represented by the following General Formula (I) and a copper ion.

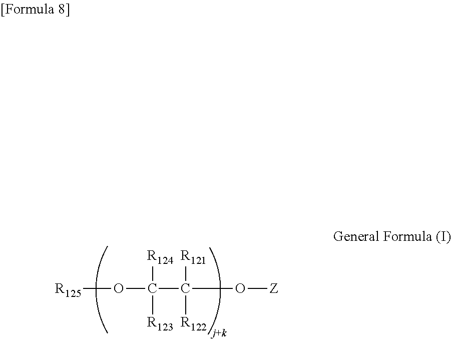

In the General Formula (I), R₁₂₅ represents an alkyl group having 1 to 20 carbon atoms or an aryl group having 6 to 20 carbon atoms. R₁₂₅ may further have a substituent. Z represents a structural unit selected from the following Formulae Z-1 and (Z-2).

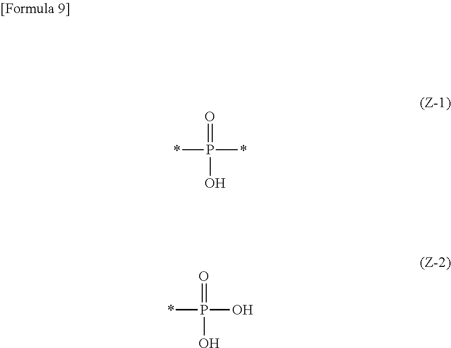

“*” in the Formulae (Z-1) and (Z-2) represents a binding site, which binds to O of General Formula (I).

R₁₂₁ to R₁₂₄ each independently represent a hydrogen atom or an alkyl group having 1 to 4 carbon atoms.

Provided that the compound having the structure represented by General Formula (I) simultaneously has at least one moiety satisfying the following Condition (i) and at least one moiety satisfying the following Condition (ii).

Condition (i): all of R₁₂₁ to R₁₂₄ are hydrogen atoms.

Condition (ii): at least one of R₁₂₁ to R₁₂₄ is an alkyl group having 1 to 4 carbon atoms.

In the above General Formula (I), j represents the number of moieties satisfying the above Condition (i), which is a number from 1 to 10. K represents the number of partial structures satisfying the above condition (ii), and is a number from 1 to 10.

5. The near-infrared absorbing composition according to any one of items 1 to 4, further comprising: a compound having a structure represented by the following General Formula (D1).

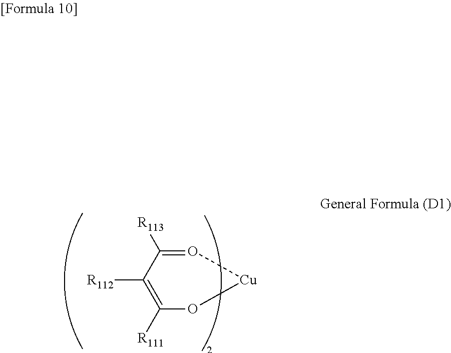

In the formula, R₁₁₁ and R₁₁₃ each independently represent an alkyl, alkoxy, amino, aryl, or heterocyclic group. R₁₁₂ represents a hydrogen or halogen atom, or an alkyl, aryl, heterocyclic, carbonyl or cyano group, each of which may have a substituent.

6. A near-infrared absorbing film comprising the near-infrared absorbing composition according to any one of items 1 to 5.

7. A near-infrared absorbing film, comprising:
an organic dye-containing layer containing an organic dye; and
a copper phosphonate-containing layer containing a phosphonic acid and a copper ion, or a copper phosphonate complex formed from a phosphonic acid and a copper ion, wherein
the organic dye includes:
   at least one of a squarylium dye (A) and a cyanine dye (B) each having a maximum absorption wavelength in a range of 680 to 740 nm, and
   a cyanine dye (C) having an absorption maximum wavelength at 760 nm or more.
8. A near-infrared absorbing film, comprising: a near-infrared absorbing film according to item 6 or 7, wherein
the near-infrared absorbing film has a film thickness within a range of 30 to 120 μm, and
a light transmittance that satisfies all of the following Conditions (1) to (4):
   (1) an average light transmittance within a wavelength range of 450 nm or more and 600 nm or less being 85% or more;
   (2) an average light transmittance withing a wavelength range of 700 nm or more and less than 1000 nm being less than 2%;
   (3) an average light transmittance within a wavelength range of 1000 nm or more and 1200 nm or less being less than 5%; and
   (4) a cutoff wavelength at which a light transmittance is 50% in a wavelength range of 600 to 700 nm being within a range of 620 to 660 nm.

9. An image sensor for a solid-state imaging element, comprising a near-infrared absorbing filter according to item 8.

### Advantageous Effects Invention

According to the present invention, it is possible to provide a near-infrared absorbing composition that has both transmittance in the visible light region and absorptivity in the near-infrared region and has excellent heat resistance over time and furthermore has excellent light resistance. Further, it is possible to provide a near-infrared absorbing film, a near-infrared absorbing filter, and an image sensor for a solid-state imaging element using the composition.

The mechanism of how the advantageous effects of the present invention is expressed or work has not been revealed yet, but is assumed as follows.

The near-infrared absorbing composition of the present invention is characterized by containing at least one of the squarylium dye (A) and the cyanine dye (B) each having a maximum absorption wavelength in the range of 680 to 740 nm, containing the cyanine dye (C) having a maximum absorption wavelength of 760 nm or more, and further containing at least a phosphonic acid and a copper ion, or a copper phosphonate complex formed from a phosphonic acid and a copper ion.

The squarylium dye (A) and the cyanine dye (B) having a maximum absorption wavelength in the range of 680 to 740 nm, which are used in the present invention, do not have side absorption in the visible light region, and can therefore improve the transmittance. In addition, when the above-described dyes are used in combination with the cyanine dye (C) having an absorption maximum wavelength of 760 nm or more, the absorption in the near-infrared region is improved.

A squarylium dye generally has fluorescence emission properties due to its molecular structure. However, the use of a squarylium dye and a cyanine dye having specific structures in combination can reduce the fluorescence. Any of these dyes has excellent heat resistance since they have an uncomplicated three-dimensional structure few steric hindrance.

A copper ion forms a copper ion complex with a phosphonic acid to exhibit excellent transmittance in the visible light region and excellent absorption in the near-infrared region. A phosphonic acid has high stability to heat, and the near-infrared absorbing composition of the present invention containing a phosphonic acid similarly has high stability to heat.

Examples of the combination of organic dyes include at least a combination of dye A1 and dye C2, a combination of dye A4 and dye C2, or a combination of dye B1 and dye C2. These combinations can further reduce the average light transmittance in the near-infrared region.

The squarylium dye used in the near-infrared absorbing composition of the present invention has fluorescence emission properties, and there is room for improvement in the light resistance. However, it is conceivable that the copper compound having the structure represented by General Formula (D1) can quench the fluorescence emitted by the squarylium dye due to a heavy atom effect (an effect of a copper atom). That is, the copper compound promotes non-radiative deactivation of the squarylium dye from an excited state to a ground state. This can prevent deterioration of the squarylium dye itself and surrounding dyes due to photoexcitation and improve the light resistance.

The compound formed from a phosphonic acid and a copper ion, which is used in the near-infrared absorbing composition of the present invention, is easily aggregated, and there is room for improvement in the dispersibility. However, the use of an alkylphosphonic acid as the phosphonic acid and inclusion of the compound having the structure represented by General Formula (I) can impart the dispersion stability.

### BRIEF DESCRIPTION OF DRAWINGS

FIG. 1 This is a cross-sectional view showing an example of a near-infrared absorbing film having a two-layer configuration.

FIG. 2 This is a cross-sectional view showing an example of a near-infrared absorbing filter composed of a near-infrared absorbing film having a two-layer configuration.

FIG. 3 This is a schematic cross-sectional view showing an example of the configuration of a camera module including a solid-state imaging element with the near-infrared absorbing filter of the present invention.

### DESCRIPTION OF EMBODIMENTS

The near-infrared absorbing composition of the present invention, which contains an organic dye and a metallic compound, is characterized by containing at least one of a squarylium dye (A) and a cyanine dye (B) each having a maximum absorption wavelength in the range of 680 to 740 nm, containing a cyanine dye (C) having a maximum absorption wavelength of 760 nm or more, wherein the squarylium dye (A) is a compound having the structure represented by any of the following General Formulae (A1) to (A4), the cyanine dye (B) is a compound having the structure represented by the following general formula (B1), and the cyanine dye (C) is a compound having the structure represented by the following general formula (C1) or (C2), and further containing at least a phosphonic acid and a copper ion, or a copper phosphonate complex formed from a phosphonic acid and a copper ion.

This feature is a technical feature common to or corresponding to the following embodiments.

In an embodiment of the present invention, it is preferable that the near-infrared absorbing composition contains the organic dye as at least a combination of the dye A1 and the dye C2 or a combination of the dye A4 and the dye C2 from the viewpoint of achieving the advantageous effects of the present invention.

It is also preferable that the near-infrared absorbing composition contains the organic dye as at least a combination of the dye B1 and the dye C2 from the viewpoint of achieving the advantageous effects.

It is also preferable that the near-infrared absorbing composition contains a compound having a structure represented by General Formula (D1) from the viewpoint of suppressing generation of fluorescence by a squarylium dye and improving light resistance.

It is also preferable that the phosphonic acid is an alkylphosphonic acid and that the near-infrared absorbing composition contains a compound having the structure represented by General Formula (I) and a copper ion, or a copper complex formed from a compound having the structure represented by General Formula (I) and a copper ion, from the viewpoint of the dispersion stability of the phosphonic acid, the copper ion, and the copper phosphonate complex.

Hereinafter, the present invention, components thereof, and embodiments and aspects for carrying out the present invention will be described in detail. In the present application, “to” is used to mean that the numerical values described before and after “to” are included as the lower limit value and the upper limit value.

Configuration of Near-Infrared Absorbing Composition

The near-infrared absorbing composition of the present invention is characterized by containing at least one of the squarylium dye (A) and the cyanine dye (B) each having a maximum absorption wavelengths in the range of 680 to 740 un, containing the cyanine dye (C) having a maximum absorption wavelength of 760 nm or more, and further containing at least a phosphonic acid and a copper ion, or a copper phosphonate complex formed from a phosphonic acid and a copper ion.

Hereinafter, details of the constituent materials of the near-infrared absorbing composition of the present invention will be described.

Organic Dye

The addition amount of near-infrared absorbing dye is preferably within the range of 0.01 to 0.3 mass % with respect to 100 mass % of the near-infrared absorbing agent constituting the near infrared-ray absorbing composition. The term “near-infrared absorbing agent” refers to a phosphonic acid and a copper ion, or a copper phosphonate complex formed from a phosphonic acid and a copper ion, which is contained as a component of the near-infrared absorbing composition.

When the addition amount of the near-infrared absorbing dye is 0.01 mass % or higher with respect to 100 mass % of the near infrared absorbing agent of the near infrared absorbing composition, the near-infrared absorption can be sufficiently increased. When the addition amount is 0.3 mass % or less, the visible light transmittance of the obtained near-infrared absorbing composition is not impaired.

Squarylium Dye (A)

The near-infrared absorbing composition of the present invention is characterized by containing at least one of the squarylium dye (A) and the cyanine dye (B) each having a maximum absorption wavelength in the range of 680 to 740 nm.

The squarylium dye (A) is a compound having the structure represented by any one of General Formulae (A1) to (A4), and is simply referred to as “dye A1”, “dye A2”, “dye A3”, and “dye A4” hereinafter.

The dye A1 is represented by the following General Formula (A1).

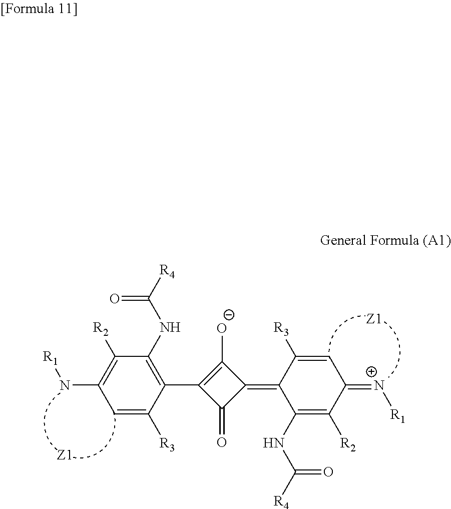

In General Formula (A1), R₁ represents an alkyl, aryl, or heterocyclic group. R₂ and R₃ each independently represent a hydrogen atom, a halogen atom, or an alkyl group. R₄ represents an alkyl, alkoxy, aryl or heterocyclic group having 1 to 4 carbon atoms. Z1 represents an atomic group necessary for forming a 5- or 6-membered ring.

In General Formula (A1), the alkyl groups represented by R₁ may be either linear or branched. Examples thereof include methyl, ethyl, propyl, i-propyl, t-butyl, pentyl, hexyl, octyl, dodecyl, tridecyl, tetradecyl, and pentadecyl. The alkyl groups represented by R₁ may further have a substituent.

In General Formula (A1), examples of aryl groups represented by R₁ include phenyl and naphthyl, which may further have a substituent.

In General Formula (A1), examples of the heterocyclic groups represented by R₁ include furyl, thienyl, pyridyl, pyridazyl, pyrimidyl, pyrazyl, triazyl, imidazolyl, pyrazolyl, thiazolyl, benzimidazolyl, benzoxazolyl, quinzolyl, phtalazyl, pyrrolidyl, imidazolidyl, morpholyl and oxazolidyl. The heterocyclic groups represented by R₁ may further have a substituent.

In General Formula (A1), R₁ is preferably an alkyl group, and more preferably an alkyl group having 1 to 4 carbon atoms.

In the General Formula (A1), examples of the substituents represented by R₂ or R₃ include alkyl groups (methyl, ethyl, propyl, i-propyl, t-butyl, pentyl, hexyl, octyl, dodecyl, tridecyl, tetradecyl, pentadecyl and the like), cycloalkyl groups (cyclopentyl, cyclohexyl and the like), alkenyl groups (vinyl, allyl and the like) and alkynyl groups (ethynyl, propagyl and the like).

Examples of the substituents represented by R₂ or R₃ include aryl groups (phenyl, naphthyl and the like) and heterocyclic groups (furyl, thienyl, pyridyl, pyridazyl, pyrimidyl, pyrazyl, triazyl, imidazolyl, pyrazolyl, thiazolyl, benzimidazolyl, benzoxazolyl, quinzolyl, phtalazyl, pyrrolidyl, imidazolidyl, morpholyl, oxazolidyl and the like).

Examples of the substituents represented by R₂ or R₃ include alkoxy groups (methoxy, ethoxy, propoxy, pentyloxy, hexyloxy, octyloxy, dodecyloxy, etc.), cycloalkoxy groups (cyclopentyloxy, cyclohexyloxy, etc.) and aryloxy groups (phenoxy, naphthyloxy, etc.).

Examples of the substituents represented by R₂ or R₃ include alkylthio groups (methylthio, ethylthio, propylthio, pentylthio, hexylthio, octylthio, dodecylthio, etc.), cycloalkylthio groups (cyclopentylthio, cyclohexylthio, etc.), and arylthio groups (phenylthio, mphthylthio, etc.).

Examples of the substituents represented by R₂ or R₃ include alkoxycarbonyl groups (methoxycarbonyl, ethoxycarbonyl, butoxycarbonyl, octyloxycarbonyl, dodecyloxycarbonyl, etc.) and aryloxycarbonyl groups (phenyloxycarbonyl, mphthyloxycarbonyl, etc.).

Examples of the substituents represented by R₂ or R₃ include sulfamoyl groups (aminosulfonyl, methylaminosulfonyl, dimethylaminosulfonyl, butylaminosulfonyl, hexylaminosulfonyl, cyclohexylaminosulfonyl, octylaminosulfonyl, dodecylaminosulfonyl, phenylaminosulfonyl, naphthylaminosulfonyl, 2-pyridylaminosulfonyl, etc.).

Examples of the substituents represented by R₂ or R₃ include acyl groups (acetyl, ethylcarbonyl, propylcarbonyl, pentylcabonyl, cyclohexylcarbonyl, octylcarbonyl, 2-ethylhexylcarbonyl, dodecylcarbonyl, phenylcarbonyl, mphthylcarbonyl, pyridylcarbonyl, etc.) and acyloxy groups (acetyloxy, ethylcarbonyloxy, butylcarbonyloxy, octylcarbonyloxy, dodecylcarbonyloxy, phenylcarbonyloxy, etc.).

Examples of the substituents represented by R₂ or R₃ include acylamino groups (methylcarbonylamino, ethylcarbonylamino, dimethylcarbonylamino, propylcarbonylamino, pentylcarbonylamino, cyclohexylcarbonylamino, 2-ethylhexylcarbonylamino, octylcarbonylamino, dodecylcarbonylamino, trifluoromethylcarbonylamino, phenylcarbonylamino, naphthylcarbonylamino, etc.) and sulfonylamino groups (methylsulfonylamino, ethylsulfonylamino, hexylsulfonylamino, decylsulfonylamino, phenylsulfonylamino, etc.).

Examples of the substituents represented by R₂ or R₃ include carbamoyl groups (aminocarbonyl, methylaminocarbonyl, dimethylaminocarbonyl, propylaminocarbonyl, pentylaminocarbonyl, cyclohexylaminocarbonyl, octylaminocarbonyl, 2-ethylhexylaminocarbonyl, dodecylaminocarbonyl, phenylaminocarbonyl, naphthylaminocarbonyl, 2-pyridylaminocarbonyl, and the like).

Examples of the substituents represented by R₂ or R₃ include ureido groups (methylureido, ethylureido, pentylureido, cyclohexylureido, octylureido, dodecylureido, phenylureido, naphthylureido, 2-pyridylaminoureido, etc.).

Examples of the substituents represented by R₂ or R₃ include sulfinyl groups (methylsulfinyl, ethylsulfinyl, butylsulfinyl, cyclohexylsulfinyl, 2-ethylhexylsulfinyl, dodecylsulfinyl, phenylsulfinyl, naphthylsulfinyl group, 2-pyridylsulfinyl group), alkylsulfonyl groups (methylsulfonyl group, ethylsulfonyl group, butylsulfonyl group, cyclohexylsulfonyl group, 2-ethylhexylsulfonyl group, dodecylsulfonyl group) and arylsulfonyl groups (phenylsulfonyl group, naphthylsulfonyl group, 2-pyridylsulfonyl group, etc.).

Examples of the substituents represented by R₂ or R₃ include amino groups (amino, ethylamino, dimethylamino, butylamino, cyclopentylamino, 2-ethylhexylamino, dodecylamino, anilino, naphthylamino, 2-pyridylamino, etc.).

Examples of the substituents represented by R₂ or R₃ include cyano, nitro, and hydroxy groups, halogen atoms (fluorine, chlorine, bromine and the like), halogenated alkyl groups (fluorinated methyl, trifluoromethyl, chloromethyl, trichloromethyl, perfluoropropyl and the like). These substituents may further have any of the above-described substituents.

Among the above-described substituents, preferred are a halogen atom, an alkyl group, an alkoxy group, an acylamino group, a sulfonylamino group, a hydroxy group, and the like. More preferred are a hydroxy group, an acylamino group and a sulfonylamino group.

R₂ and R₃ each preferably represent a hydrogen atom, a halogen atom, an alkyl group, an alkoxy group, a hydroxy group, an acylamino group and a sulfonylamino group. More preferred are a hydrogen atom, an alkyl group, a hydroxy group, an acylamino group and a sulfonylamino group. It is also preferred that R₂ and R₃ are bound to R₁ to form a 5- or 6-membered ring.

In General Formula (A1), R₄ represents an alkyl, alkoxy, aryl or heterocyclic group having 1 to 4 carbon atoms, and these represent the same substituents as those described above in the description of the substituents. Preferred is an alkyl group having 1 to 4 carbon atoms.

In the General Formula (A1), examples of the atomic groups necessary for forming a 5- or 6-membered ring represented by Z1 include combinations of —CR₅R₆—, —O—, —C(═O)—, —S— and —NR₇—. Preferred are —CR₅R₆— and —C(═O)—, and more preferred is —CR₅R₆—. It is preferred that R₅, R₆, and R₇ each independently represent a hydrogen atom, an alkyl group, an aryl group, or a heterocyclic group. More preferred are a hydrogen atom and an alkyl group. These may be further substituted with any of the above-mentioned substituents.

The dye A2 is represented by the following General Formula (A2).

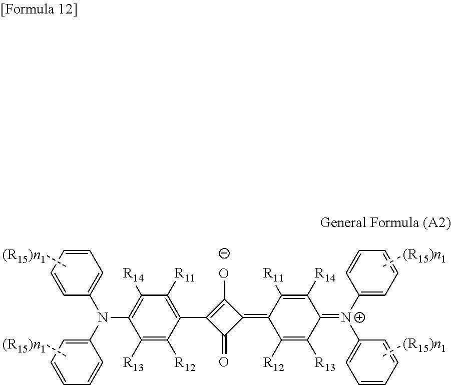

In General Formula (A2), R₁₁ and R₁₂ each independently represent a hydrogen atom, a hydroxy group, —NHCOR₁₆, or —NHSO₂R₁₇, and are not hydrogen atoms at the same time. R₁₃ and R₁₄ each independently represent a hydrogen atom, a halogen atom, or an alkyl group. R₁₅ represents a substituent. n, represents an integer of 0 to 5. R₁₆ and R₁₇ each independently represent an alkyl, aryl, or heterocyclic group having 1 to 4 carbon atoms.

In General Formula (A2), R₁₁ and R₁₂ are each preferably a hydrogen atom, a hydroxy group, or —NHCOR₁₆, and are not hydrogen atoms at the same time. R₁₁ and R₁₂ are preferably bound to the oxygen atom of squaric acid by hydrogen bonding. Most preferred is a hydroxy group.

In General Formula (A2), R₁₃ and R₁₄ each represent any of the same substituents as R₂ and R₃ in the description of General Formula (A1). Preferred examples of R₃ and R₁₄ include a hydrogen atom, halogen atoms, alkyl groups, alkoxy groups, —NHCOR₁₆, and —NHSO₂R₁₇. More preferred are a hydrogen atom, an alkyl group, and a alkoxy group. Most preferred is a hydrogen atom.

In General Formula (A2), R₁₅ represents any of the same substituents as R₂ and R₃ in the description of General Formula (A1). R₁₅ can be bound to each other to form a 5- or 6-membered ring.

Preferable examples of R₁₅ include a hydrogen atom, halogen atoms, alkyl groups, alkoxy groups, hydroxy groups, acylamino groups, and sulfonylamino groups. More preferred examples include a hydrogen atom, halogen atoms, alkyl groups and alkoxy groups.

In terms of the spectral absorption waveform, in order to suppress sub-absorption around 400 to 450 nm, it is preferable that the ortho-positions with respect to the N atom are hydrogen atoms.

In General Formula (A2), R₁₆ and R₁₇ are each preferably an alkyl group having 1 to 4 carbon atoms, which may further have a substituent.

In General Formula (A2), n₁ represents 0 to 5, preferably 0 to 2.

The dye A3 is represented by General Formula (A3) shown below.

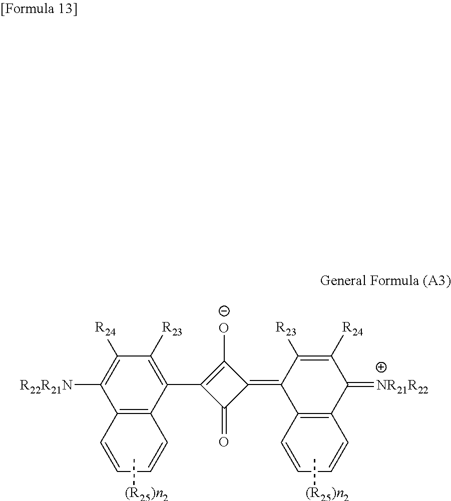

In General Formula (A3), R₂₁ and R₂₂ each independently represent a hydrogen atom, an alkyl group, an aryl group, or a heterocyclic group. R₂₃ each independently represents a hydroxy group, —NHCOR₂₆, or —NHSO₂R₂₇. R₂₄ each independently represents a hydrogen atom or a substituent. R₂₅ each independently represents a substituent. n₂ each represents an integer of 0 to 4. R₂₆ and R₂₇ each independently represent an alkyl, aryl, or heterocyclic group having 1 to 4 carbon atoms.

In General Formula (A3), preferred examples of R₂₁ and R₂₂ include alkyl groups and aryl groups, which may further have a substituent.

In General Formula (A3), R₂₃ is preferably a hydroxy group or —NHCOR₂₆, and most preferably a hydroxy group.

In General Formula (A3), R₂₄ and R₂₅ represent any of the same substituents as R₂ and R₃ in the description of General Formula (A1) that can be substituted. Preferred examples of R₁₂₄ and R₁₂₅ include a hydrogen atom, halogen atoms, alkyl groups, alkoxy groups, —NHCOR₂, and —NHSO₂R₂₇. More preferred examples include a hydrogen atom, halogen atoms, alkyl groups and alkoxy groups.

In General Formula (A3), R₂ and R₇ are each preferably an alkyl group having 1 to 4 carbon atoms, which may further have a substituent.

In General Formula (A3), n₂ represents 0 to 5, preferably 0 to 2.

The dye A4 is represented by General Formula (A4) shown below.

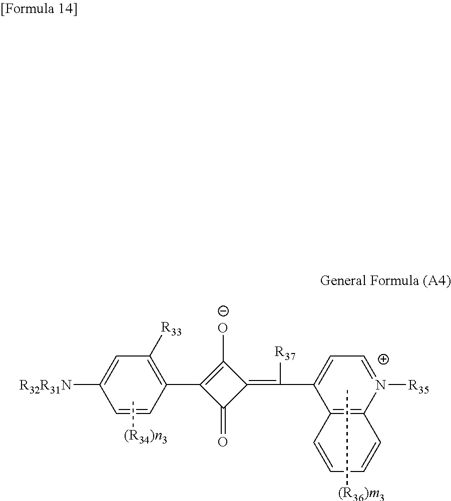

In the General Formula (A4), R₃₁ and R₃₂ each independently represent a hydrogen atom or an alkyl, aryl or heterocyclic group. R₃₃ represents a hydroxy group, —NHCOR₃₈ or —NHSO₂R₃₉. R₃₄ and R₃₆ each independently represent a halogen atom or a substituent. R₃₅ represents an alkyl, aryl or heterocyclic group. n₃ represents an integer of 0 to 3. m₃ represents an integer of 0 to 6. R₃₇ represents a hydrogen atom, a halogen atom, or an alkyl group. R₃₈ and R₃, each independently represent an alkyl, aryl, or heterocyclic group having 1 to 4 carbon atoms.

In General Formula (A4), R₃₁ and R₃₂ each represent any of the same substituents as R₂₁ and R₂₂ in the description of General Formula (A3), and the preferred are also the same.

In the General Formula (A4), R₃₃ represents any of the same substituents as the R₂ of the General Formula (A3). Preferred are a hydroxy group and —NHCOR₃₈ and most preferred is a hydroxy group.

In General Formula (A4), R₃₄ and R₃₆ each represent any of the same substituents as R₂ and R₃ in the description of General Formula (A1) that can be substituted. Preferred examples of R₃ and R₆ include a hydrogen atom, halogen atoms, alkyl groups, alkoxy groups, —NHCOR₃₈, and —NHSO₂R₃₉. More preferred examples include a hydrogen atom, halogen atoms, alkyl groups and alkoxy groups.

In the General Formula (A4), R₃₅ is preferably an alkyl group, which may further have a substituent.

It is preferable that R₃₇ represents a hydrogen atom or an alkyl group.

R₃₈ and R₃₉ are each preferably an alkyl group having 1 to 4 carbon atoms, which may further have a substituent.

n₃ and m₃ are each preferably an integer of 0 to 2.

Cyanine Dye (B)

The near-infrared absorbing composition of the present invention is characterized by containing at least one of the squarylium dye (A) and the cyanine dye (B) each having a maximum absorption wavelength in the range of 680 to 740 nm. The cyanine dye (B) is a compound having the structure represented by General Formula (B1). Hereinafter, it is simply referred to as a “dye B1”.

The dye B1 is represented by General Formula (B1) shown below.

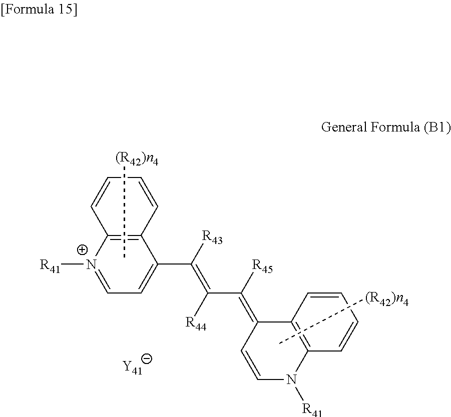

In General Formula (B1), R₄₁ each independently represents an alkyl, aryl, or heterocyclic group. R₄₂ each independently represents a halogen atom or a substituent. R₄₃ to R₄₅ each independently represent a hydrogen atom, a halogen atom, an alkyl group, or an aryl group. n₄ each independently represents an integer of 0 to 6. Y₄₁ represents a halogen ion or an anionic atomic group.

In General Formula (B1), R₄₁ is preferably an alkyl group, which may further have a substituent.

R₄₂ is not particularly limited as long as it can be substituted. R₄₂ represents any of the same substituents as R₂ and R₃ in the description of General Formula (A1). Preferred examples of R₄₂ include a hydrogen atom, halogen atoms, alkyl groups, alkoxy groups, —NHCOR₄₆, and —NHSO₂R₄₇. More preferred examples include a hydrogen atom, halogen atoms, alkyl groups and alkoxy groups.

In General Formula (B1), R₄₃ to R₄₅ each preferably represents a hydrogen atom, a halogen atom or an alkyl group. R₄₃ and R₄₅ may be bound to each other to form a ring.

R₄₆ and R₄₇ are each preferably an alkyl group having 1 to 4 carbon atoms, which may further have a substituent. nu is preferably an integer of 0 to 2.

In General Formula (B1), examples of anions represented by Y₄₁ include halogen ions and halide ions (ions of fluorides, chlorides, bromides, and iodides), enolates (acetylacetonate, hexafluoroacetylacetonate), a hydroxy ion, a sulfite ion, a sulfate ion, alkylsulfonate ions, arylsulfonate ions, a nitrate ion, a nitrite ion, a carbonate ion, a perchlorate ion, alkylcarboxylate ions, arylcarboxylate ions, tetraalkyl borates, salicylates, benzoates, PF₆⁻, BF₄⁻, and SbF₆⁻. Preferred are halogen ions, PF₆ and BF₄⁻.

Cyanine Dye (C)

The near-infrared absorbing composition of the present invention is characterized by containing the cyanine dye (C) having an absorption maximum wavelength of 760 nm or more. The cyanine dye (C) is a compound having the structure represented by any one of General Formulae (C1) and (C2). Hereinafter, these are simply referred to as “dye C1” and “dye C2”.

The dye C1 is represented by General Formula (C1) shown below.

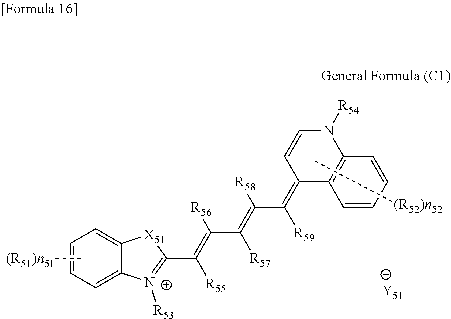

In General Formula (C1), R₅₁ and R₅₂ each independently represent a halogen atom or a substituent, and adjacent substituents may form a 5- or 6-membered ring. n₅₁ and n₅₂ represent integers of 0 to 4 and 0 to 5, respectively. R₅₃ and R₅₄ each independently represent an alkyl, aryl, or heterocyclic group. R₅₅ to R₅₉ each independently represent a hydrogen atom, a halogen atom, an alkyl group, an aryl groups, or a heterocyclic group. R₅₅ and R₅₇, R₅₆ and R₅₈, or R₅₇ and R₅₉ may be bound to each other to forma 5- or 6-membered ring. X₅₁ represents —S— or —CR₅₁₁R₅₁₂. Y₅₁ represents an anionic atom or an anionic atomic group. R₅₁₁ and R₅₁₂ each independently represent a hydrogen atom, an alkyl group, or an aryl group.

In General Formula (C1), R₅₁ and R₅₂ each represents any of are the same substituents of R₂ and R₃ in the description of General Formula (A1). Preferred are halogen atoms, alkyl groups, alkoxy groups, and aryl groups, which may further have a substituent. Adjacent substituents may be bound to each other to form a 5- or 6-membered ring, preferably a phenyl group. These substituents may further have a substituent.

n₅₁ and n₅₂ are each preferably an integer of 0 to 2.

In the General Formula (C1), R₅₃ and R₅₄ are each preferably an alkyl group, which may further have a substituent.

R₅₅ to R₅₉ are each preferably a hydrogen atom, an alkyl group, or an aryl group, and it is particularly preferable that
R₅₆ and R₅₈ are bound to each other to form a 5- or 6-membered ring. These substituents may further have a substituent.

In General Formula (C1), X₅₁ preferably represents —CR₅₁₁R₅₁₂—. R₅₁₁ and R₅₁₂ are preferably a hydrogen atom or an alkyl group. Y₅₁ represents any of the same substituents as Y₄₁ in General Formula (B1), and the preferred substituents are also the same.

The Dye C2 is represented by the following General Formula (C2).

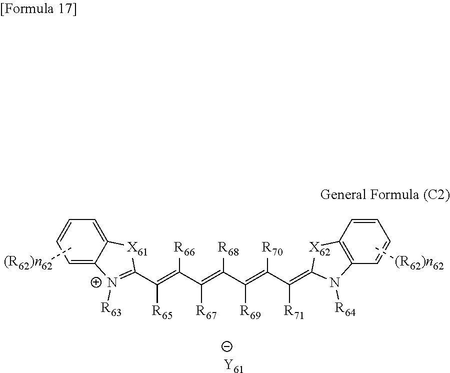

In General Formula (C2), R₆₁ and R₆₂ each independently represent a halogen atom or a substituent. Adjacent substituents may form a 5- or 6-membered ring. n %, and n₆₂ each independently represent an integer of 0 to 4. R₆₃ and R₆₄ each independently represent an alkyl group, an aryl group, or a heterocyclic group. R₆₅ to R₇₁ each independently represent a hydrogen atom, a halogen atom, an alkyl group, an aryl group, or a heterocyclic group. R₆₅ and R₆₇, R₆₆ and R₆₈, R₆₇ and R₆₉, R₆₈ and R₇₀, or R₆₉ and R₇₁ may be bound to each other to form a 5- or 6-membered ring. X₆₁ and X₆₂ each independently represent —O—, —S—, or —CR₆₁₁R₆₁₂—. Y₆₁ represents an anionic atom or an anionic atomic group. R₆₁₁ and R₆₁₂ each independently represent a hydrogen atom or an alkyl group.

In General Formula (C2), R₆₁ and R₆₂ each represent any of the same substituents of R₂ and R₃ in the description of General Formula (A1). Preferred are halogen atoms, alkyl groups, alkoxy groups and aryl groups, and these groups may further have a substituent. Furthermore, adjacent substituents may be bound to each other to form a 5- or 6-membered ring, preferably a phenyl group. Further, it may further have a substituent. n₆₁, and n₆₂ are each preferably an integer of 0 to 2.

Preferably, R₆₃ and R₇₁ are each an alkyl group, which may further have a substituent.

R₆₅ to R₇₁ are each preferably a hydrogen atom, an alkyl group, or an aryl group. In particular, it is preferable that R₆₆ and R₆₈, R₆₇ and R₆₉, or R₆₆, R₆₈, and R₇₀ are bound to each other to form one or a plurality of 5- or 6-membered rings, which may further have a substituent.

In General Formula (C2), X₆₁ and X₆₂ are each preferably —S— or —CR₆₁₁R₆₁₂—, and more preferably —C₆₁₁R₆₁₂—.

R₆₁₁ and R₆₁₂ are each preferably a hydrogen atom or an alkyl group.

Y₆₁ represents any of the same substituents as Y₄₁ in the description of General Formula (B1), and the preferred substituents are also the same.

The dyes represented by General Formulae (A1) to (A4); (B1); (C1) and (C2) are necessary for forming a spectral absorption band mainly in a range of 400 to 800 nm in the absorption spectrum. The near-infrared absorbing composition can form a preferable spectral absorption waveform by containing at least any one of the squarylium dyes (A1) to (A4) and the cyanine dye (B1) each having a maximum absorption wavelength in a range of 680 to 740 nm, and by containing the cyanine dye (C1) or (C2) having a maximum absorption wavelength of 760 nm or more.

It is preferable that the dye is any of the combination of the dyes A1 and C2, the combination of A4 and C2, and the combination of B1 and C2 from the viewpoint of decreasing the transmittance in the near-infrared region while suppressing a decrease of the transmittance in the visible region. Furthermore, by mixing a plurality of dyes among the above-described combinations, it is also possible to smooth the transmission spectrum waveform.

Typical specific examples of the dyes represented by General Formulae (A1) to (A4); (B1); (C1) and (C2) and the maximum absorption wavelengths thereof in methanol solvent are shown below. The present invention is not limited thereto.

Although it depends on the solubility of the dyes, approximately 1×10⁻⁶ mol/L methanol solutions are prepared. Then, measurements are performed at the wavelength of 300 to 1200 nm using a spectrophotometer V-780 manufactured by JASCO Corporation. The maximum absorption wavelengths are thus determined.

### Specific Examples of Dye A1

The following (A1-1) to (A1-20) are typical specific examples of the dye A1.

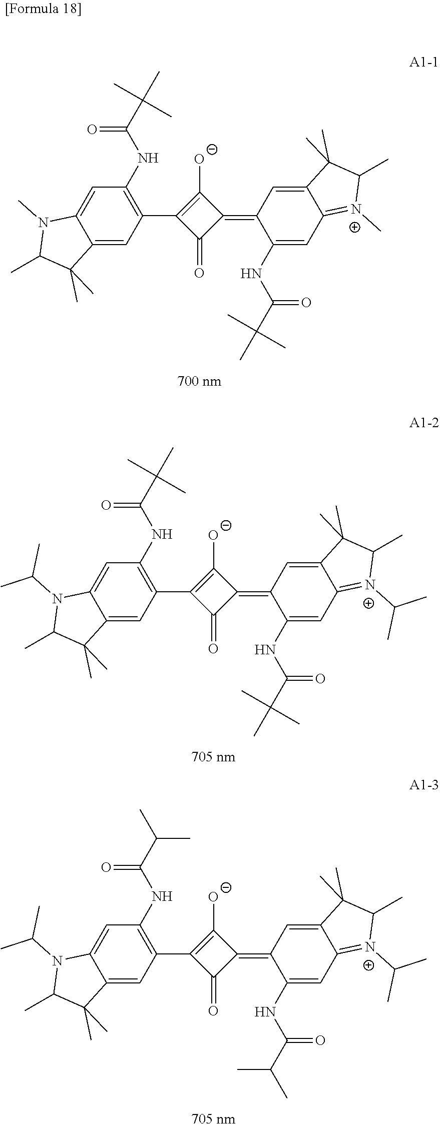

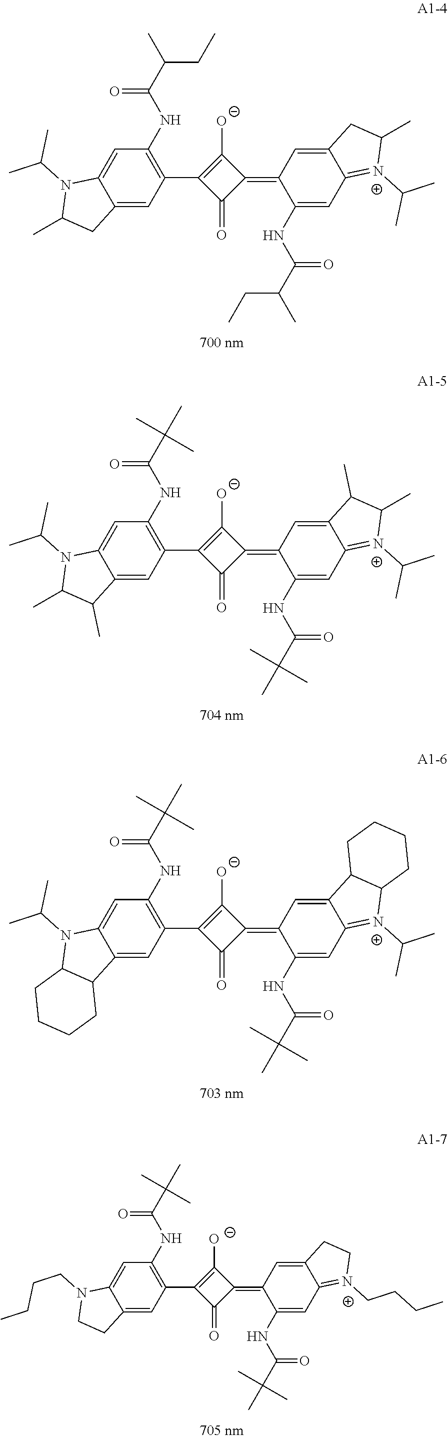

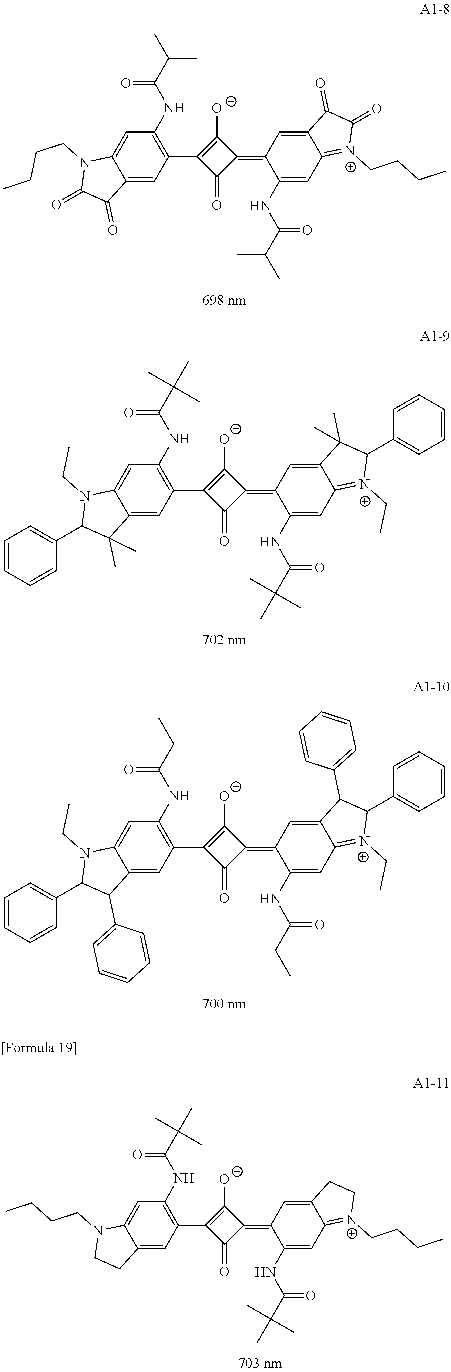

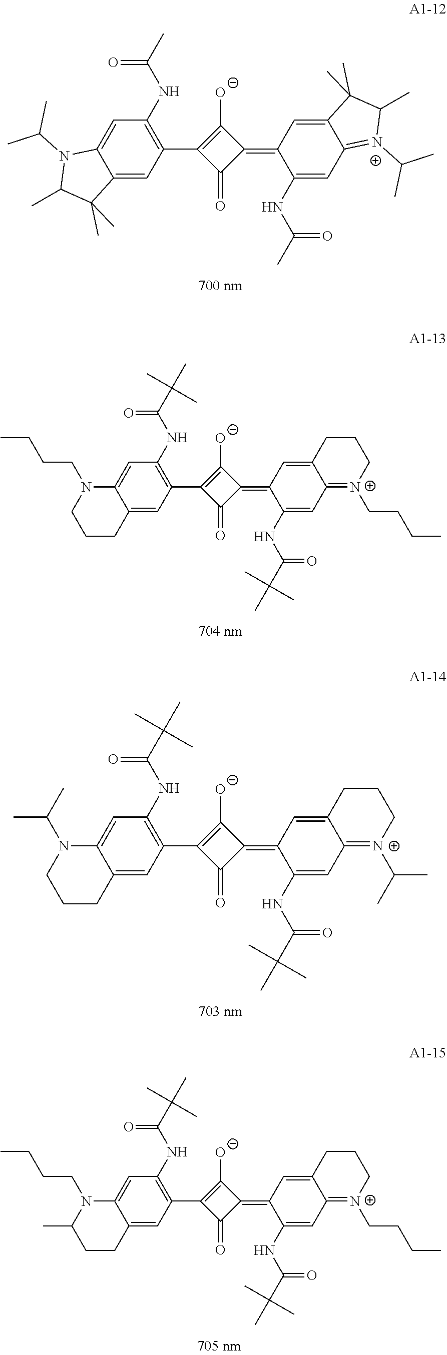

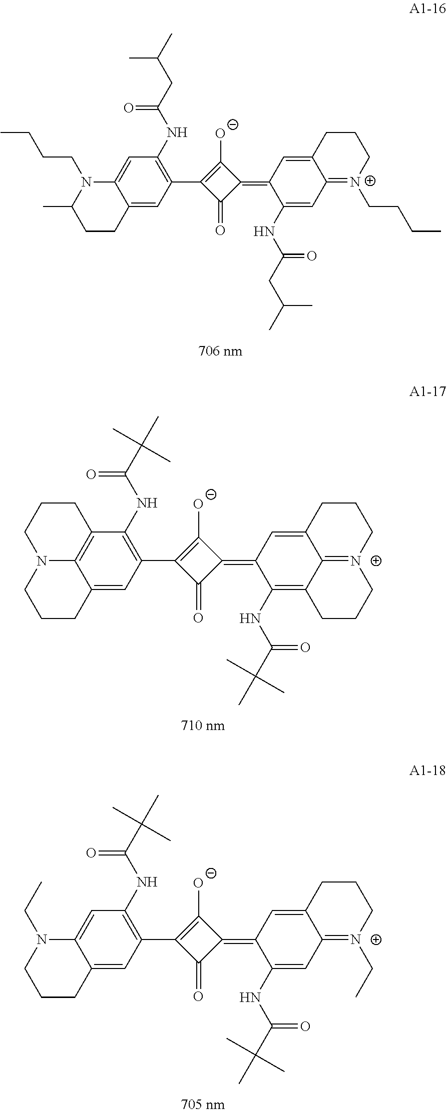 [SMILES: CCCCN1c2cc(NC(=O)CC(C)C)c(C3=C([O-])/C(=c4\cc5c(cc4NC(=O)CC(C)C)=[N+](CCCC)CCC5)C3=O)cc2CCC1C ; CC(C)(C)C(=O)Nc1c(C2=C([O-])/C(=c3\cc4c5c(c3NC(=O)C(C)(C)C)CCC[N+]=5CCC4)C2=O)cc2c3c1CCCN3CCC2 ; CCN1CCCc2cc(C3=C([O-])/C(=c4\cc5c(cc4NC(=O)C(C)(C)C)=[N+](CC)CCC5)C3=O)c(NC(=O)C(C)(C)C)cc21]

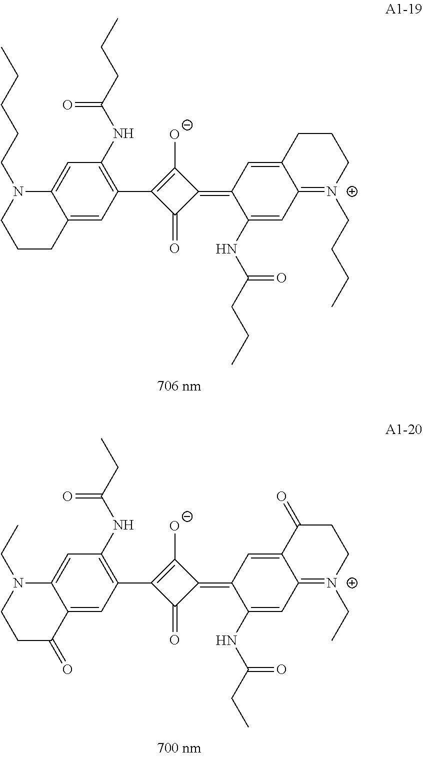 [SMILES: CCCCCN1CCCc2cc(C3=C([O-])/C(=c4\cc5c(cc4NC(=O)CCC)=[N+](CCCC)CCC5)C3=O)c(NC(=O)CCC)cc21 ; CCC(=O)Nc1cc2c(cc1C1=C([O-])/C(=c3\cc4c(cc3NC(=O)CC)=[N+](CC)CCC4=O)C1=O)C(=O)CCN2CC]

### Specific Examples of Dye A2

The following (A2-1) to (A2-14) are typical specific examples of Dye A2.

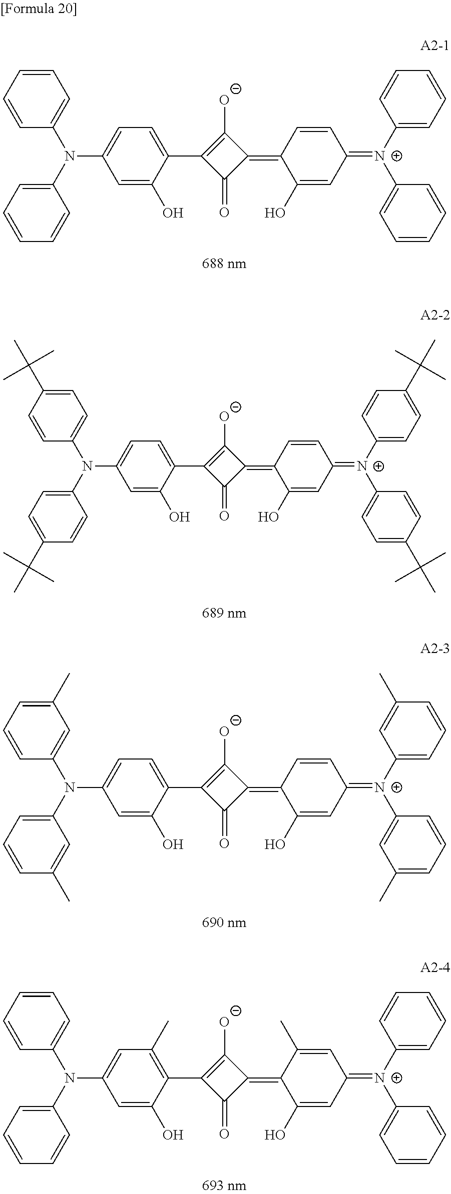 [SMILES: O=C1C(c2ccc(N(c3ccccc3)c3ccccc3)cc2O)=C([O-])/C1=C1\C=CC(=[N+](c2ccccc2)c2ccccc2)C=C1O ; CC(C)(C)c1ccc(N(c2ccc(C(C)(C)C)cc2)c2ccc(C3=C([O-])/C(=C4\C=CC(=[N+](c5ccc(C(C)(C)C)cc5)c5ccc(C(C)(C)C)cc5)C=C4O)C3=O)c(O)c2)cc1 ; Cc1cccc(N(c2cccc(C)c2)c2ccc(C3=C([O-])/C(=C4\C=CC(=[N+](c5cccc(C)c5)c5cccc(C)c5)C=C4O)C3=O)c(O)c2)c1 ; CC1=CC(=[N+](c2ccccc2)c2ccccc2)C=C(O)/C1=C1\C(=O)C(c2c(C)cc(N(c3ccccc3)c3ccccc3)cc2O)=C1[O-]]

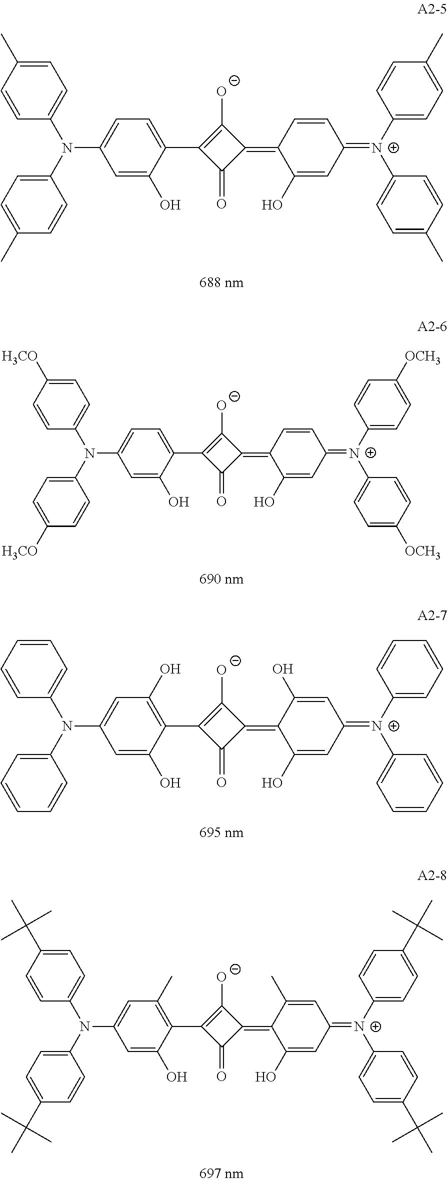

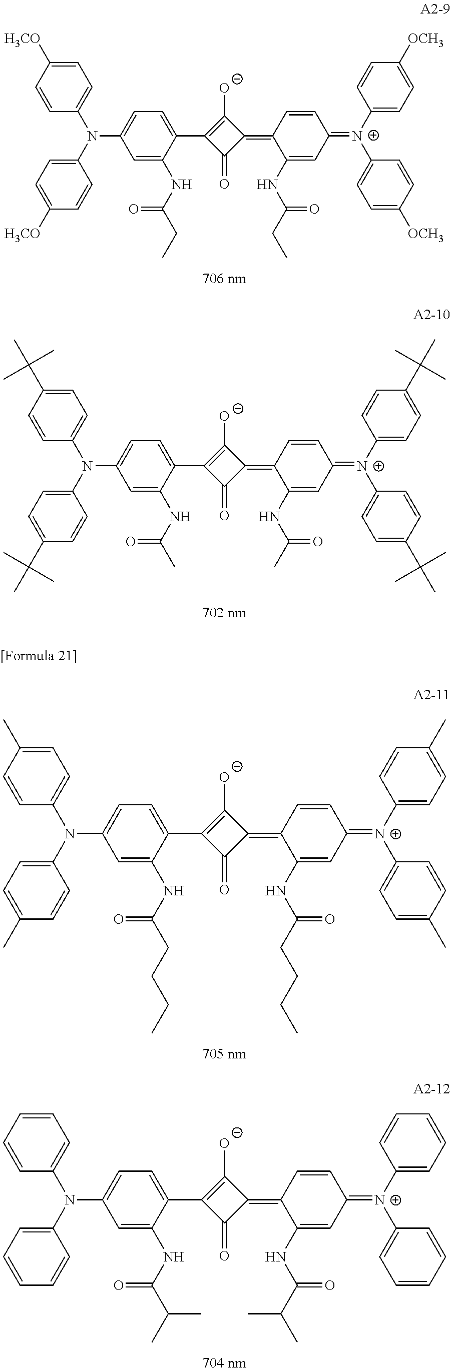 [SMILES: CCC(=O)NC1=CC(=[N+](c2ccc(OC)cc2)c2ccc(OC)cc2)C=C/C1=C1/C(=O)C(c2ccc(N(c3ccc(OC)cc3)c3ccc(OC)cc3)cc2NC(=O)CC)=C1[O-] ; CC(=O)NC1=CC(=[N+](c2ccc(C(C)(C)C)cc2)c2ccc(C(C)(C)C)cc2)C=C/C1=C1/C(=O)C(c2ccc(N(c3ccc(C(C)(C)C)cc3)c3ccc(C(C)(C)C)cc3)cc2NC(C)=O)=C1[O-] ; CCCCC(=O)NC1=CC(=[N+](c2ccc(C)cc2)c2ccc(C)cc2)C=C/C1=C1/C(=O)C(c2ccc(N(c3ccc(C)cc3)c3ccc(C)cc3)cc2NC(=O)CCCC)=C1[O-] ; CC(C)C(=O)NC1=CC(=[N+](c2ccccc2)c2ccccc2)C=C/C1=C1/C(=O)C(c2ccc(N(c3ccccc3)c3ccccc3)cc2NC(=O)C(C)C)=C1[O-]]

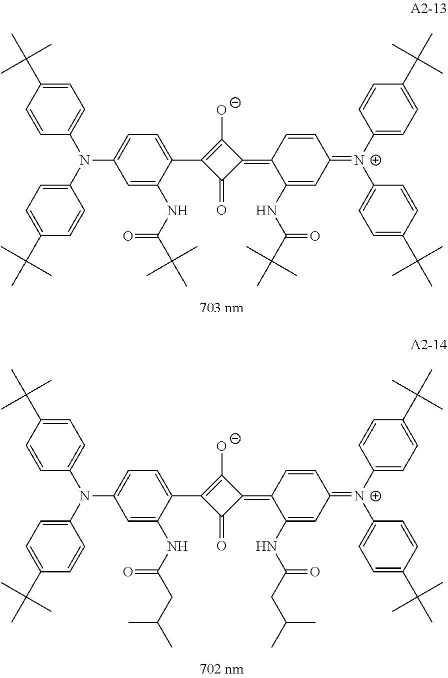

### Specific Examples of Dye A3

The following (A3-1) to (A3-18) are typical specific examples of the dye A3.

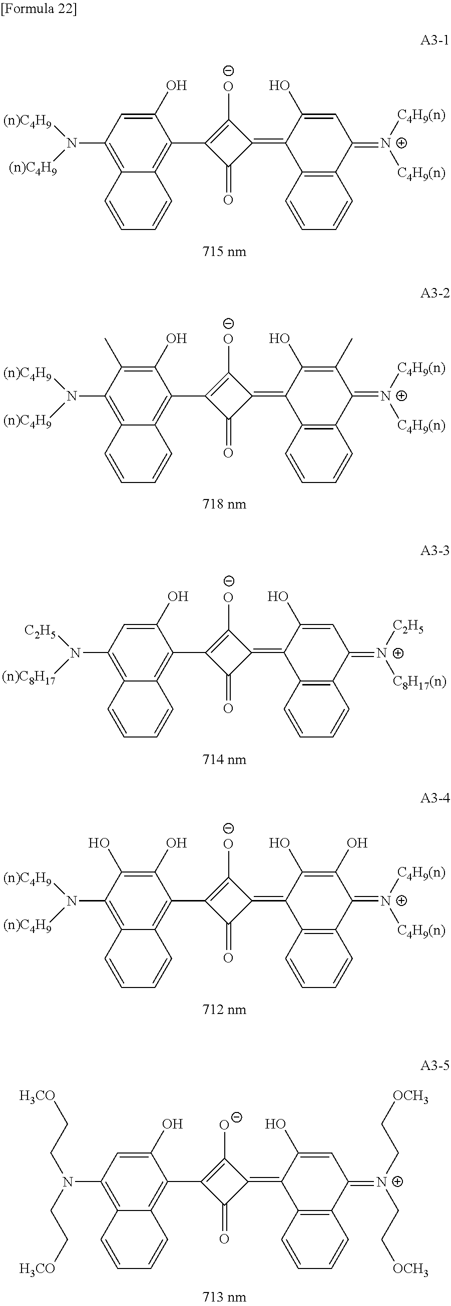

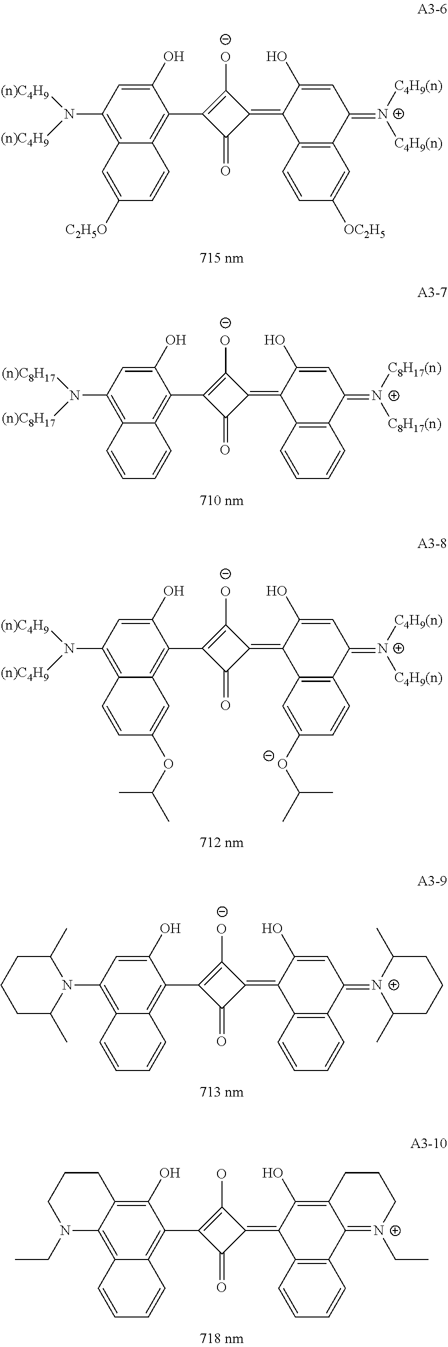

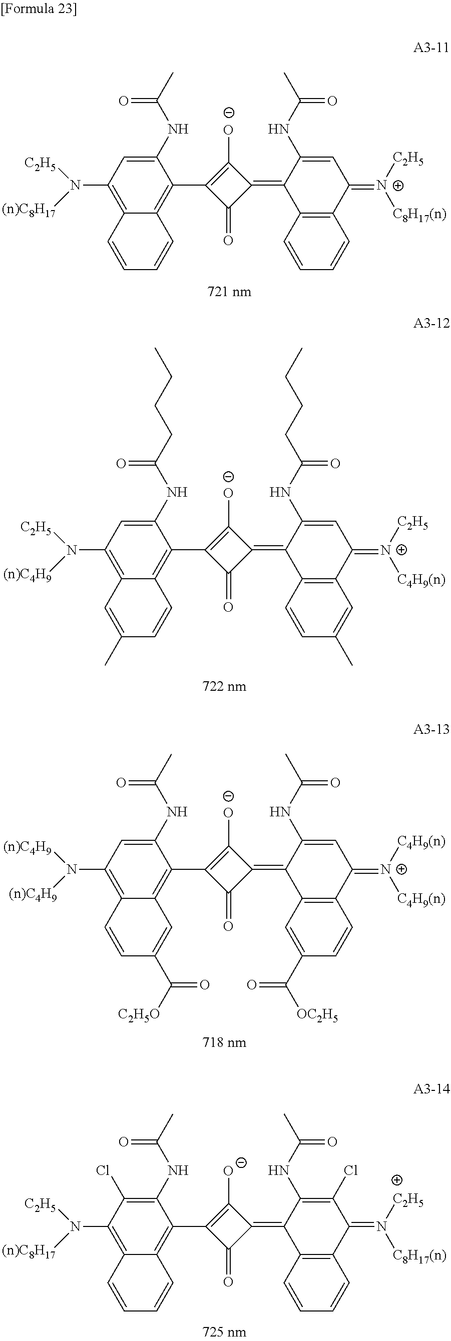

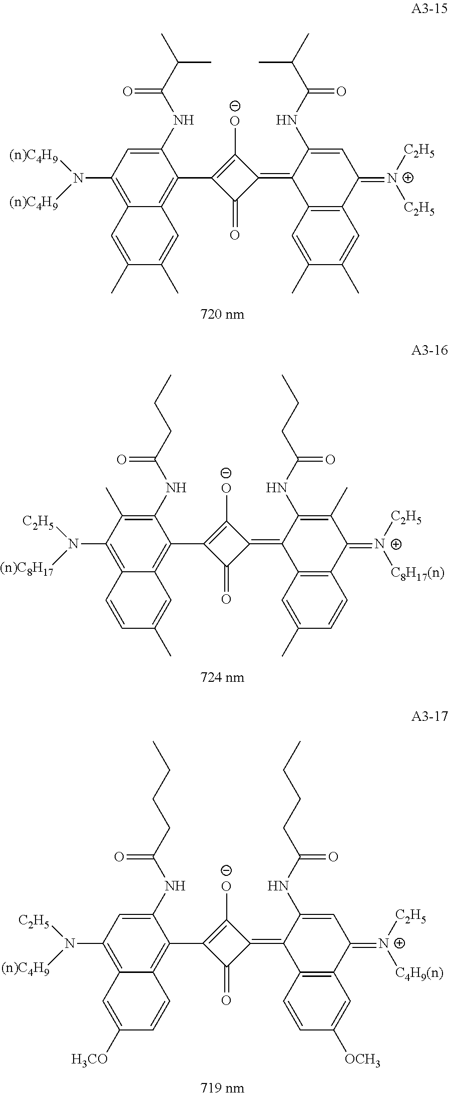

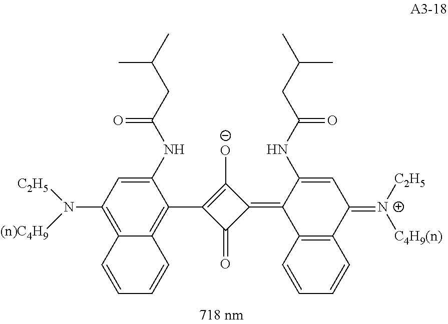

### Specific Examples of Dye A4

The following (A4-1) to (A4-20) are typical specific examples of the dye A4.

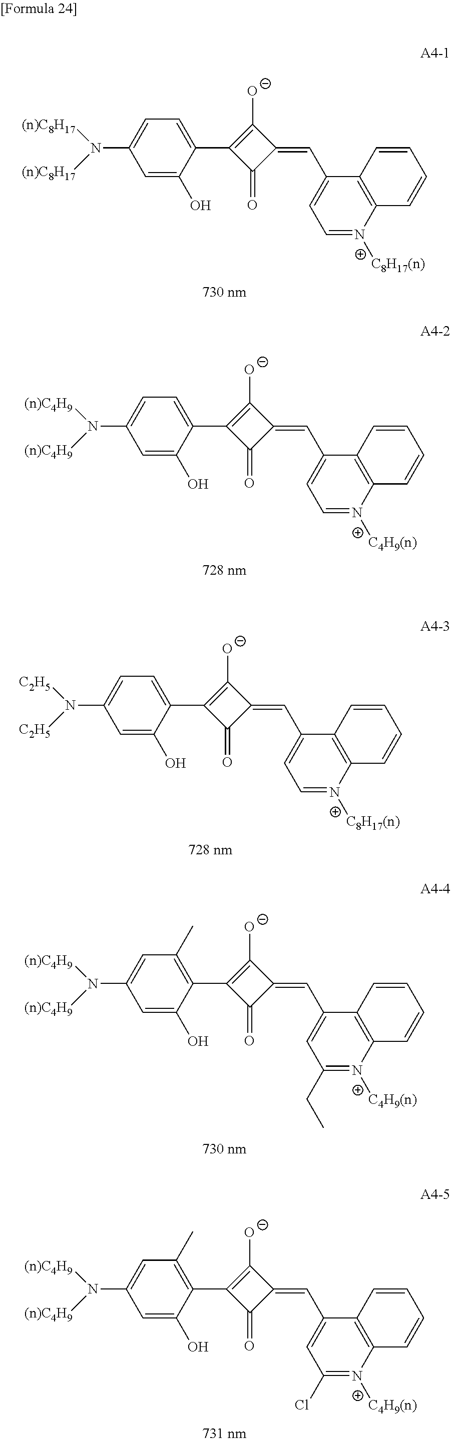

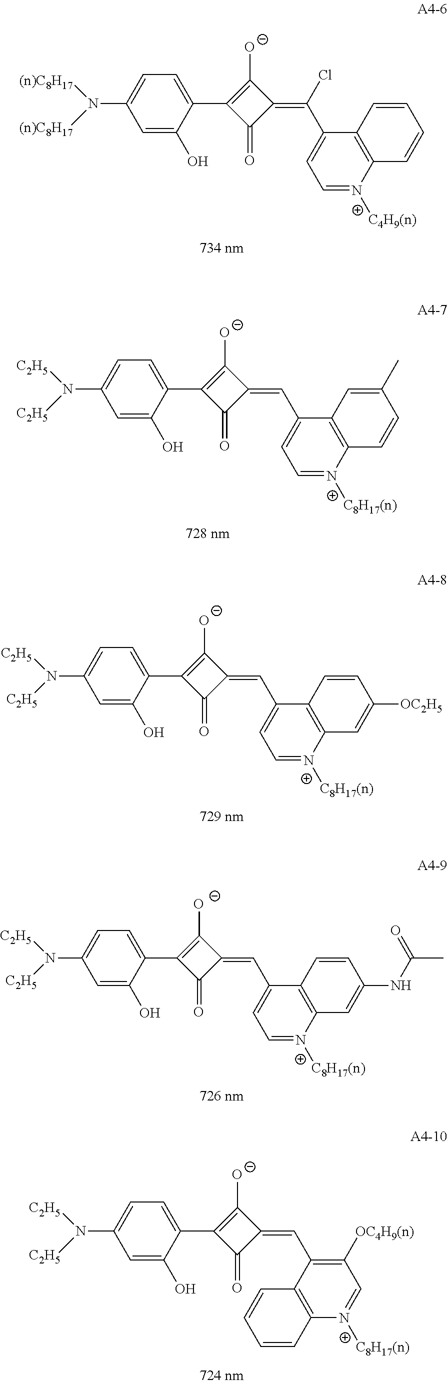

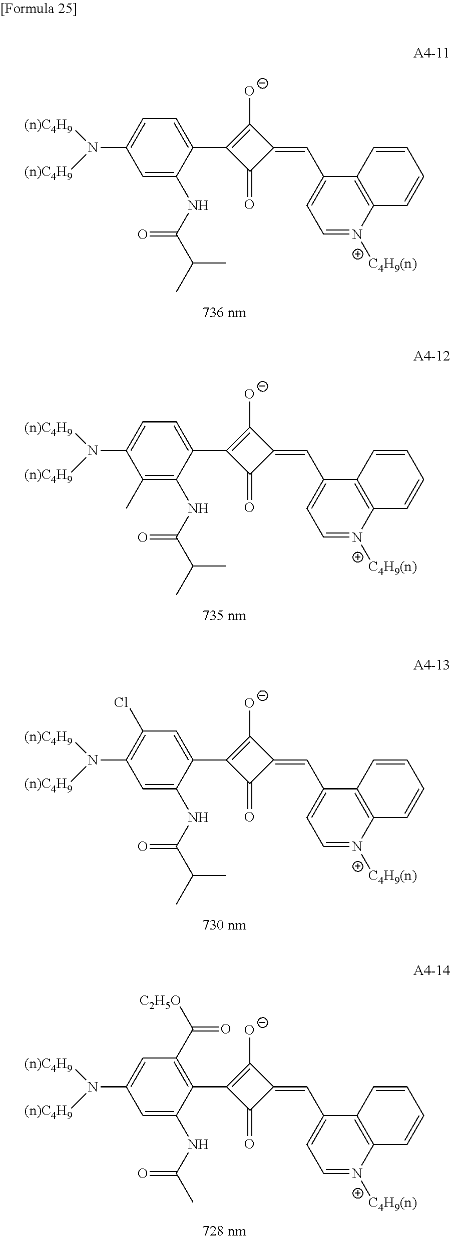

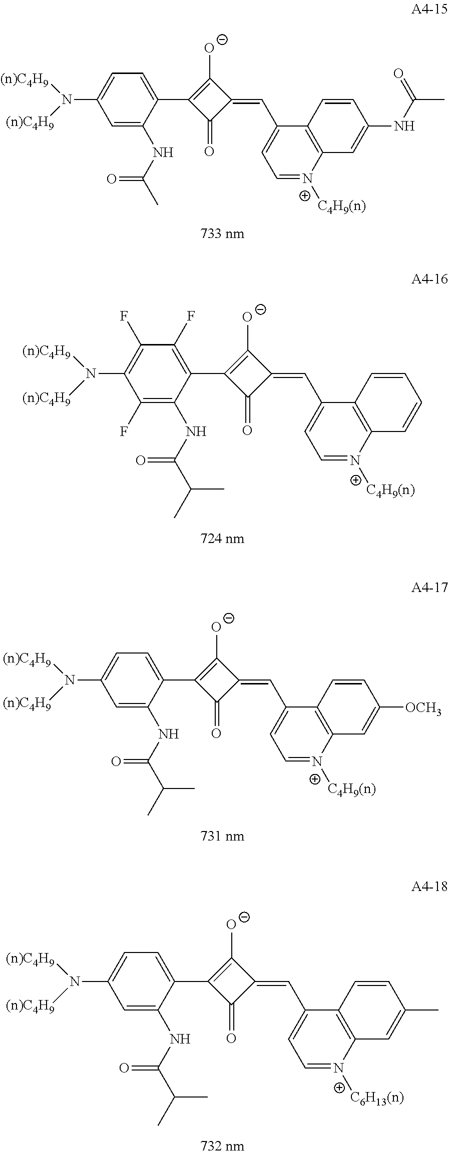

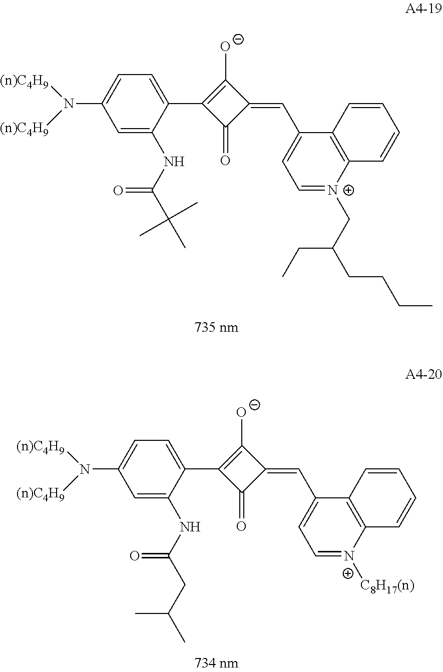

### Specific Examples of Dye B1

The following (B1-1) to (B1-14) are typical specific examples of the dye B1.

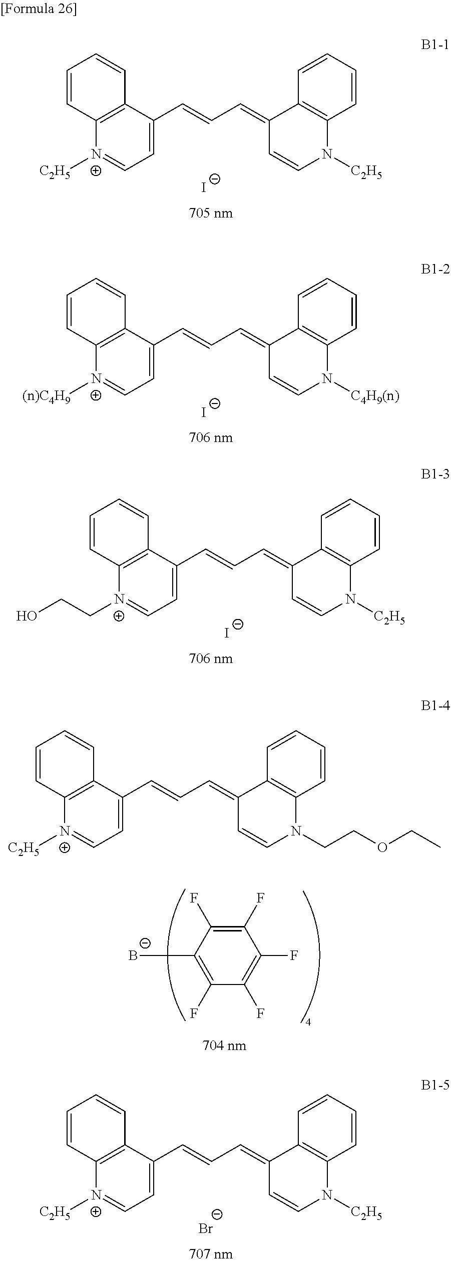

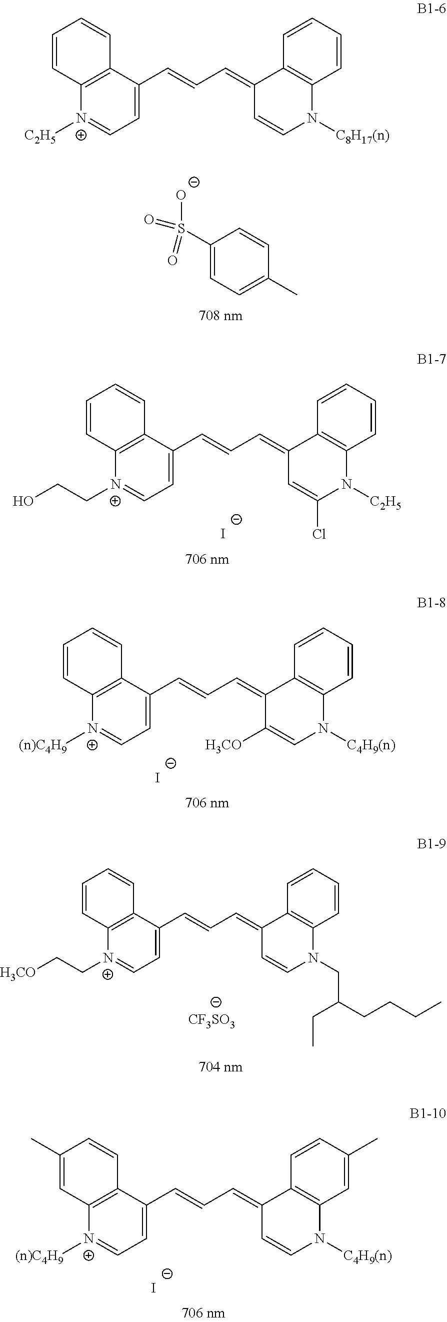

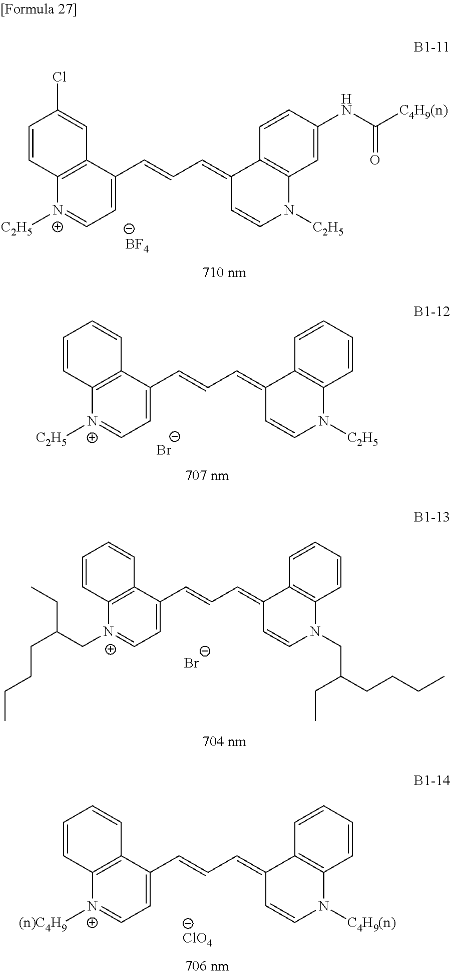

### Specific Examples of Dye C1

The following (C1-1) to (C1-10) are typical specific examples of the dye C1.

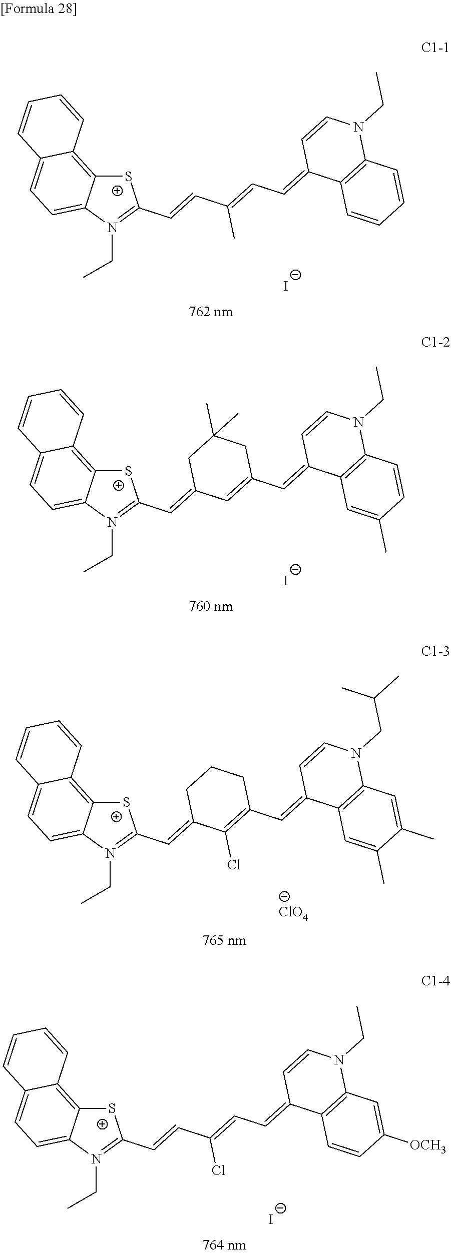

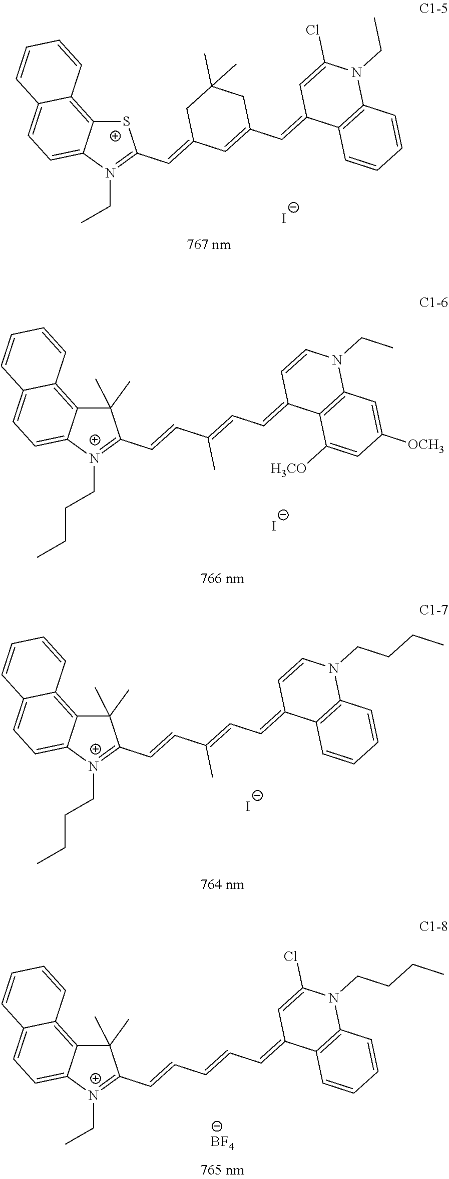

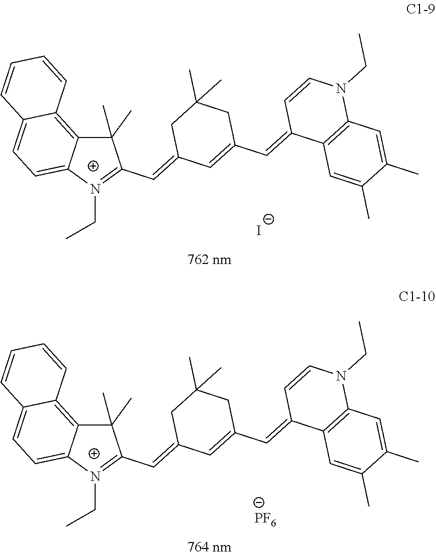

### Specific Examples of Dye C2

The following (C2-1) to (C2-30) are typical specific examples of the dye C2.

TsO⁻ in the chemical structural formulae represents a p-toluenesulfonate ion. A p-toluenesulfonate ion is also referred to as a tosylate ion or a tosylate anion.

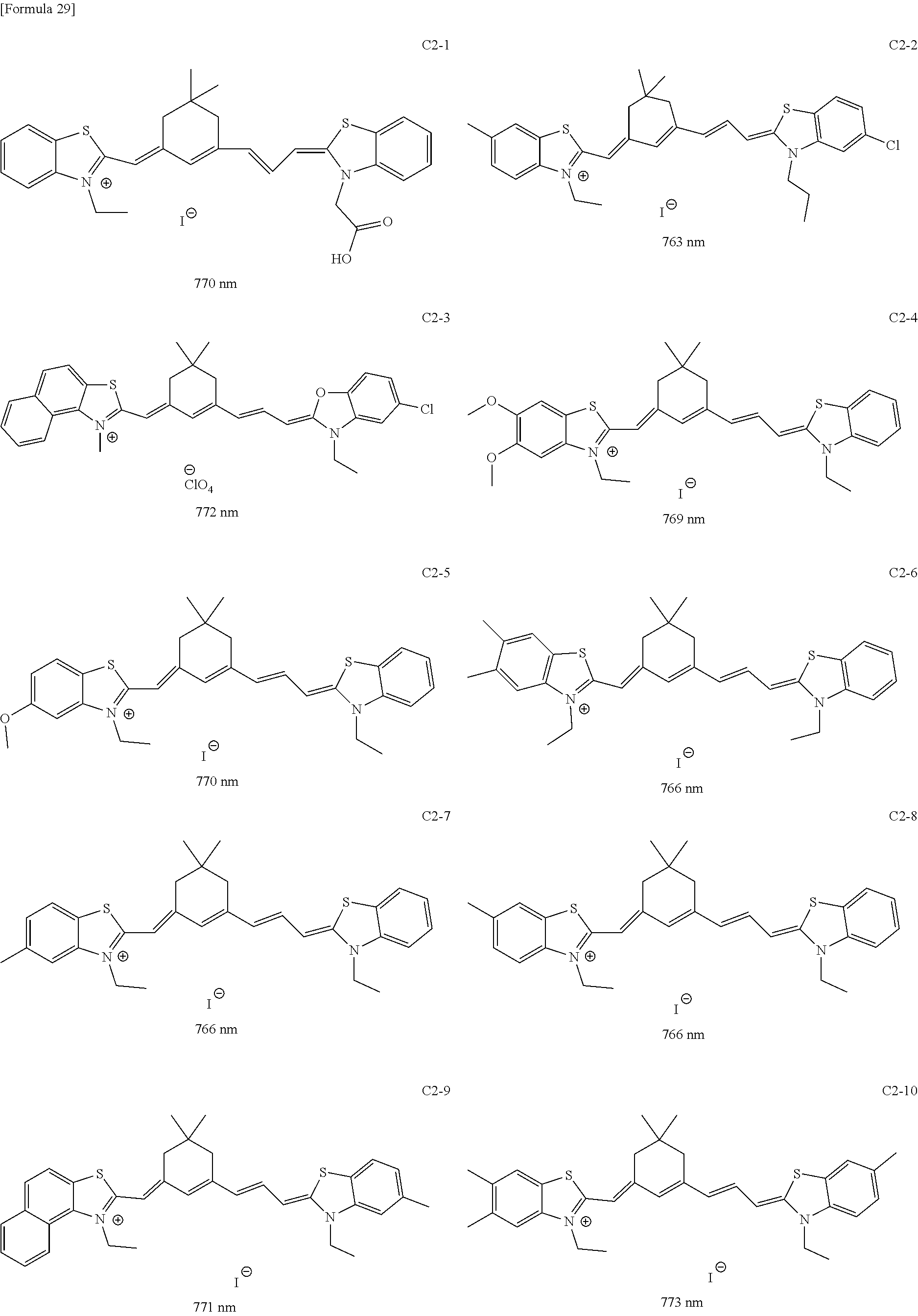

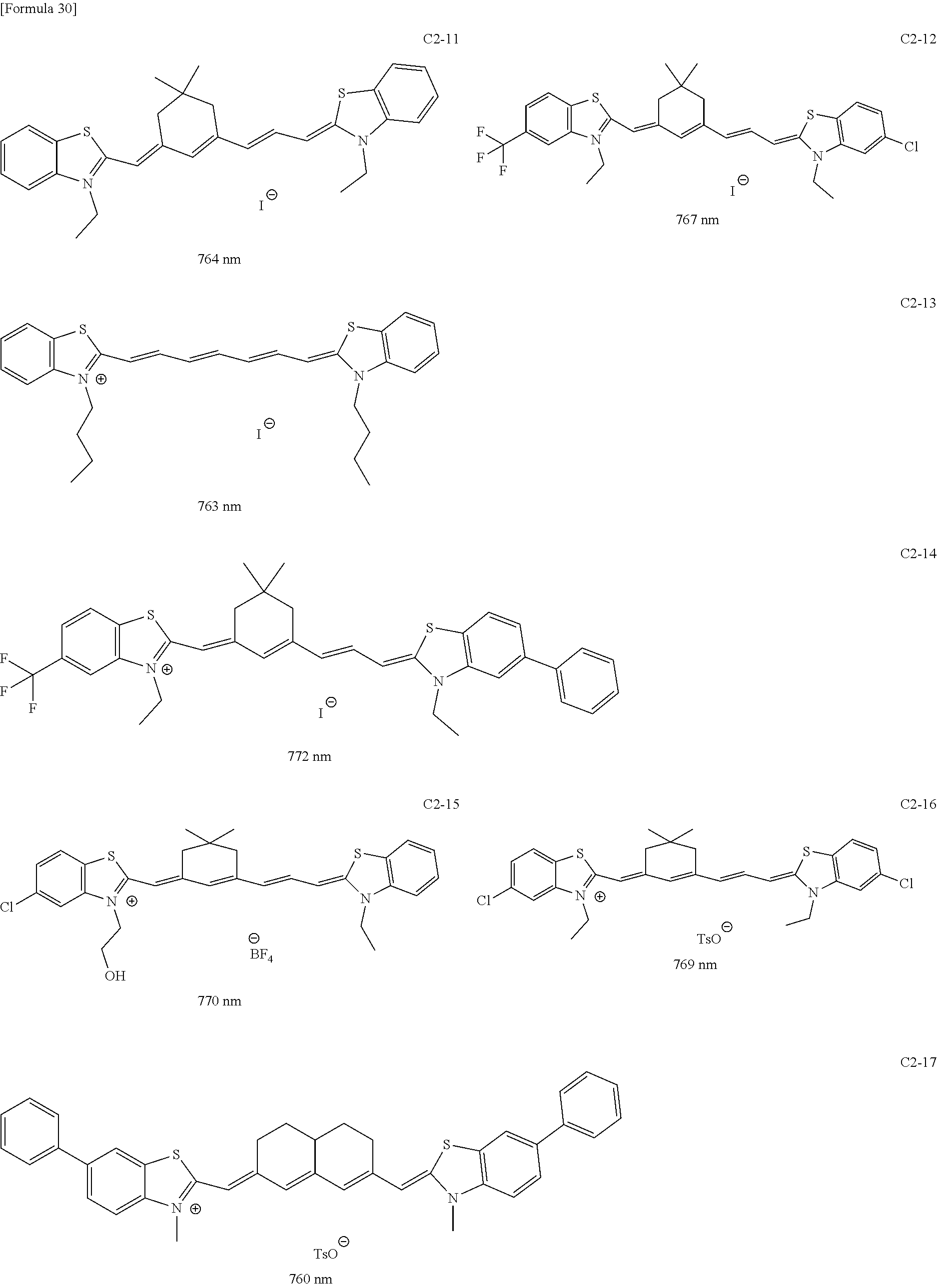

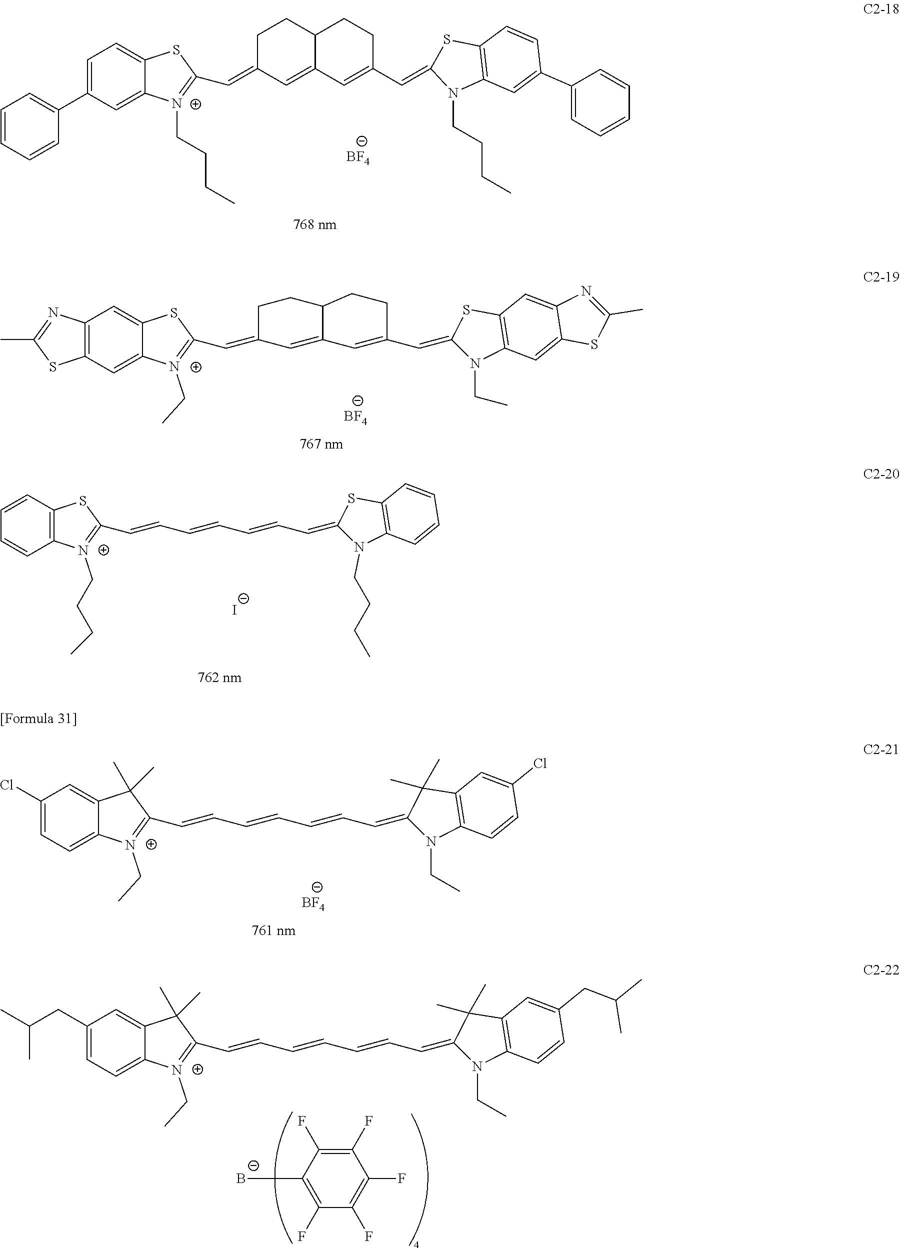

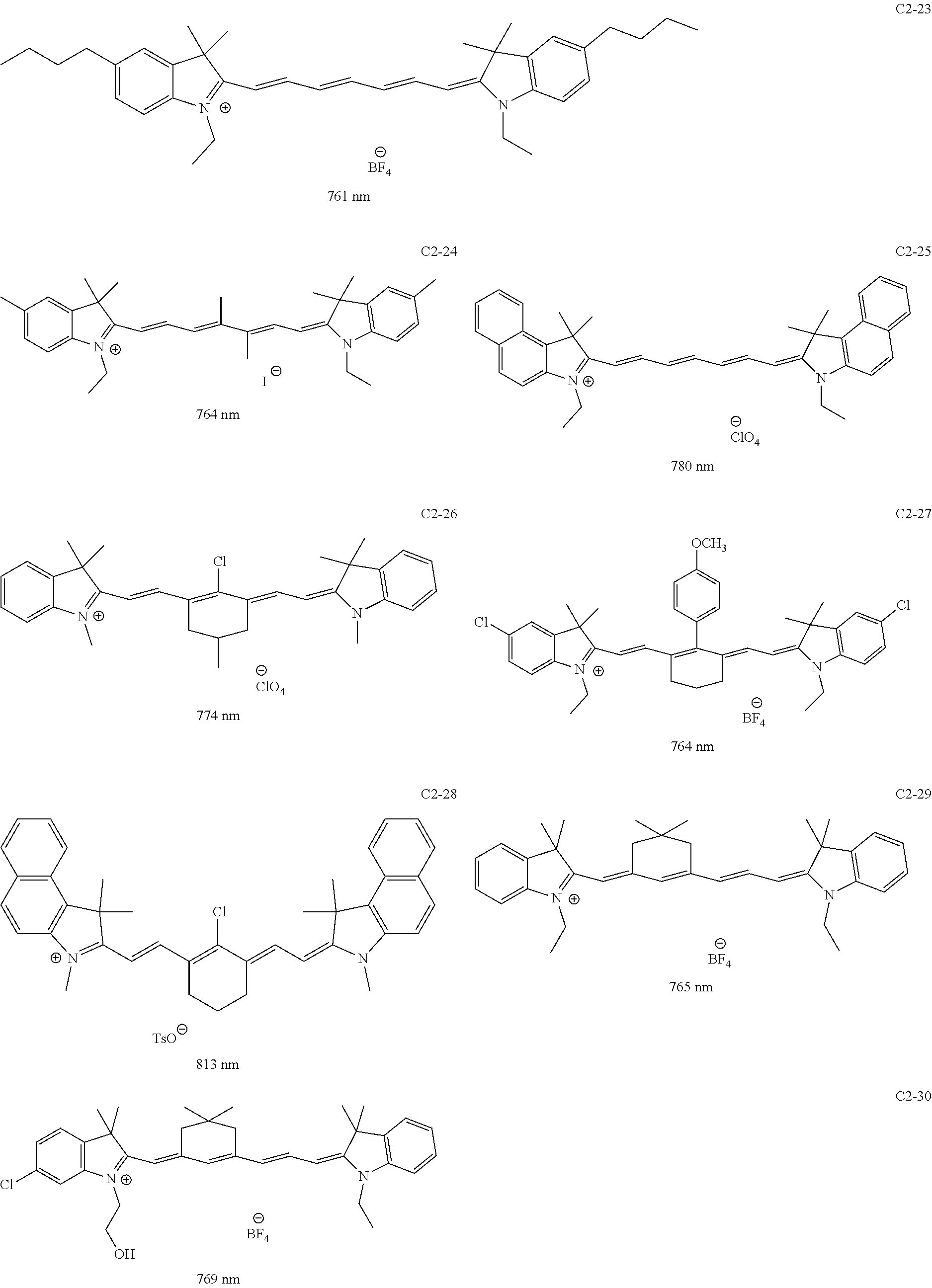

Next typical synthesis methods of the dyes of General Formulae A1 to A4, B1 and C1 to C2 will be described.

The squarylium dyes can be easily synthesized with reference to the following documents.

Japanese Unexamined Patent Publication No. 2004-319309, Japanese Unexamined Patent Publication No. 2008-209462, Japanese Unexamined Patent Publication No. 2009-36811, Japanese Unexamined Patent Publication No. 2009-180875 and Japanese Unexamined Patent Publication No. 2017-197437

The cyanine dyes can be easily synthesized with reference to the following documents.
1) “Heterocyclic Compounds—Cyanine Dyes and Related Compounds” by F. M. Harmer, published by John Wiley & Sons, Inc., New York, London, 1964
2) “Heterocyclic Compounds—Special topics in heterocyclic chemistry” by D. M. Stunner, Chapter 18, Section 14, pp. 482 to 515, published by John Wiley & Sons, Inc., New York, London, 1977
3) “Rodd's Chemistry of Carbon Compounds”, 2nd. Ed. vol. IV, part B, Chapter 15, pp. 369 to 422, published by Sevier Science Publishing Company Inc., New York, 1977
4) Japanese Unexamined Patent Publication No. H6-313939, Japanese Unexamined Patent Publication No. H5-88293, Japanese Unexamined Patent Publication No. 2006-16564, Japanese Unexamined Patent Publication No. 2000-321704, Japanese Unexamined Patent Publication No. 2006-63171 and Japanese Unexamined Patent Publication No. 2018-177830

Synthesis examples of the dyes represented by General Formulae A1 to A4, B1, and C1 to C2 are shown below.

### Synthesis Example 1

### Synthesis of A1-1

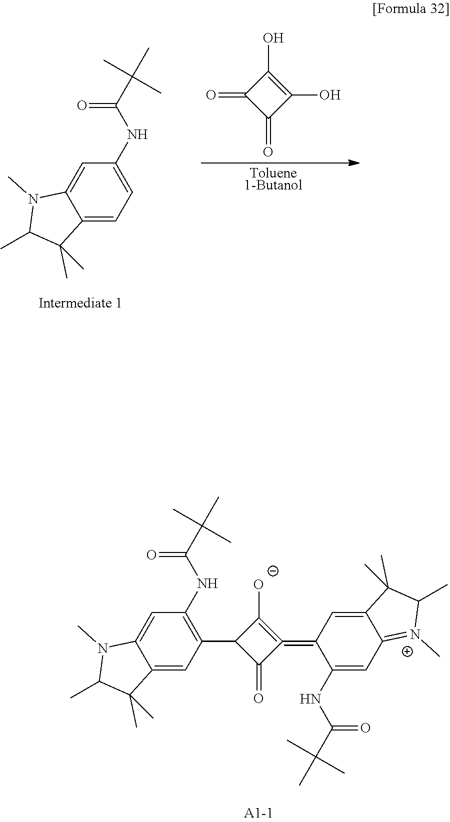

Toluene: 15 mL and 1-butanol: 15 mL are added to Intermediate 1: 0.6 g and squaric acid: 0.12 g, and the mixture is heated under reflux for 5 hours while dehydration is performed using an ester tube. After cooling, the solvent was distilled off under reduced pressure, and toluene was further added to concentrate the mixture. The residue was dissolved in toluene, and 0.47 g of a target substance was isolated by column chromatography (the developing solvent being a mixture of ethyl acetate and N-heptane). The product was identified by MASS, 1H-NMR, and IR spectroscopy, and it was confirmed that the product was the target substance (A1-1).

### Synthesis Example 2

### Synthesis of A2-2

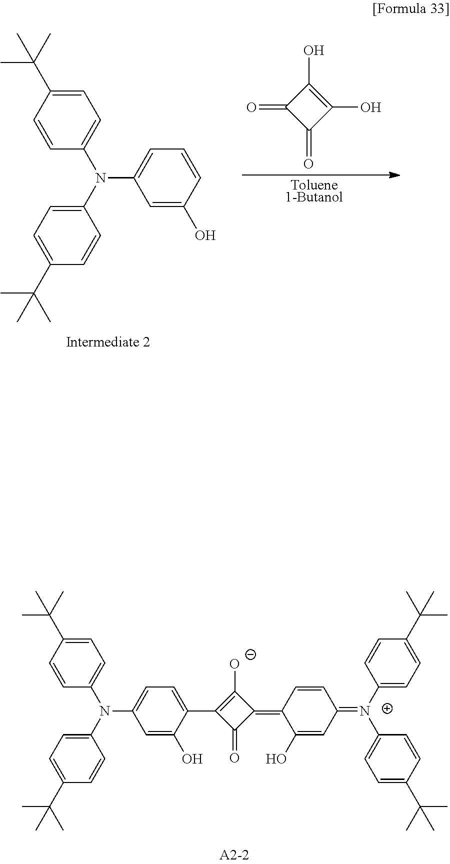

Toluene: 20 mL and 1-butanol: 20 mL are added to Intermediate 2: 1.50 g and squaric acid: 0.22 g, and the mixture is heated under reflux for 4 hours while dehydration is performed using an ester tube. After cooling, the solvent was distilled off under reduced pressure, and toluene was further added to concentrate the mixture. The residue was dissolved in toluene, and 1.26 g of a target substance was isolated by column chromatography (the developing solvent being a mixture of ethyl acetate and N-heptane). The product was identified by MASS, 1H-NMR, and IR spectroscopy, and it was confirmed that the product was the target substance (A2-2).

### Synthesis Example 3

### Synthesis of A3-1

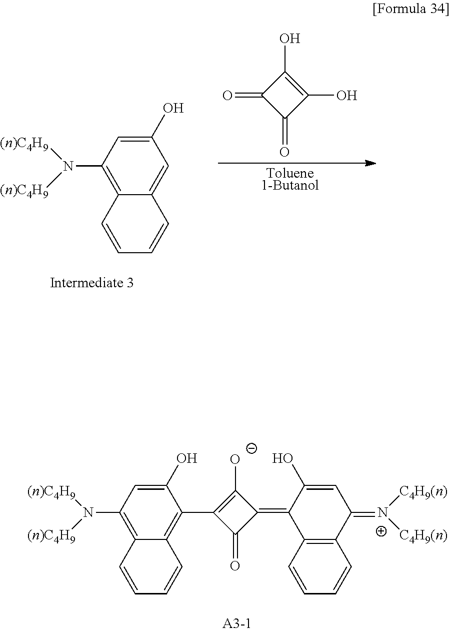

Toluene: 20 mL and 1-butanol: 20 mL are added to Intermediate 3: 1.15 g and squaric acid: 0.22 g, and the mixture is heated under reflux for 8 hours while dehydration is performed using an ester tube. After cooling, the solvent was distilled off under reduced pressure, and toluene was further added to concentrate the mixture. The residue was dissolved in toluene, and the solution was subjected to column chromatography (developing solvent: a mixture of ethyl acetate and N-heptane) to isolate the target substance: 0.78 g. The product was identified by MASS, 1H-NMR, and IR spectroscopy, and it was confirmed that the product was the target substance (A3-1).

### Synthesis Example 4

### Synthesis of A4-1

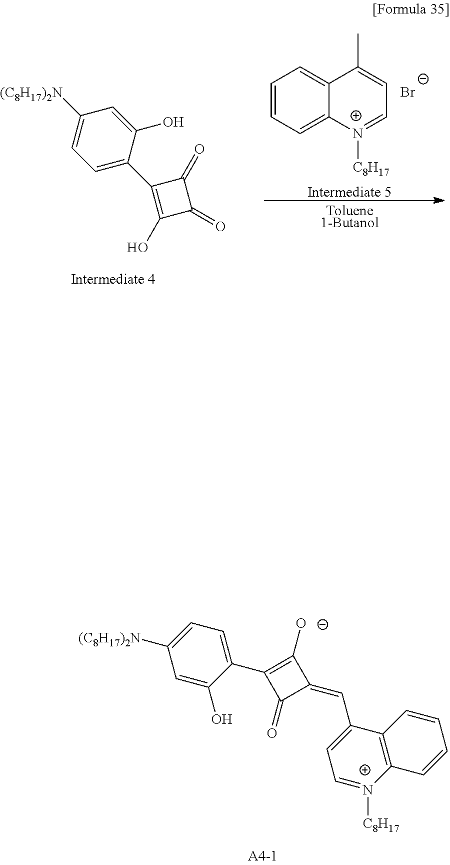

Toluene: 20 mL and 1-butanol: 20 mL are added to Intermediate 4: 1.35 g and Intermediate 5: 1.06 g, and the mixture is heated under reflux for 3 hours while dehydration is performed using an ester tube. After cooling, the solvent was distilled off under reduced pressure, and toluene was further added to concentrate the mixture. The residue was dissolved in toluene, and the solution was subjected to column chromatography (developing solvent was a mixed of ethyl acetate and N-heptane) to isolate 1.22 g of the target substance. The product was identified by MASS, 1H-NMR, and IR spectroscopy, and it was confirmed that the product was the target substance (A4-1).

### Synthesis Example 5

### Synthesis of B1-3

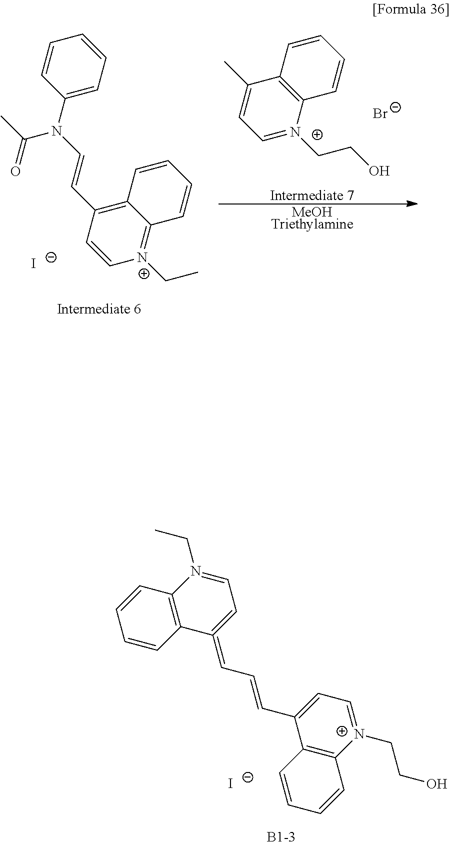

Methanol: 40 mL and triethylamine: 0.36 g are added to Intermediate 6: 1.60 g and Intermediate 7: 0.97 g, and the mixture is heated under reflux for 6 hours. After cooling, the precipitated crystal was filtered and washed with methanol to isolate the target substance: 0.76 g. The product was identified by MASS, 1H-NMR, and IR spectroscopy, and it was confirmed that the product was the target substance (B1-3).

### Synthesis Example 6

### Synthesis of C1-7

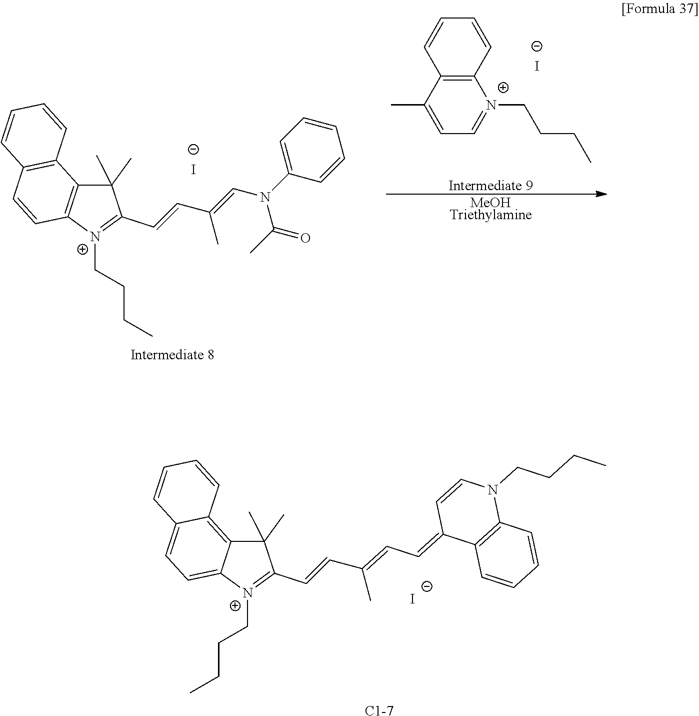

Methanol: 40 mL and triethylamine: 0.22 g are added to Intermediate 8: 1.26 g and Intermediate 9: 0.65 g, and the mixture was heated under reflux for 6 hours. After cooling, the solvent is distilled off under reduced pressure, the residue is extracted with ethyl acetate, neutralized and washed with water, and the ethyl acetate is concentrated. The residue was dissolved in methylene chloride, and the solution was subjected to column chromatography (developing solvent: a mixture of ethyl acetate and methanol) to isolate 0.83 g of the target substance. The product was identified by MASS, 1H-NMR, and IR spectroscopy, and it was confirmed that the product was the target substance (C1-7).

### Synthesis Example 7

### Synthesis of C2-18

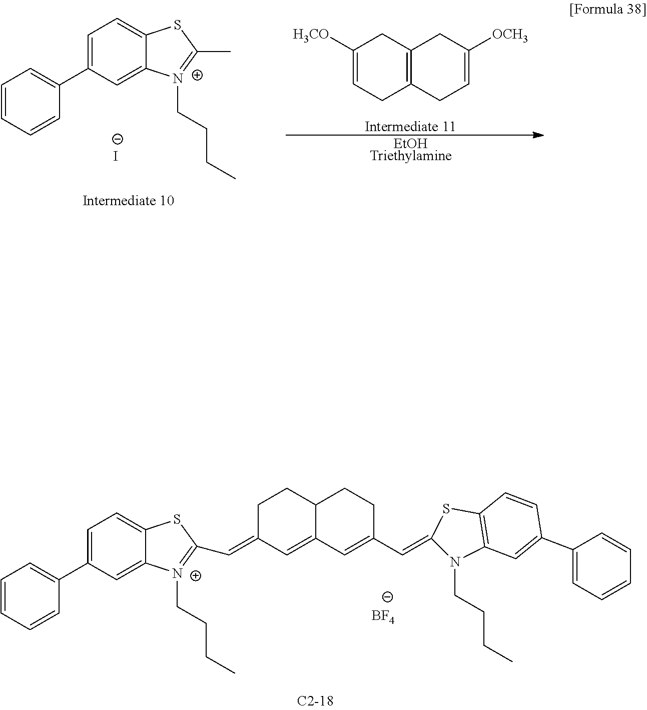

Intermediate 10: 4.09 g was dissolved in m-cresol: 2.5 mL, Intermediate 11: 2.0 g was added thereto, and the mixture was heated and stirred in a 120° C. oil bath for 10 minutes. Next, 50 mL of ethanol and 0.5 g of triethylamine were added, and the mixture was heated and stirred in a 70° C. water bath for 30 minutes. To the reaction solution, sodium tetrafluoroborate: 0.5 g was added, and the mixture was cooled and stirred to cause precipitation. The crystals were collected by filtration and recrystallized from a mixed solvent of fluorinated alcohol and methanol to isolate 0.58 g of the target substance. The product was identified by MASS, 1H-NMR and IR spectroscopy, and it was confirmed that the product was the target substance (C2-18.

### Metal Compound

### Copper Phosphonate Complex

The near-infrared absorbing composition of the present invention is characterized by containing a phosphonic acid and a copper ion or a copper phosphonate complex formed from a phosphonic acid and a copper ion. By containing the copper phosphonate complex, it is possible to decrease the light transmittance in the wavelength region of approximately 800 nm or longer.

The phosphonic acid has a structure represented by the following General Formula (H1).

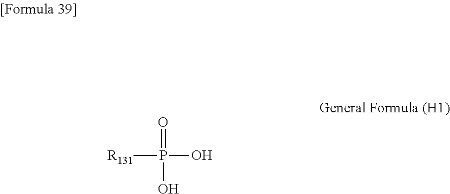

In the General Formula (H1), R₁₃₁ represents a branched, linear or cyclic alkyl, alkenyl, alkenyl, aryl or allyl group having 1 to 30 carbon atoms. The hydrogen atoms of these groups may or may not be substituted with a halogen atom, an oxyalkyl group, a polyoxyalkyl group, an oxyaryl group, a polyoxyaryl group, an acyl group, an aldehyde group, a carboxy group, a hydroxy group, or a group having an aromatic ring. R₁₃₁ is preferably an alkyl group having 1 to 20 carbon atoms from the viewpoint of good moisture and heat resistance and good near-infrared absorption property. R₁₃₁ is more preferably an alkyl group having 1 to 4 carbon atoms from the viewpoint of achieving both near-infrared absorption and visible light transmittance.

Examples of the phosphonic acid compounds having the structure represented by General Formula (H1) include ethylphosphonic acid, propylphosphonic acid, butylphosphonic acid, pentylphosphonic acid, hexylphosphonic acid, octylphosphonic acid, 2-ethylhexylphosphonic acid, 2-chloroethylphosphonic acid, 3-bromopropylphosphonic acid, 3-methoxybutylphosphonic acid, 1,1-dimethylpropylphosphonic acid, 1,1-dimethylethylphosphonic acid, 1-methylpropylphosphonic acid, benzenephosphonic acid, 4-methoxyphenylphosphonic acid. Specific examples thereof include the following compounds (H-1) to (H-8).

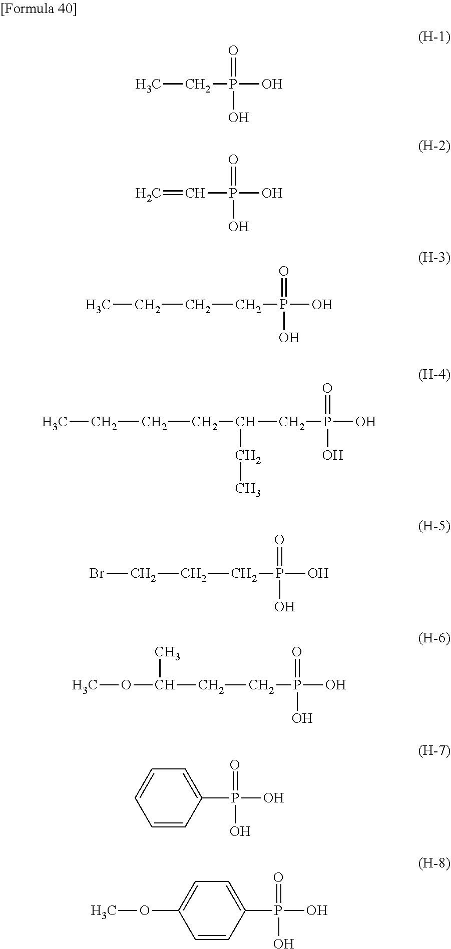

In the present invention, the phosphonic acid constituting the copper phosphonate complex is preferably at least one alkylphosphonic acid selected from the following phosphonic acid group.
1: Methylphosphonic acid
2: Ethylphosphonic acid
3: Propylphosphonic acid
4: Butylphosphonic acid
5: Pentylphosphonic acid
6: Hexylphosphonic acid
7: Octylphosphonic acid
8: 2-Ethylhexylphosphonic acid
9: 2-Chloroethylphosphonic acid
10: 3-Bromopropylphosphonic acid
11: 3-Methoxybutylphosphonic acid
12: 1,1-Dimethylpropylphosphonic acid
13: 1,1-Dimethylethylphosphonic acid
14: 1-Methylpropylphosphonic acid

Hereinafter, the copper phosphonate complexes applicable to the present invention will be described. The copper phosphonate complex has the structure represented by the following General Formula (H2).

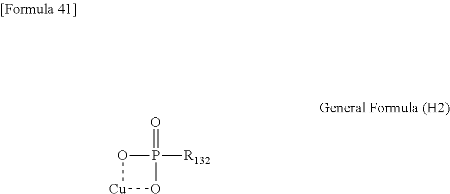

In General Formula (H2), R₁₃₂ represents an alkyl, phenyl, or benzyl group.

Examples of the copper salts that are used for formation of the copper phosphonate complex having the structure represented by General Formula (H2) include copper salts capable of supplying a divalent copper ion. Examples thereof include copper acetate anhydride, copper formate anhydride, anhydrous copper stearate, copper benzoate anhydride, copper acetoacetate anhydride, anhydrous copper ethylacetoacetate, copper methacrylate anhydride, anhydrous copper pyrophosphates, anhydrous copper naphthenate, a copper salt of an organic acid such as anhydrous copper citrate, a hydrate or a hydrate of a copper salt of the organic acid, copper chloride, copper sulfate, copper nitrate, copper phosphate, basic copper sulfate, a copper salt of an inorganic acid such as basic copper carbonate, a hydrate or a hydrate of a copper salt of the inorganic acid; copper hydroxide.

In the present invention, the phosphonic acid constituting the copper phosphonate complex is preferably an alkylphosphonic acid. Examples thereof include a copper ethylphosphonate complex, a copper propylphosphonate complex, a copper butylphosphonate complex, a copper pentylphosphonate complex, a copper hexylphosphonate complex, a copper octylphosphonate complex, a copper 2-ethylhexylphosphonate complex, a copper 2-chloroethylphosphonate complex, a copper 3-bromopropylphosphonate complex, a copper 3-methoxybutylphosphonate complex, a copper 1,1-dimethylpropylphosphonate complex, a copper 1,1-dimethylethylphosphonate complex, and a copper 1-methylpropylphosphonate complex.

In the near-infrared absorbing composition of the present invention, it is preferable that the copper complex fine particles are uniformly dispersed in the near-infrared absorbing film, which is described later, from the viewpoint of the spectral characteristics. For this reason, it is preferable that the particle size of the copper complex fine particles in the near-infrared absorbing dispersion liquid is small.

The average particle size of the copper complex fine particles in the near-infrared absorbing dispersion liquid is preferably 200 nm or less, more preferably 100 nm or less, and yet more preferably 80 nm or less.

The average particle size of the copper complex fine particles in the near-infrared absorbing dispersion liquid can be measured by a dynamic light scattering method using the zeta potential and particle diameter measurement system ELSZ-1000ZS manufactured by Otsuka Electronics Corporation.

Compound Having Structure Represented by General Formula (I)

In the near-infrared absorbing composition of the present invention, it is preferable that the phosphonic acid is an alkylphosphonic acid and that the composition contains a compound having the structure represented by the following General Formula (I) and a copper ion, or a copper complex formed from the compound having the structure represented by the following General Formula (I) and a copper ion, from the viewpoint of improving the dispersion stability.

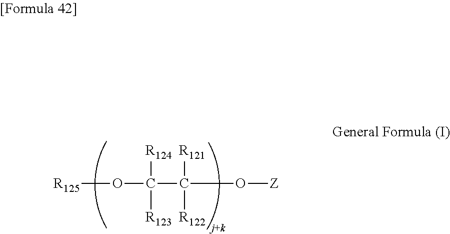

The compound having the structure represented by General Formula (I) may react with a copper ion to form a copper complex.

In General Formula (I), R₁₂₅ represents an alkyl group having 1 to 20 carbon atoms or an aryl group having 6 to 20 carbon atoms. R₁₂₅ may further have a substituent, and such substituents are not particularly limited as long as the advantageous effects of the present invention are not impaired.

The alkyl groups having 1 to 20 carbon atoms represented by R₁₂₅ may be linear or branched. Examples thereof include a methyl group, an ethyl group, an n-propyl group, an isopropyl group, an n-butyl group, a tert-butyl group, an n-hexyl group, a 2-ethylhexyl group, an n-octyl group, a 2-butyloctyl group, a 2-hexyloctyl group, an n-decyl group, a 2-hexyldecyl group, an n-dodecyl group, an n-stearyl group and the like. Each alkyl group may further have a substituent, and such substituents are not particularly limited. In light of the dispersibility and moisture resistance of the metal complex, alkyl groups having 6 to 16 carbon atoms are preferred.

Examples of the aryl groups having 6 to 20 carbon atoms represented by R₁₂₅ include a phenyl group, a mesityl group, a tolyl group, a xylyl group, a naphthyl group, an anthryl group, an azulenyl group, an acenaphthenyl group, a fluorenyl group, a phenanthryl group, an indenyl group, a pyrenyl group, and a biphenylyl group. Preferred are a phenyl group, a naphthyl group, a fluorenyl group, a phenanthryl group, a biphenylyl group and a fluorononyl group. Each of the aryl groups may further have a substituent, and such substituent are not particularly limited as long as the advantageous effect of the present invention are not impaired.

Examples of the substituents which the R₁₂₅ may have include alkyl groups (e.g., methyl, ethyl, trifluoromethyl, isopropyl groups, etc.), alkoxy groups (e.g., methoxy, ethoxy groups, etc.), halogen atoms (e.g., a fluorine atom, etc.), a cyano group, a nitro group, dialkylamino groups (e.g., a dimethylamino group, etc.), trialkylsilyl groups (e.g., a trimethylsilyl group, etc.), triarylsilyl groups (e.g., a triphenylsilyl group, etc.), triheteroarylsilyl groups (e.g., a tripyridylsilyl group, etc.), a benzyl group, aryl groups (e.g., a phenyl group, etc.), heteroaryl groups (e.g., pyridyl and carbazolyl groups, etc.). Examples of the fused rings include 9,9′-dimethylfluorene, carbazole, and dibenzofuran. However, the substituents that R₁₂₅ may have are not particularly limited.

In General Formula (I), R₁₂₁ to R₁₂₄ each represent a hydrogen atom or an alkyl group having 1 to 4 carbon atoms, and examples thereof include a methyl group, an ethyl group, a n-propyl group, and a n-butyl group. In light of the dispersibility of the metal complex, a methyl group is particularly preferable.

With regard to R₁₂₁ to R₁₂₄, the compound is characterized by simultaneously having, in its molecular structure, at least one moiety that satisfies the following Condition (i) and at least one moiety that satisfies the following Condition (ii).

Condition (i): all of R₁₂₁ to R₁₂₄ are hydrogen atoms.

Condition (ii): at least one of R₁₂₁ to R₁₂₄ is an alkyl group having 1 to 4 carbon atoms.

The moiety satisfying Condition (ii) includes a structure in which at least one of R₁₂₁ to R₁₂₄ is an alkyl group having 1 to 4 carbon atoms. The moiety satisfying Condition (ii) includes a structure in which two, three or four of R₁₂₁ to R₁₂₄ are the alkyl groups. From the viewpoint of the dispersibility of the metal complex, it is preferable that only one of R₁₂₁ to R₁₂₄ is an alkyl groups having 1 to 4 carbon atoms.

The moiety satisfying Condition (i) is an ethyleneoxide structure in which all of R₁₂₁ to R₁₂₄ are hydrogen atoms, has high ability to form a complex with metal, and contributes to increasing the dispersibility. On the other hand, the moiety satisfying Condition (ii) is an alkyl-substituted ethylene oxide structure, has a large number of components, and contributes to increasing the dispersion stability due to an entropy effect in case of moisture incorporation.

In General Formula (I), j represents the number of moieties in which all of R₁₂₁ to R₁₂₄ defined by Condition (i) are hydrogen atoms. The number is within a range of 1 to 10, preferably within a range of 1 to 3. k represents the number of moieties in which at least one of R₁₂₁ to R₁₂₄ defined by Condition (ii) is an alkyl having 1 to 4 carbon atoms. The number is within a range of 1 to 10, preferably within a range of 1 to 3.

j and k represent the average numbers of moles added of the ethylene oxide structures and the alkyl-substituted ethylene oxide structures, respectively.

In the present application, the term “ethylene oxide structure” refers to a repeating unit structure of polyethylene oxide, i.e., the ring-opened structure of ethylene oxide, which is a three membered cyclic ether. The term “propylene oxide structure” refers to a repeating unit structure of polypropylene oxide, i.e., the ring-opened structure of propylene oxide, which is a three membered cyclic ether, is ring-opened.

In General Formula (I), Z represents a structural unit selected from Formulae (Z-1) and (Z-2).

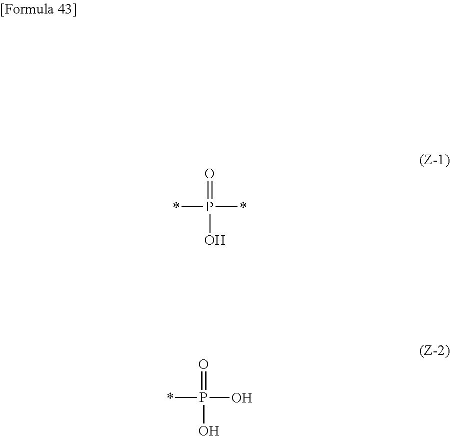

“*” in Formulae (Z-1) and (Z-2) represents a binding site, which binds to O of General Formula (I).

When Z in the above General Formula (I) is Formula (Z-1), the compound is a diester. When Z is Formula (Z-2), the compound is a monoester. In light of the dispersibility of the metal complex, the compound is preferably a mixture of diester and monoester. Among the monoester and the diester, the molar ratio of the monoester is preferably within a range of 20% to 95%.

The compound having the structure represented by the above General Formula (I) can be synthesized with reference to known methods described in, for example, Japanese Unexamined Patent Publication No. 2005-255608, Japanese Unexamined Patent Publication No. 2015-000396, Japanese Unexamined Patent Publication No. 2015-000970, Japanese Unexamined Patent Publication No. 2015-178072, Japanese Unexamined Patent Publication No. 2015-178073, and Japanese Patent No. 4422866.

The content of phosphorus atoms in the near-infrared absorbing film is preferably 1.5 mol or less and mom preferably in a range of 0.3 to 1.3 mol with respect to 1 mol of copper ions. That is, it is very preferable that the content ratio (P/Cu) of phosphorus atoms to copper ions is in the range of 0.3 to 1.3 in molar ratio from the viewpoints of the moisture resistance of the near-infrared absorbing film and the dispersibility of copper ions in the near-infrared absorbing layer.

When P/Cu is less than 0.3 in molar ratio, the amount of copper ions coordinated to the compound represented by General Formula (I) is excessive, and it becomes difficult for the copper ions to be uniformly dispersed in the near-infrared absorbing film. When P/Cu exceeds 1.3 in molar ratio, devitrification tends to occur when the thickness of the near-infrared absorbing film is decreased and the content of copper ions is increased. This tendency is particularly remarkable in a high-temperature and high-humidity environment. Furthermore, it is more preferable that P/Cu is within a range of 0.8 to 1.3 in molar ratio. When the molar ratio is 0.8 or more, the dispersibility of copper ions in a resin can be reliably and sufficiently enhanced.

Hereinafter, the structures of representative exemplary compounds will be described.

Exemplary Compound 1

Exemplary Compound 1 has the following structure as shown in Table I.

R₁₂₅: methyl

Condition (i): R₁₂₁ to R₁₂₄=H

Condition (ii): R₁₂₁=H, R₁₂₂=methyl, R₁₂₃=methyl, R₁₂₄=H

Z: Z-1, Z-2

j: 1.0

k: 8.0

Exemplary Compound 1 is represented by the structures of Exemplary Compound (1-1) in which Z is Z-2 and Exemplary Compound (1-2) in which Z is Z-1.

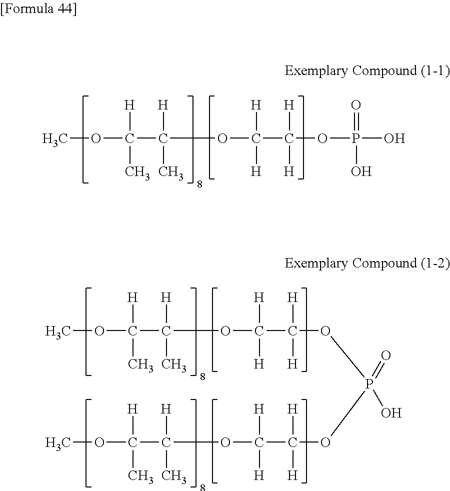

Exemplary Compound 1 has a monoester ratio of 55%, and contains 55% of Exemplary Compound (1-1) and 45% of Exemplary Compound (1-2).

In the present invention, the order of the ethylene oxide structures and the alkyl-substituted ethylene oxide structures is not particularly limited. A compound in which the respective structures are randomly arranged is also included in the compound defined in the present invention. The following Exemplary Compounds (1-3) and (1-4) are also included in Exemplary Compound 1.

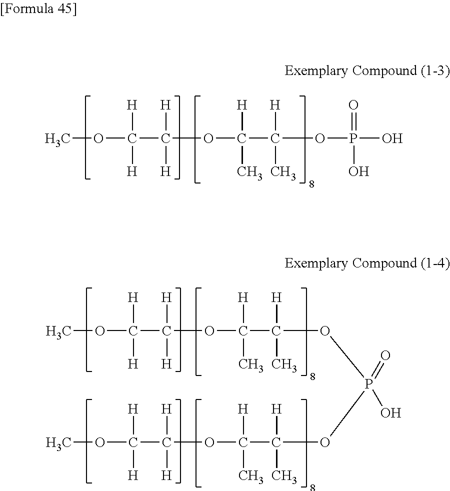

In the present invention, the order of the ethylene oxide structures and the I-substituted ethylene oxide structures is not particularly limited. A compound in which the respective structures are randomly arranged is also included in the compound defined in the present invention.

Exemplary Compound 2

Exemplary Compound 2 has the following structure as shown in Table I.

R₁₂₅: methyl

Condition (i): R₁₂₁ to R₁₂₄=H

Condition (ii): R₁₂₁=H, R₁₂₂=H, R₁₂₃=H, R₁₂₄=methyl

Z: Z-1, Z-2

j: 2.0

k: 3.0

Exemplary Compound 2 is represented by the structures of Exemplary Compound (2-1) in which Z is Z-2 and Exemplary Compound (2-2) in which Z is Z-1.

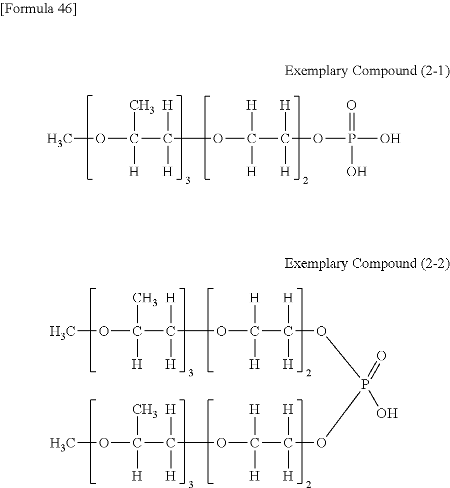

Exemplary Compound 2 has a monoester ratio of 50%, and contains the same molar amount of Exemplary Compound (2-1) and Exemplary Compound (2-2).

As in Exemplary Compound 1, the order of the ethylene oxide structures and the alkyl-substituted ethylene oxide structures in Exemplary Compound 2 can be suitably changed by changing the synthesis method. Exemplary Compound (2-3) and (2-4) below are also included in Exemplary Compound 2.

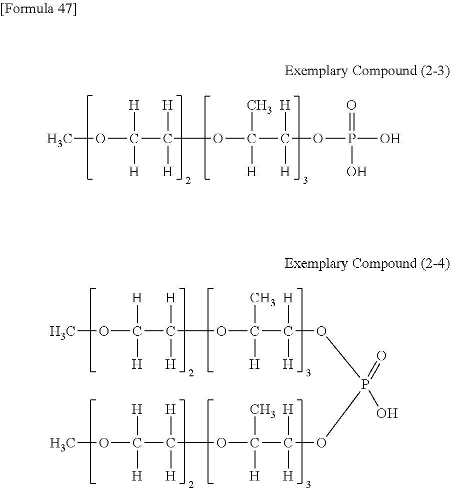

In the present invention, the order of the ethylene oxide structures and the alkyl-substituted ethylene oxide structures is not particularly limited. A compound in which the respective structures are randomly arranged is also included in the compound defined in the present invention.

Next, specific examples of the compound having the structure represented by General Formula (I) are listed in Tables I to IV below, but the present invention is not limited to these Exemplary Compounds.

TABLE I
General Formula (I)

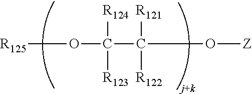

| Exemplary | | Moiety Satisfying | | | | | | | | |
|---|---|---|---|---|---|---|---|---|---|---|
| Compound | | Condition (i) | | Moiety Satisfying Condition (ii) | | | | | | Monoester |
| No. | R₁₂₅ | j | R₁₂₁-R₁₂₄ | k | R₁₂₁ | R₁₂₂ | R₁₂₃ | R₁₂₄ | Z | Ratio (%) |
| 1 | Methyl | 1.0 | H | 8.0 | H | Methyl | Methy | H | Z-1, Z-2 | 55 |
| 2 | Methyl | 2.0 | H | 3.0 | H | H | H | Methyl | Z-1, Z-2 | 50 |
| 3 | Methyl | 3.0 | H | 3.0 | H | H | Methyl | H | Z-1, Z-2 | 70 |
| 4 | Methyl | 1.5 | H | 1.5 | H | H | Ethyl | H | Z-1, Z-2 | 50 |
| 5 | Methyl | 2.0 | H | 3.0 | H | H | Methyl | H | Z-1, Z-2 | 55 |
| 6 | Methyl | 1.0 | H | 3.0 | H | H | Methyl | H | Z-1, Z-2 | 30 |
| 7 | Methyl | 4.0 | H | 3.0 | H | H | Methyl | H | Z-1, Z-2 | 50 |
| 8 | Methyl | 3.0 | H | 3.0 | H | H | Methyl | H | Z-1, Z-2 | 50 |
| 9 | Methyl | 2.5 | H | 2.5 | H | H | Methyl | H | Z-1, Z-2 | 80 |
| 10 | Methyl | 3.0 | H | 5.0 | Methyl | H | H | H | Z-1, Z-2 | 55 |
| 11 | n-Propyl | 2.0 | H | 4.0 | H | H | Methyl | H | Z-1, Z-2 | 40 |
| 12 | n-Propyl | 3.0 | H | 8.0 | H | H | Methyl | H | Z-1, Z-2 | 50 |
| 13 | n-Propyl | 1.5 | H | 1.5 | H | H | Methyl | H | Z-1, Z-2 | 70 |
| 14 | n-Propyl | 3.0 | H | 2.0 | Methyl | H | Methyl | H | Z-1, Z-2 | 50 |
| 15 | n-Propyl | 2.0 | H | 2.0 | H | H | Methyl | H | Z-1, Z-2 | 55 |
| 16 | Isopropyl | 2.0 | H | 3.0 | H | H | Methyl | H | Z-1, Z-2 | 10 |
| 17 | Isopropyl | 4.0 | H | 5.0 | Methyl | H | Methyl | H | Z-1, Z-2 | 20 |
| 18 | Isopropyl | 2.0 | H | 2.0 | H | H | Methyl | H | Z-1, Z-2 | 80 |
| 19 | n-Butyl | 1.0 | H | 1.0 | H | H | Methyl | H | Z-1, Z-2 | 30 |
| 20 | n-Butyl | 3.0 | H | 3.0 | H | H | Methyl | H | Z-1, Z-2 | 50 |
| 21 | n-Butyl | 2.0 | H | 4.0 | H | H | Methyl | H | Z-1, Z-2 | 50 |
| 22 | n-Butyl | 2.5 | H | 2.0 | H | H | Methyl | H | Z-1, Z-2 | 80 |
| 23 | n-Butyl | 3.0 | H | 3.0 | Ethyl | H | H | H | Z-1, Z-2 | 55 |

(Z-1) 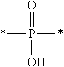 [SMILES: *P(*)(=O)O]
(Z-2)

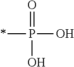 [SMILES: *P(=O)(O)O]

TABLE II

| Exemplary | | Moiety Satisfying | | | | | | | | Monoester |
|---|---|---|---|---|---|---|---|---|---|---|
| Compound | | Condition (i) | | Moiety Satisfying Condition (ii) | | | | | | Ratio |
| No. | R₁₂₅ | j | R₁₂₁-R₁₂₄ | k | R₁₂₁ | R₁₂₂ | R₁₂₃ | R₁₂₄ | Z | (%) |
| 24 | Isobutyl | 3.0 | H | 3.0 | H | H | Methyl | H | Z-1, Z-2 | 50 |
| 25 | Isobutyl | 6.0 | H | 6.0 | H | H | Methyl | H | Z-1, Z-2 | 50 |
| 26 | Isobutyl | 2.0 | H | 2.0 | H | H | Methyl | H | Z-1, Z-2 | 50 |
| 27 | tert-Butyl | 1.5 | H | 2.5 | H | H | Methyl | H | Z-1, Z-2 | 50 |
| 28 | tert-Butyl | 3.0 | H | 3.0 | H | H | Methyl | H | Z-1, Z-2 | 50 |
| 29 | tert-Butyl | 2.0 | H | 2.0 | H | H | Methyl | H | Z-1, Z-2 | 55 |
| 30 | n-Pentyl | 3.0 | H | 4.0 | H | H | Methyl | H | Z-1, Z-2 | 50 |
| 31 | n-Pentyl | 1.0 | H | 2.0 | H | H | Methyl | H | Z-1, Z-2 | 50 |
| 32 | n-Pentyl | 2.0 | H | 2.0 | H | H | Methyl | H | Z-1, Z-2 | 50 |
| 33 | n-Pentyl | 3.0 | H | 3.0 | H | H | Methyl | H | Z-1, Z-2 | 50 |
| 34 | n-Pentyl | 3.0 | H | 3.0 | H | H | Methyl | Methyl | Z-1, Z-2 | 50 |
| 35 | isopentyl | 3.0 | H | 3.0 | H | H | Methyl | H | Z-1, Z-2 | 50 |
| 36 | isopentyl | 8.0 | H | 8.0 | H | H | Methyl | H | Z-1, Z-2 | 50 |
| 37 | isopentyl | 2.0 | H | 2.0 | H | H | Methyl | H | Z-1, Z-2 | 50 |
| 38 | n-Hexyl | 3.0 | H | 3.0 | H | H | Methyl | H | Z-1, Z-2 | 60 |
| 39 | n-Hexyl | 1.5 | H | 1.5 | H | H | Methyl | H | Z-1, Z-2 | 50 |
| 40 | n-Hexyl | 5.0 | H | 5.0 | Methyl | H | Methyl | H | Z-1, Z-2 | 98 |
| 41 | n-Hexyl | 2.0 | H | 2.5 | H | H | Methyl | H | Z-1, Z-2 | 60 |
| 42 | n-Hexyl | 1.0 | H | 1.0 | H | H | Methyl | H | Z-1, Z-2 | 70 |
| 43 | n-Hexyl | 2.0 | H | 1.0 | H | H | Methyl | H | Z-1, Z-2 | 60 |
| 44 | n-Hexyl | 1.0 | H | 3.0 | H | H | Methyl | H | Z-1, Z-2 | 50 |
| 45 | n-Hexyl | 2.0 | H | 4.0 | H | H | Methyl | H | Z-1, Z-2 | 55 |
| 46 | Isohexyl | 1.2 | H | 1.2 | H | H | Methyl | H | Z-1, Z-2 | 50 |
| 47 | Isohexyl | 2.0 | H | 2.0 | H | H | Methyl | H | Z-1, Z-2 | 50 |
| 48 | n-Octyl | 5.0 | H | 5.0 | H | H | Methyl | H | Z-1, Z-2 | 50 |
| 49 | n-Octyl | 2.0 | H | 2.0 | H | H | H | Methyl | Z-1, Z-2 | 50 |
| 50 | n-Octyl | 1.0 | H | 2.0 | H | H | Methyl | H | Z-1, Z-2 | 50 |

TABLE III

| Exemplary | | Moiety Satisfying | | | | | | | | Monoester |
|---|---|---|---|---|---|---|---|---|---|---|
| Compound | | Condition (i) | | Moiety Satisfying Condition (ii) | | | | | | Ratio |
| No. | R₁₂₅ | j | R₁₂₁-R₁₂₄ | k | R₁₂₁ | R₁₂₂ | R₁₂₃ | R₁₂₄ | Z | (%) |
| 51 | n-Octyl | 3.0 | H | 3.0 | H | H | Methyl | H | Z-1, Z-2 | 50 |
| 52 | n-Octyl | 2.0 | H | 1.0 | H | H | Methyl | H | Z-1, Z-2 | 60 |
| 53 | n-Octyl | 2.0 | H | 2.0 | H | H | Methyl | H | Z-1, Z-2 | 55 |
| 54 | 2-ethylhexyl | 2.0 | H | 2.0 | H | H | Methyl | H | Z-1, Z-2 | 40 |
| 55 | 2-ethylhexyl | 3.0 | H | 3.0 | H | H | Methyl | H | Z-1, Z-2 | 30 |
| 56 | 2-ethylhexyl | 2.5 | H | 2.5 | H | H | H | Methyl | Z-1, Z-2 | 50 |
| 57 | 2-ethylhexyl | 1.0 | H | 1.5 | H | H | Methyl | H | Z-1, Z-2 | 60 |
| 58 | 2-ethylhexyl | 1.0 | H | 2.0 | Methyl | H | H | H | Z-1, Z-2 | 30 |
| 59 | 2-ethylhexyl | 3.0 | H | 1.0 | H | H | Methyl | H | Z-1, Z-2 | 55 |
| 60 | Iso-octyl | 5.0 | H | 5.0 | Methyl | H | Methyl | H | Z-1, Z-2 | 18 |
| 61 | Iso-octyl | 1.2 | H | 1.8 | H | H | Methyl | H | Z-1, Z-2 | 50 |
| 62 | Iso-octyl | 3.0 | H | 2.0 | H | H | Methyl | H | Z-1, Z-2 | 50 |
| 63 | Iso-octyl | 2.0 | H | 3.0 | H | H | Methyl | H | Z-1, Z-2 | 50 |
| 64 | n-Decyl | 3.0 | H | 3.0 | H | H | Methyl | H | Z-1, Z-2 | 50 |
| 65 | n-Decyl | 2.0 | H | 2.0 | H | H | Methyl | H | Z-1, Z-2 | 50 |
| 66 | n-Decyl | 3.0 | H | 1.0 | H | H | Methyl | H | Z-1, Z-2 | 50 |
| 67 | n-Decyl | 1.0 | H | 1.0 | H | H | Methyl | H | Z-1, Z-2 | 50 |
| 68 | n-Decyl | 2.0 | H | 5.0 | Methyl | Methyl | H | H | Z-1, Z-2 | 95 |
| 69 | n-Decyl | 3.0 | H | 3.0 | H | H | Methyl | H | Z-1, Z-2 | 55 |
| 70 | Isodecyl | 3.0 | H | 3.0 | H | H | Methyl | H | Z-1, Z-2 | 50 |
| 71 | Isodecyl | 2.0 | H | 2.0 | H | H | Methyl | H | Z-1, Z-2 | 50 |
| 72 | n-Dodecyl | 1.0 | H | 1.5 | H | H | Methyl | H | Z-1, Z-2 | 50 |
| 73 | n-Dodecyl | 2.0 | H | 2.0 | H | H | Methyl | H | Z-1, Z-2 | 60 |
| 74 | n-Dodecyl | 1.0 | H | 1.0 | H | H | Methyl | H | Z-1, Z-2 | 50 |
| 75 | n-Dodecyl | 1.3 | H | 1.7 | H | H | Methyl | H | Z-1, Z-2 | 30 |
| 76 | n-Dodecyl | 5.0 | H | 5.0 | H | H | Butyl | H | Z-1, Z-2 | 50 |
| 77 | n-Dodecyl | 2.0 | H | 2.0 | H | H | Methyl | H | Z-1, Z-2 | 80 |

TABLE IV

| Exemplary | | Moiety Satisfying | | | | | | | | Monoester |
|---|---|---|---|---|---|---|---|---|---|---|
| Compound | | Condition (i) | | Moiety Satisfying Condition (ii) | | | | | | Ratio |
| No. | R₁₂₅ | j | R₁₂₁-R₁₂₄ | k | R₁₂₁ | R₁₂₂ | R₁₂₃ | R₁₂₄ | Z | (%) |
| 78 | 2-butyloctyl | 1.0 | H | 1.0 | H | H | Methyl | H | Z-1, Z-2 | 50 |
| 79 | 2-butyloctyl | 1.0 | H | 2.0 | H | H | Methyl | H | Z-1, Z-2 | 50 |
| 80 | 2-butyloctyl | 2.0 | H | 2.0 | H | H | Methyl | H | Z-1, Z-2 | 50 |
| 81 | 2-butyloctyl | 3.0 | H | 3.0 | H | H | Methyl | H | Z-1, Z-2 | 50 |
| 82 | 2-butyloctyl | 3.0 | H | 3.0 | Methyl | H | H | H | Z-1, Z-2 | 50 |
| 83 | 2-hexyloctyl | 2.0 | H | 2.0 | H | H | Methyl | H | Z-1, Z-2 | 50 |
| 84 | 2-hexyloctyl | 2.0 | H | 3.0 | H | H | Methyl | H | Z-1, Z-2 | 30 |
| 85 | 2-hexyloctyl | 3.0 | H | 3.0 | H | H | Methyl | H | Z-1, Z-2 | 50 |
| 86 | 2-hexyloctyl | 3.0 | H | 1.0 | H | H | Methyl | H | Z-1, Z-2 | 70 |
| 87 | n-Pentadecyl | 3.0 | H | 2.0 | H | H | Methyl | H | Z-1, Z-2 | 50 |
| 88 | n-Pentadecyl | 2.0 | H | 3.0 | H | H | Methyl | H | Z-1, Z-2 | 50 |
| 89 | n-Pentadecyl | 3.0 | H | 3.0 | H | H | Methyl | H | Z-1, Z-2 | 50 |
| 90 | n-Pentadecyl | 1.0 | H | 1.0 | H | H | Methyl | H | Z-1, Z-2 | 50 |
| 91 | n-Stearyl | 3.0 | H | 3.0 | H | H | Methyl | H | Z-1, Z-2 | 70 |
| 92 | n-Stearyl | 1.2 | H | 2.4 | H | H | Methyl | H | Z-1, Z-2 | 70 |
| 93 | n-Stearyl | 5.0 | H | 5.0 | H | H | Methyl | H | Z-1, Z-2 | 60 |
| 94 | n-Stearyl | 3.0 | H | 3.0 | H | H | Methyl | H | Z-1, Z-2 | 50 |
| 95 | n-Stearyl | 3.0 | H | 3.0 | H | H | Methyl | H | Z-1, Z-2 | 55 |
| 96 | Phenyl | 3.0 | H | 3.0 | H | H | Methyl | H | Z-1, Z-2 | 50 |
| 97 | Phenyl | 2.0 | H | 2.0 | H | H | Methyl | H | Z-1, Z-2 | 50 |
| 98 | Phenyl | 1.0 | H | 1.0 | H | H | Methyl | H | Z-1, Z-2 | 50 |
| 99 | Xylyl | 3.0 | H | 3.0 | H | H | Methyl | H | Z-1, Z-2 | 50 |

The compound having the structure represented by the General Formula (I) according to the present invention can be synthesized with reference to known methods described in, for example, Japanese Unexamined Patent Publication No. 2005-255608, Japanese Unexamined Patent Publication No. 2015-000396, Japanese Unexamined Patent Publication No. 2015-000970, Japanese Unexamined Patent Publication No. 2015-178072, Japanese Unexamined Patent Publication No. 2015-178073, and Japanese Patent No. 4422866.

Synthesis of Exemplary Compounds

Next, representative examples of the synthesis of the compound having the structure represented by General Formula (I) according to the present invention will be described, but the present invention is not limited to these synthesis methods.

Synthesis of Exemplary Compound 49

In an autoclave, 130 g (1.0 mol) of n-Octanol 130 g was charged, and 116 g (2.0 mol) of propylene oxide was added thereto using potassium hydroxide as a catalyst under the conditions of a pressure of 147 kPa and a temperature of 130° C. Thereafter, 88 g (2.0 mol) of ethyleneoxide was added thereto.

Next, after confirming that no N-octanol was left, the above adduct was placed in a reaction vessel and reacted with 47 g (0.33 mol) of phosphoric anhydride in toluene at 80° C. for 5 hours. Thereafter, the reaction product was washed with distilled water, and the solvents were distilled off under reduced pressure to obtain Exemplary Compound 49 shown below (R₁₂₅=octyl group, Condition (i): R₁₂₁=H, R₁₂₂=H, R₁₂₃=H, R₁₂₄=H, Condition (ii): R₁₂₁=H, R₁₂₂=H, R₁₂₃=H, R₁₂₄=methyl, j: 2.0, k: 2.0, Z: phosphoric acid monoester (Z-2)/phosphoric acid diester (Z-1)).

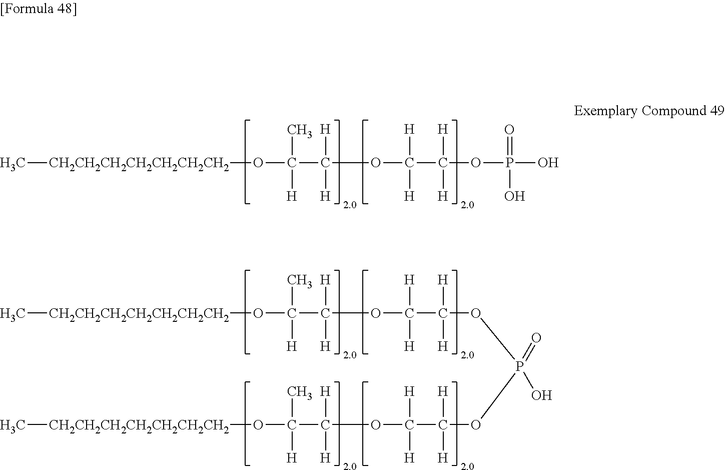

Synthesis of Exemplary Compound 56

In an autoclave, 130 g (1.0 mol) of 22-ethylhexanol was placed, and 145 g (2.5 mol) of propylene oxide was added thereto using potassium hydroxide as a catalyst under conditions of a pressure of 147 kPa and a temperature of 130° C. Thereafter, 110 g (2.5 mol) of ethyleneoxide was added thereto.

Next, after confirming that no 2-ethylhexanol remained, the above adduct was placed in a reaction vessel and reacted with 47 g (0.33 mol) phosphate anhydride in toluene at 80° C. for 5 hours. Thereafter, the reaction product was washed with distilled water, and the solvent was distilled off under reduced pressure to obtain the following Exemplary Compound 56 (R₁₂₅=2-ethylhexyl group, Condition (i): R₁₂₁=H, R₁₂=H, R₁₂₃=H, R₁₂₄=H, Condition (ii): R₁₂₁=H, R₁₂₂=H, R₁₂₃=H, R₁₂₄=methyl, j: 2.5, k: 2.5, Z: phosphate monoester (Z-2)/phosphate diester (Z-1)).

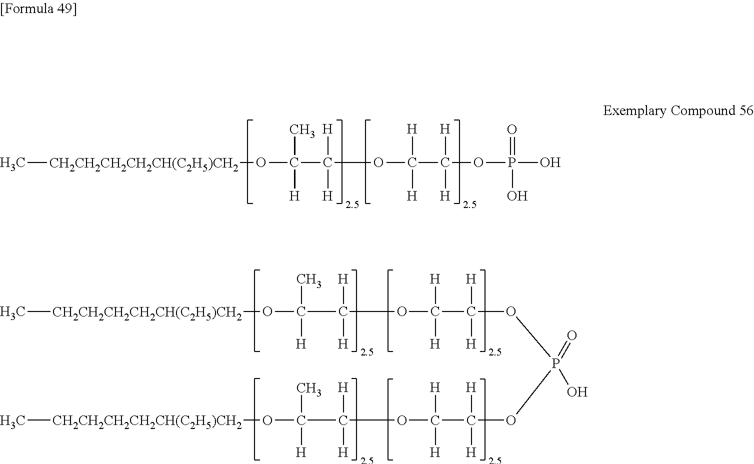

Compound Having Structure Represented by General Formula (D1)

The near-infrared absorbing composition of the present invention preferably further contains a compound having the structure represented by the following General Formula (D1) from the viewpoint of improving the light resistance.

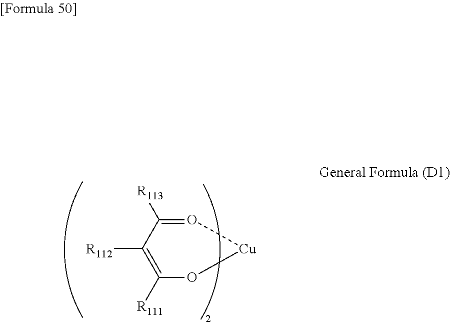

In General Formula (D1), R₁₁₁ and R₁₁₃ each independently represent an alkyl, alkoxy, amino, aryl, or heterocyclic group. R₁₁₂ represents a hydrogen atom, a halogen atom, an alkyl group, an aryl group, a heterocyclic group, a carbonyl group or a cyano group. They may have a substituent.

Generally, squarylium dyes have fluorescence emitting properties, and a squarylium dyes emit (radiate) light in transition from the singlet excited state to the ground state. This leads to deterioration of other squarylium dyes or cyanine dyes present in the surroundings due to photoexcitation. In addition, squarylium dyes themselves in the singlet excited state also cause deterioration of the dyes due to a reaction with compounds such as oxygen present in the surroundings, a cleavage reaction of the molecule, or the like.

Therefore, there is room for improvement in light resistance by quenching the emitted fluorescence. That is, it is conceivable that the copper compound having the structure represented by General Formula (D1) can quench the fluorescence emitted by the squarylium dye due to a heavy atom effect (an effect of a copper atom). Promoting non-radiative deactivation of the squarylium dye from the excited state to the ground state can prevent the degradation of the squarylium dye itself and surrounding dyes due to photoexcitation. This can improve the light resistance.

Since the fluorescence emission generates scattered light, there is a possibility that image quality of a camera equipped with the filter is deteriorated. The squarylium dye used in the present invention also has a fluorescent property. Therefore, by quenching the fluorescence, it is possible to reduce generation of scattered light and to improve the image quality of the camera.

In the present invention, by dissolving and mixing the organic dyes and the copper compound to be used in a solution, it is possible to cause interaction between the organic dyes and the copper ions to quench the fluorescence. The copper compound is preferably a compound having the structure represented by General Formula (D1).

In General Formula (D1), R₁₁₁ and R₁₁₂ each represent an electron-withdrawing group having a Hammet's substitution constant (σp value) of 0.1 or more and 0.9 or less. R₁₁₃ represents an alkyl, aryl, heterocyclic, alkoxy or amino group, which may have a substituent.

Substituents represented by R₁₁₁ and R₁₁₂, which has a op value of 0.1 or more and 0.9 or less, will be described. As used herein, the Hammett's substituent constant op is preferably the value described in the report by Hansch, C. Leo et al. (for example, J. Med. Chem. 16, 1207 (1973); ibid. 20, 304 (1977)).

Examples of the substituents or atoms having a op value of 0.10 or more include a chlorine atom, a bromine atom, an iodine atom, a carboxy group, a cyano group, a nitro group, and halogen-substituted alkyl groups (e.g., trichloromethyl, trifluoromethyl, chloromethyl, trifluoromethylthiomethyl, trifluoromethanesulfonylmethyl, and perfluorobutyl). Examples of the substituents or atoms having a op value of 0.10 or more include an acyl group substituted on an aliphatic, aromatic or heterocyclic ring (e.g., formyl, acetyl, benzoyl). Examples of the substituents or atoms having a op value of 0.10 or mom include a sulfonyl group substituted on an aliphatic, aromatic or heterocyclic ring (e.g., trifluoromethanesulfonyl, methanesulfonyl, and benzenesulfonyl). Examples of the substituents or atoms having a op value of 0.10 or mom include carbamoyl groups (e.g., carbamoyl, methylcarbamoyl, phenylcarbamoyl, 2-chlorophenylcarbamoyl), alkoxycarbonyl groups (e.g, methoxycarbonyl, ethoxycarbonyl, diphenylmethylcarbonyl), substituted aromatic groups (e.g, pentachlorophenyl, pentafluorophenyl, 2,4-dimethanesulfonylphenyl, 2-trifluoromethylphenyl), heterocyclic residues (e.g, 2-benzoxazolyl, 2-benzthiazolyl, 1-phenyl-2-benzimidazolyl, 1-tetrazolyl), azo groups (e.g, phenylazo), a ditrifluoromethylamino group, a trifluoromethoxy group, alkylsulfonyloxy groups (e.g, methanesulfonyloxy), acyloxy groups (e.g, acetyloxy, benzoyloxy), arylsulfonyloxy groups (e.g, benzenesulfonyloxy), phosphoryl groups (e.g, dimethoxyphosphonyl, diphenylphosphoryl), sulfamoyl groups (e.g, N-ethylsulfamoyl, n,N-dipropylsulfamoyl, N-(2-dodecyloxyethyl) sulfamoyl, N-ethyl-N-dodecylsulfamoyl, N,N-diethylsulfamoyl).

Examples of the substituents having a op value of 0.35 or more include a cyano group, a nitro group, a carboxy group, and fluorine-substituted alkyl groups (e.g., trifluoromethyl, perfluorobutyl). Examples of the substituents having a op value of 0.35 or mom include an acyl group substituted on an aliphatic, aromatic or heterocyclic ring (e.g., acetyl, benzoyl, formyl). Examples of substituents having a op value of 0.35 or mom include a sulfonyl group substituted on an aliphatic, aromatic or heterocyclic ring (e.g., trifluoromethanesulfonyl, methanesulfonyl, and benzenesulfonyl). Examples of the substituents having a op value of 0.35 or mom include carbamoyl groups (for example, carbamoyl, methylcarbamoyl, phenylcarbamoyl, 2-chlorophenylcarbamoyl), alkoxycarbonyl groups (e.g., methoxycarbonyl, ethoxycarbonyl, diphenylmethylcarbonyl), a fluorine- or sulfonyl-substituted aromatic groups (e.g, pentafluorophenyl, 2,4-dimethanesulfonylphenyl), heterocyclic residues (e.g., 1-tetrazolyl), azo groups (e.g., phenylazo), alkylsulfonyloxy groups (e.g., methanesulfonyloxy), phosphoryl groups (e.g., dimethoxyphosphoryl, diphenylphosphoryl), and a sulfamoyl group.

Examples of the substituents having a op value of 0.60 or more include a cyano group and a nitro group. Examples of the substituents having a op value of 0.60 or more include a sulfonyl group substituted on an aliphatic, aromatic or heterocyclic ring (e.g., trifluoromethanesulfonyl, difluoromethanesulfonyl, methanesulfonyl, benzenesulfonyl).

Preferred examples of R₁₁₁ and R₁₁₂ include halogenated alkyl groups (particularly fluorine-substituted alkyl groups), a carbonyl groups, a cyano group, alkoxycarbonyl groups, alkylsulfonyl groups, and alkylsulfonyloxy groups. Preferred substituents of R₁₁₃ include alkyl groups, alkoxy groups, and amino groups, and more preferred are alkyl groups or alkoxy groups.

Specific examples of General Formula (D1) are illustrated below, but the present invention is not limited thereto.

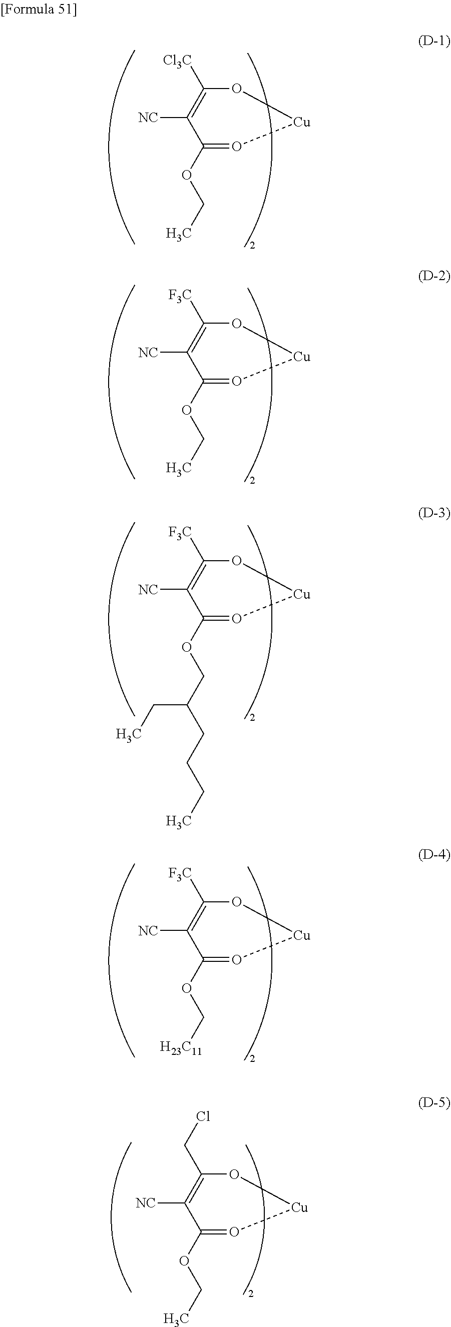

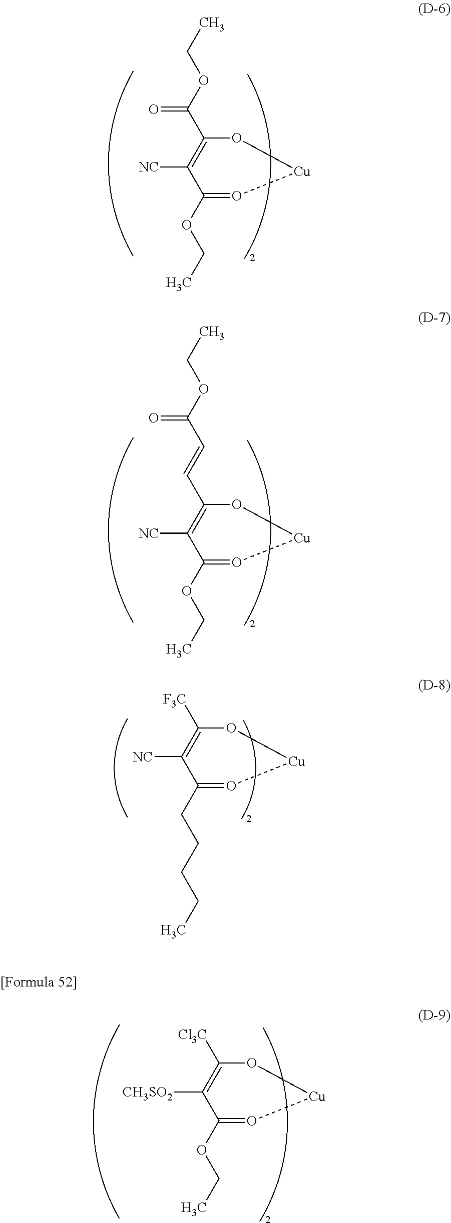

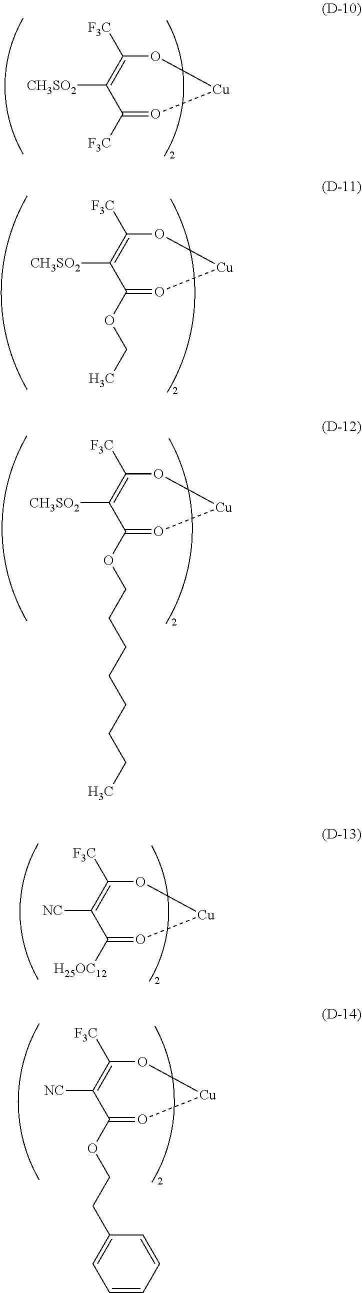

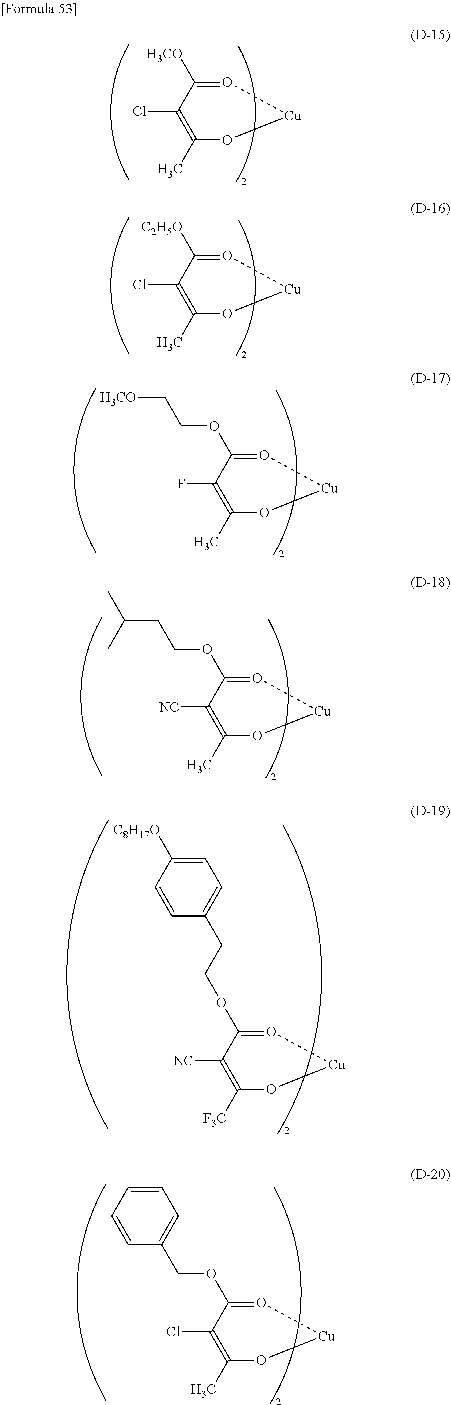

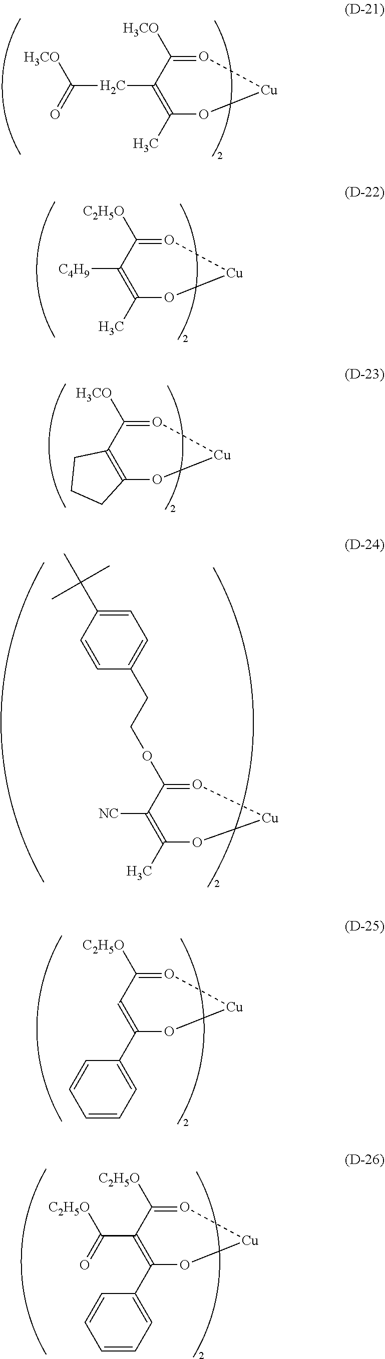

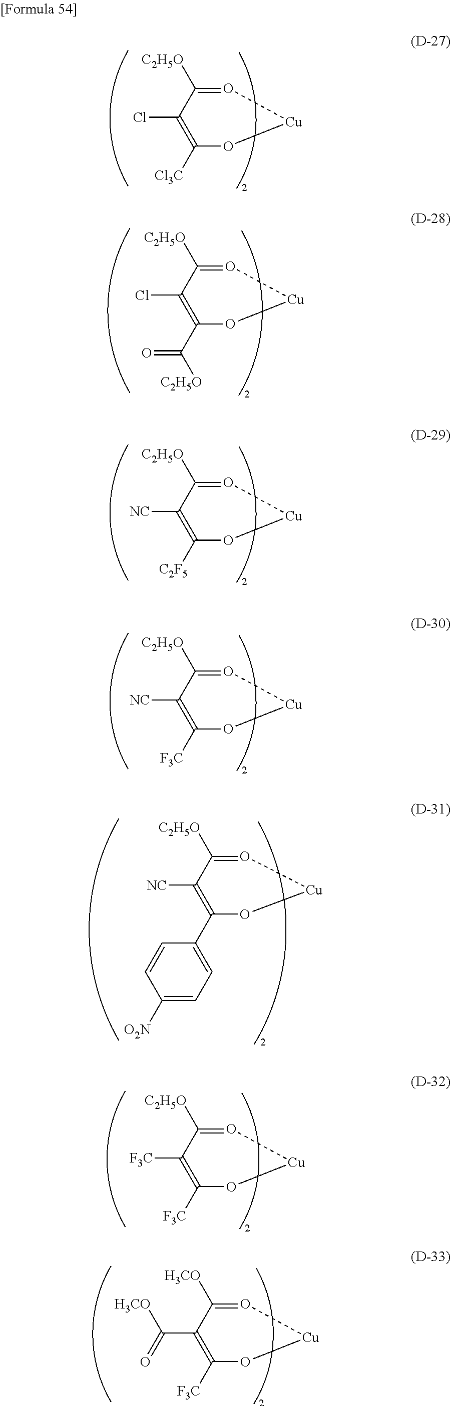

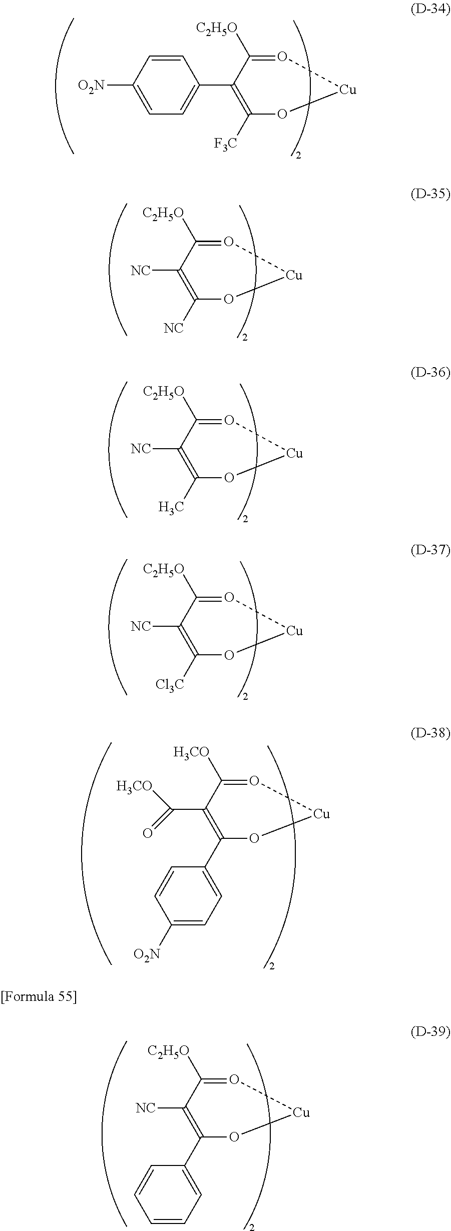

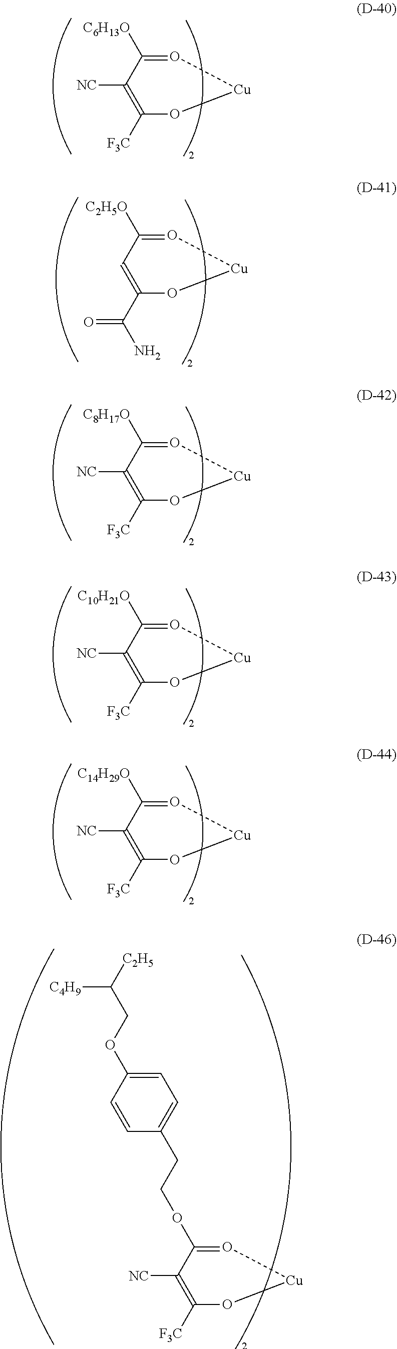

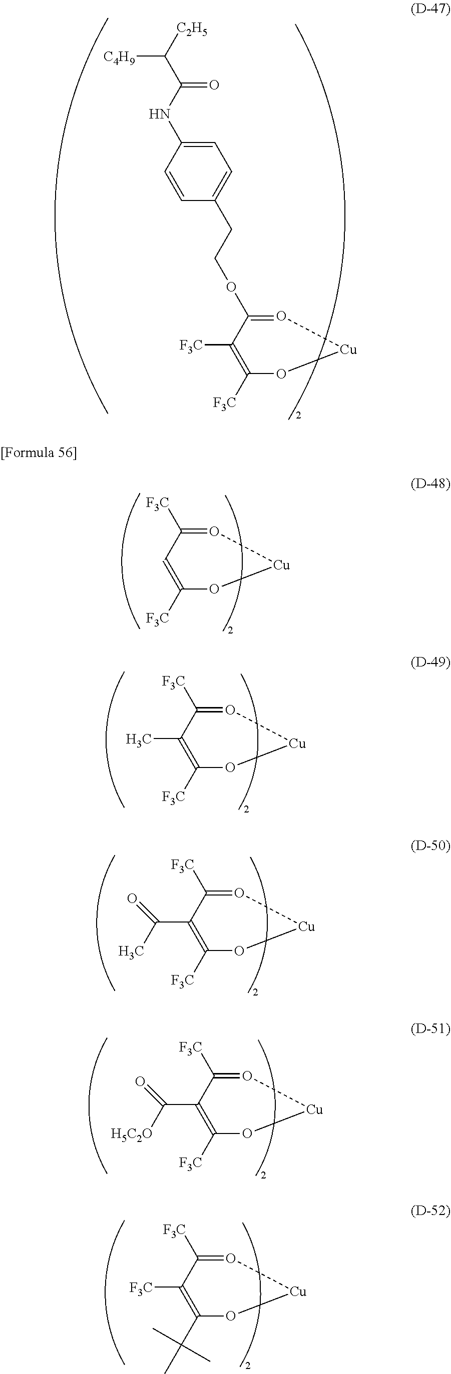

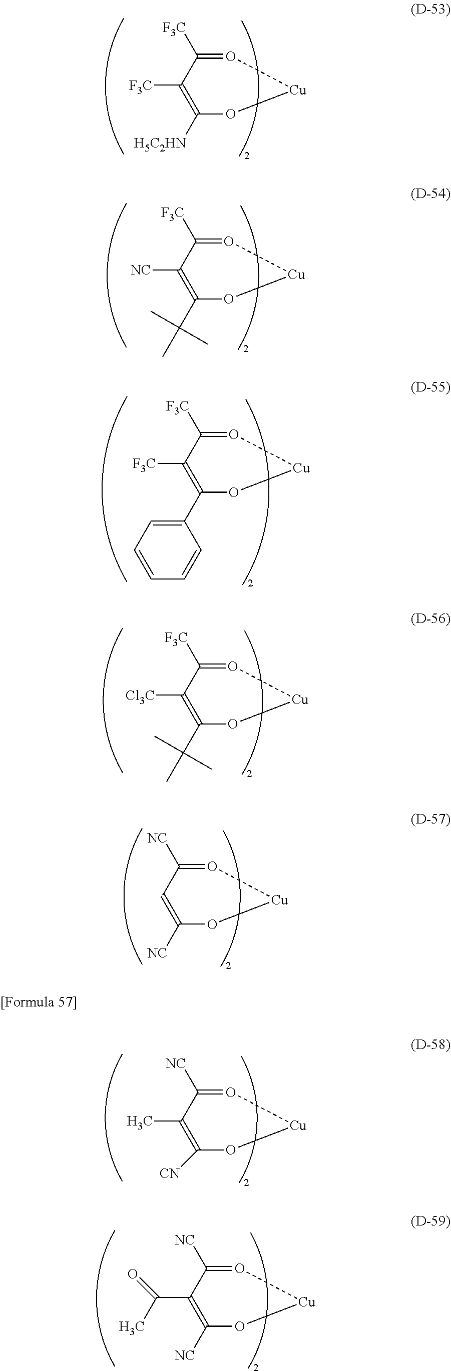

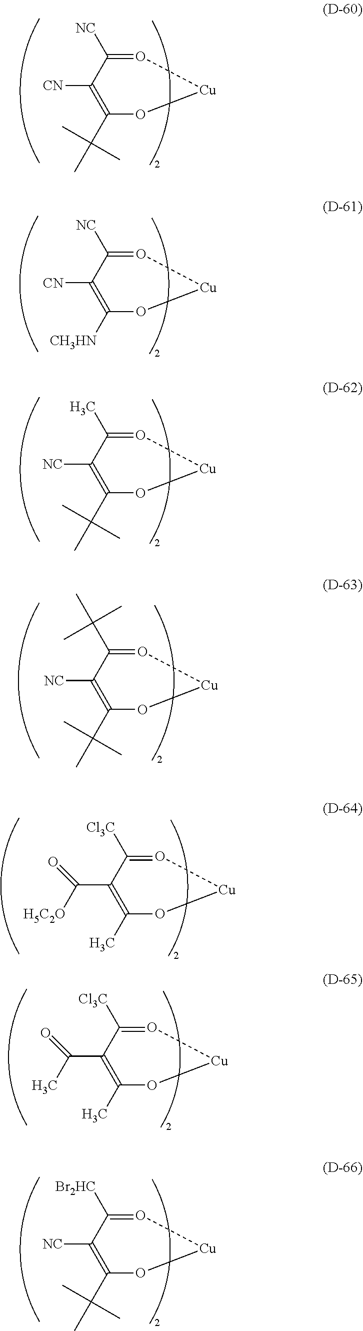

Solvent

Next, solvents applicable to the preparation of the near-infrared absorbing composition according to the present invention will be described.

The solvent used for the near-infrared absorbing composition of the present invention is not particularly limited, and examples thereof include hydrocarbon-based solvents. More preferable are aliphatic hydrocarbon-based solvents, aromatic hydrocarbon-based solvents, and halogen-based solvents.

Examples of the aliphatic hydrocarbon-based solvents include non-cyclic aliphatic hydrocarbon-based solvents such as hexane and heptane, cyclic aliphatic hydrocarbon-based solvents such as cyclohexane, alcohol-based solvents such as methanol, ethanol, n-propanol and ethylene glycol, ketone-based solvent such as methyl ethyl ketone and acetone, ether-based solvents diethyl ether, diisopropyl ether, tetrahtydrofuran, 1,4-dioxane, ethylene glycol mosomethyl ether. Examples of the aromatic hydrocarbon-based solvents include toluene, xylene, mnesitylene, cyclohexybenzene, and isopropybiphenryl. Examples of the halogen-based solvents include mnethylene chloride, 1,1,2-trichloroethane, chloroform. Further examples include anisole, 2-ethylhexane, sec-butyl ether, 2-pentanol, 2-methyltetrahydrofuran, 2-propylene glycol monomethyl ether, 2,3-dimethyl-1,4-dioxane, sec-butylbenzene, 2-methylcyclohexylbenzene. Among these, toluene and tetrahydrofuran are preferable from the viewpoint of the boiling point and solubility.

Solid Content Concentration

The ratio of solid content with respect to the near-infrared absorbing composition is preferably in the range of 5 to 30 mass %. When the content is in the above-described range, the concentration of the solid substance (for example, copper complex fine particles) is appropriate. The particle aggregation during storage is suppressed, and more excellent stability over time can be achieved. As used herein, the “stability over time” refers to the dispersion stability and the near infrared absorbing properties of the copper complex fine particles. The ratio of solid content with respect to the near-infrared absorbing composition is more preferably in the range of 10 to 20 mass %.

Ultraviolet Absorber

The near-infrared absorbing composition of the present invention preferably further contains an ultraviolet absorber from the viewpoints of the spectral characteristics and light resistance.

The ultraviolet absorber is not particularly limited. Examples thereof include benzotriazole-based ultraviolet absorbers, benzophenone-based ultraviolet absorbers, salicylic acid ester-based ultraviolet absorbers, cyanoacrylate-based ultraviolet absorbers, and triazine-based ultraviolet absorbers.

Examples of the benzotriazole-based ultraviolet absorbers include 5-chloro-2-(3,5-di-sec-butyl-2-hydroxyphenyl)-2H-benzotriazole, (2-2H-benzotriazole-2-yl)-6-(straight chain and side chain dodecyl)-4-methylphenol. Some benzotriazole-based ultraviolet absorbers can also be obtained as commercially available products. Examples thereof include TINUVIN® series such as TINUVIN109, TINUVIN171, TINUVIN234, TINUVIN326, TINUVIN327, TINUVIN328, and TINUVIN928, all of which are commercially available products manufactured by BASF SE.

Examples of the benzophenone-based ultraviolet absorbers include 2-hydroxy-4-benzyloxybenzophenone, 2,4-benzyloxybenzophenone, 2,2′-dihydroxy-4-methoxybenzophenone, 2-hydroxy-4-methoxy-5-sulfobenzophenone, and bis(2-methoxy-4-hydroxy-5-benzoylphenylmethane).

Examples of the salicylate ester-based ultraviolet absorbers include phenyl salicylate and p-tert-butyl salicylate.

Examples of the cyanoacrylate-based ultraviolet absorbers include 2′-ethylhexyl-2-cyano-3,3-diphenyl acrylate, ethyl-2-cyano-3-(3′, 4′-methylenedioxyphenyl)-acrylate.

Examples of the triazine-based ultraviolet absorber include 2-(2′-hydroxy-4′-hexyloxyphenyl)-4,6-diphenyltriazine. Examples of commercially available products of the triazine-based ultraviolet absorbers include TINUVIN® 477 (manufactured by BASF SE).

The addition amount of ultraviolet absorber is preferably in the range of 0.1 to 5.0 mass % with respect to 100 mass % of the near-infrared absorber constituting the near-infrared absorbing composition. Note that the term “near-infrared absorber” refers to a phosphonic acid and a copper ion, or a copper phosphonate complex formed from a phosphonic acid and a copper ion, which is contained as a component of the near-infrared absorbing composition.

In a case where the amount of the ultraviolet absorber added is 0.1% by mass or more with respect to 100% by mass of the near-infrared absorber, the light resistance can be sufficiently enhanced. In a case where the amount of the ultraviolet absorber added is 5.0% by mass or less, the visible light transmittance of the obtained near-infrared absorbing composition is not impaired.

Method for Producing Near-Infrared Absorbing Composition

An example of the method for producing the near-infrared absorbing composition of the present invention will be described below. The production method is not limited to the method exemplified here.

A salt of copper such as copper acetate is added to a predetermined solvent such as tetrahydrofuran (THF) and dissolved by stirring, ultrasonic treatment, or the like. Furthermore, a phosphate ester is added thereto to prepare a liquid A. Separately, a phosphonic acid such as ethylphosphonic acid is added to a predetermined solvent such as THF and dissolved with stirring to prepare a liquid B. A mixture solution of the liquid A and the liquid B is stirred at room temperature for ten and several hours to prepare a liquid C. Then, a predetermined solvent such as toluene is added to the liquid C, and the solvent is volatilized by heat treatment at a predetermined temperature to volatilize the solvent to prepare a liquid D. The organic dyes are added to a predetermined solvent such as diacetone alcohol or the like, and the mixture is stirred and dissolved, and this is added to the liquid D to prepare a liquid E. The solid content concentration is adjusted by subjecting the liquid E to a heat treatment at a predetermined temperature to volatilize the solvent, and thus the near-infrared absorbing composition of the present invention can be obtained.

Near-Infrared Absorbing Film

One feature of the present invention is that a near-infrared absorbing film is formed using the above-described various organic dyes and metal compounds or the near-infrared absorbing composition of the present invention.

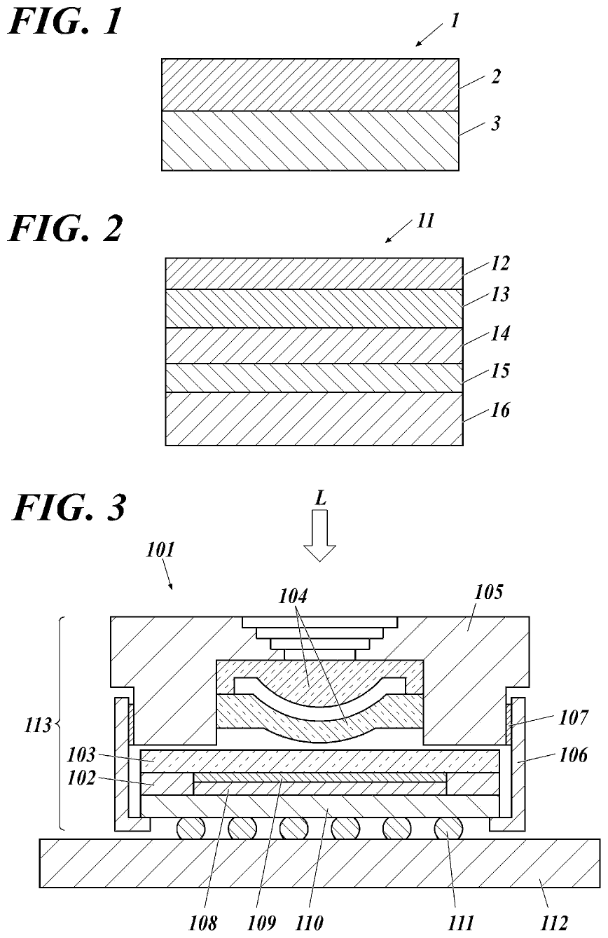

The near-infrared absorbing film of the present invention may have a single-layer configuration containing the organic dyes and the metal compound in the same layer. The near-infrared absorbing film of the present invention may have a two-layer configuration composed of an organic dye-containing layer 3 and a copper phosphonate-containing layer 2 as shown in FIG. 1. However, the near-infrared absorbing film of the present invention is not limited to the configurations exemplified here.

Any of the above-described various organic dyes and metal compounds, and the near-infrared absorbing composition of the present invention can be formed into wet coating liquid. Therefore, the near-infrared absorbing film can be easily manufactured by, for example, a simple process of forming a film by spin coating.

Hereinafter, the method of forming the near-infrared absorbing film will be described. The forming method is also not limited to the method exemplified herein.

Single-Layer Configuration

The near-infrared absorbing film of the present invention may have a single-layer configuration in which the organic dyes and the metal compound are contained in the same layer.

The near-infrared absorbing film having the single-layer configuration is formed as follows. A coating solution prepared by adding a matrix resin to the near-infrared absorbing composition according to the present invention is applied onto a substrate by spin coating or a wet coating method using a dispenser. Thereafter, the coating film is subjected to a predetermined heating treatment to cure the coating film.

The matrix resin used for forming the near-infrared absorbing film is a resin that is transparent to visible light and near-infrared light and can disperse fine particles of a metal complex or a copper phosphonate complex. Metal complexes and copper phosphonate complexes are substances having relatively low polarity and is well dispersed in a hydrophobic material. Therefore, a resin having an acrylic group, an epoxy group, or a phenyl group can be used as the matrix resin for forming the near-infrared absorbing film.

Among them, it is particularly preferable to use a resin having a phenyl group as the matrix resin of the near-infrared absorbing film. In this case, the matrix resin of the near-infrared absorbing film has high heat resistance. Polysiloxane is not easily thermally decomposed, has high transparency to visible light and near-infrared light, and has high heat resistance. Accordingly, polysiloxane has advantageous characteristics as a material for an image sensor of a solid-state imaging device. Therefore, it is also preferable to use polysiloxane as the matrix resin of the near-infrared-absorbing film.

Polysiloxane that can be used as the matrix resin of the near-infrared-absorbing film is available as a commercial product. Examples thereof include KR-255, KR-300, KR-2621-1, KR-211, KR-311, KR-216, KR-212, and KR-251, which are silicone resins manufactured by Shin-Etsu Chemical Co., Ltd.

Other Additives Other additives can be applied to the near-infrared-absorbing film of the present invention to the extent that they do not impair the objects and advantageous effects of the present invention Examples thereof include sensitizers, crosslinking agents, curing accelerators, fillers, thermal curing accelerators, thermal polymerization inhibitors, and plasticizers. In addition, an adhesion promoter to the surface of the base material and other aids (for example, conductive particles, a filler, an antifoaming agent, a flame retardant, a leveling agent, a peeling promoter, an antioxidant, a fragrance, a surface tension adjuster, and a chain transfer agent) may be used in combination.

By appropriately adding these components, it is possible to adjust the properties such as stability and film physical properties of the desired near-infrared absorbing film.

For these components, reference can be made to, for example, the contents described in Japanese Unexamined Patent Publication No. 2012-003225, paragraphs 0183 to 0260, Japanese Unexamined Patent Publication No. 2008-250074, paragraphs 0101 to 0102, Japanese Unexamined Patent Publication No. 2008-250074, paragraphs 0103 to 0104, Japanese Unexamined Patent Publication No. 2008-250074, paragraphs 0107 to 0109, and the like.

Two-Layer Configuration

The near-infrared absorbing film 1 of the present invention may have a two-layer configuration including the organic dye-containing layer 3 and the copper phosphonate-containing layer 2, as illustrated in FIG. 1. The copper phosphonate-containing layer is specifically a layer containing a copper phosphonate complex formed from phosphonic acid and copper ion, or phosphonic acid and copper ion.

For example, impurities contained in fine particles of the copper phosphonate may adversely affect storage properties such as light resistance and heat resistance of the organic dyes. However, with the two layer-configuration or the configuration in which an intermediate layer is further provided, diffusion of these impurities is suppressed, and a decrease in the storage stability can be suppressed. Further the two-layer configuration decreases moisture permeability and improves the heat and moisture resistance.

The mass of the organic dyes contained in the organic dye-containing layer is, for example, in the range of 0.3 to 8 mass % with respect to the mass of the entire final solid content of the organic dye-containing layer. The matrix resin used for forming the organic dye-containing layer is a resin that is transparent to visible light and near-infrared light and can disperse the organic dyes. For example, resins such as polyester, polyacryl, polyolefin, polycarbonate, polycycloolefin, and polyvinyl butyral can be used.

Further, it is preferable that the thickness of the near-infrared absorbing film is in the range of 0.5 to 5 μm. By changing the thickness of the organic dye-containing layer, it is possible to adjust the cutoff wavelength of the near-infrared absorbing film.

The matrix resin used for forming the copper phosphonate-containing layer is a resin that is transparent to visible light and near-infrared light and is capable of dispersing the fine particles of copper phosphonate. Copper phosphonate is a substance having relatively low polarity and is dispersed well in a hydrophobic material. For example, a resin having an acrylic group, an epoxy group, or a phenyl group can be used. In light of the heat resistance, it is particularly preferable to use a resin having a phenyl group. In addition, from the viewpoint of transparency to visible light and near infrared light and heat resistance, it is preferable to use polysiloxane (silicone resin). The mass of the fine particles of copper phosphonate contained in the copper phosphonate-containing layer is, for example, in the range of 15 to 45 mass % with respect to the total mass of the final solid content of the copper phosphonate-containing layer.

An average particle size of the fine particles of copper phosphonate is, for example, within the range of 5 to 200 nm, and desirably within the range of 5 to 100 nm. When the average particle size of the fine particles of copper phosphonate is 5 nm or more, it is possible to prevent the structure of copper phosphonate from being destroyed without requiring a special step for refining the fine particles of copper phosphonate. When the average particle size of the fine particles of the copper phosphonate is 200 nm or less, there is almost no influence of light scattering such as Mie scattering, and it is possible to prevent a decrease of the light transmittance. In addition, it is possible to prevent a decrease in the performance such as contrast and haze of an image to be formed by the imaging device. When the average particle diameter of the fine particles of copper phosphonate is 100 nm or less, the influence of Raryleigh scattering is reduced, and thus the transparency in the visible light region of the copper phosphonate-containing layer is further increased.

The thickness of the copper phosphonate-containing layer is, for example, within the range of 30 to 200 μm. Preferably, the thickness is within the range of 30 to 120 μm. Within this range, for example, the average light transmission in the wave range of 800 to 1100 nm of the near-infrared absorbing film can be reduced to 5% or less. In addition, the average light transmission rate in the range of 450 to 600 nm of the near-infrared absorbing film can be maintained high, for example, 70% or higher.

The organic dye-containing layer 3 of the near-infrared absorbing film having the two-layer configuration can be formed, for example, as follows. A coating liquid of the organic dye-containing layer, which is prepared by adding the desired organic dyes of the present invention and the matrix resin to a solvent, is applied onto a substrate by spin coating or a wet coating method using a dispenser. Thereafter, the coating film is subjected to a predetermined heating treatment to cure the coating film. The coating method is preferably spin coating. The thickness of the organic dye-containing layer can be finely adjusted by adjusting the rotational speed of the spin coater.

The copper phosphonate-containing layer 2 can be formed, for example, as follows. A copper salt such as copper acetate is added to a predetermined solvent such as tetrahydrofuran (THF) and dissolved therein by sonication or the like. Furthermore, a phosphate ester is added thereto to prepare a liquid A. Separately, a phosphonic acid such as ethylphosphonic acid is added to a predetermined solvent such as THF, and the mixture is stirred to prepare a liquid B. A mixture solution of the liquid A and the liquid B is stirred at room temperature for ten and several hours to prepare a liquid C. Then, a predetermined solvent such as toluene is added to the liquid C, and the solvent is volatilized by heat treatment at a predetermined temperature to volatilize the solvent to prepare a liquid D.

Next, a matrix resin such as a silicone resin is added to the liquid D (dispersion of fine particles of copper phosphonate), and the mixture is stirred to prepare a coating liquid of the copper phosphonate-containing layer. The prepared coating solution is applied onto a substrate by spin coating or a wet coating method using a dispenser, and thereafter, the coating film is subjected to a predetermined heat treatment to cure the coating film. Even in the formation of the near-infrared absorbing film having the two-layer configuration, the same matrix resin and additive as those of the single-layer configuration can be used.

Near-Infrared Absorbing Filter One characteristic of the near-infrared-absorbing filter of the present invention is that it is formed using the near-infrared absorbing film of the present invention. For example, it can be easily produced by a coating method.

The near-infrared absorbing film used in the near-infrared absorbing filter of the present invention may have a single-layer configuration, but preferably has a two-layer configuration. For the layer arrangement of the near-infrared absorption filter having a two-layer configuration, for example, reference can be made to U.S. Pat. No. 6,619,828.

FIG. 2 illustrates an example of the near-infrared absorbing filter made of the near-infrared absorbing film having a two-layer configuration. The near-infrared absorbing filter of the present invention is not limited to the configuration exemplified here.

When the copper phosphonate-containing layer is formed and thereafter the organic dye-containing layer is formed on the surface of the copper phosphonate-containing layer, there is a possibility that the characteristics of the copper phosphonate-containing layer are not sufficiently exhibited. Therefore, it is preferable to form the organic dye-containing layer and thereafter form the copper phosphonate-containing layer on the surface of the organic dye-containing layer.

In addition, from the viewpoint of sufficiently exhibiting the characteristics of the near infrared-absorbing filter, it is preferable that a transparent substrate or an intermediate protective layer is interposed between the organic dye-containing layer and the copper phosphonate-containing layer.

Further, the near-infrared absorbing filter of the present invention may include an anti-reflection layer on the filter surface. This can improve the light transmittance in the visible light region. When the near-infrared absorption filter is used in an imaging apparatus such as a digital camera, an image with high brightness can be obtained.

The near-infrared absorption filter of the present invention preferably has a film thickness in the range of 30 to 120 μm from the viewpoint of improving the light transmittance in the visible light region.

In addition, the near-infrared absorbing film of the present invention is suitable for, for example, a luminosity correction member for a CCD, a CMOS, or other light-receiving elements, a light measuring component, a heat absorber, a composite optical filter, a lens member (spectacles, sunglasses, goggles, an optical system, an optical waveguide system), a fiber component (optical fiber), a noise cutting component, a display cover or display filter such as a front panel of a plasma display, a front panel of a projector, a member for cutting heat rays of a light source, a color-tone corrector, an illumination brightness adjustment member, an optical element (a light amplification element, a wavelength conversion element, or the like), a Faraday element, an optical communication device such as an isolator, an element for an optical disk, and the like.

Image Sensor for Solid-State Imaging Element One characteristic of the image sensor for solid-state imaging element of the present invention is that it is formed using the near-infrared ray absorption filter of the present invention. In more detail, the image sensor for a solid-state imaging element of the present invention is characterized by application as a near-infrared absorbing filter provided on the light receiving side of a solid-state imaging element substrate, for example, a near-infrared absorbing filter for a wafer-level lens. In addition, another characteristic is application to an image sensor for a solid-state imaging element as a near-infrared absorbing filter or the like provided on the rear surface side of the solid-state imaging element substrate. As used herein, the “rear surface side” refers to the surface opposite to the light receiving side.

By applying the near-infrared absorbing filter of the present invention to an image sensor for a solid-state image sensing device, it is possible to improve the transmittance in the visible light region, the heat resistance, and the light resistance.

FIG. 3 is a schematic cross-sectional view showing the configuration of a camera module including a solid-state imaging device with the near-infrared absorbing filter of the present invention.

The camera nodule 101 illustrated in FIG. 3 is connected to the circuit board 112, which is a mounting board, via the solder balls 111, which are connecting members.

Specifically, the camera module 101 includes a solid-state imaging element substrate 110 including an imaging element portion 113 on a first main surface of a silicone substrate. The camera module 101 includes a flattening layer 108 provided on the first main surface-side (light receiving side) of the solid-state imaging element substrate 110. The camera module 101 includes a near-infrared absorbing filter 109 provided on the flattening layer 108. The camera module 101 includes a glass substrate 103 (light-transmissive substrate) disposed above the near-infrared absorbing filter 109. The camera module 101 includes a lens holder 105 that is arranged above the glass substrate 103 and includes an imaging lens 104 in an internal space. The camera module 101 includes a light and electromagnetic shield 106 that is arranged so as to surround the peripheries of the solid-state imaging element substrate 110 and the glass substrate 103. These members are attached by adhesives 102 and 107.

A method of manufacturing the camera module including the solid-state imaging element substrate and the infrared absorbing filter disposed on the light receiving side of the solid-state imaging element substrate will be described. In this case, the near-infrared absorbing film can be formed by spin-coating the infrared absorbing composition of the present invention described above on the light receiving side of the solid-state imaging element substrate. The near-infrared absorbing film may have a single-layer configuration or a two-layer configuration.

The infrared absorbing filter 109 of the camera module 101 is formed by, for example, spin-coating the above-described organic dyes and metal compound or the near-infrared absorbing composition of the present invention on the flattening layer 108 to form the near-infrared absorbing film.

In the camera module 101, incident light L from the outside is sequentially transmitted through the imaging lens 104, the glass substrate 103, the infrared absorbing filter 109, and the flattening layer 108. Thereafter, the light L reaches the imaging element portion of the solid-state imaging element substrate 110.

The camera module 101 is connected to the circuit board 112 via solder balls 111 (connection material) on the second main surface side of the solid-state imaging element substrate 110.

### EXAMPLES

Hereinafter, the present invention will be specifically described with reference to Examples, but the present invention is not limited thereto. In the examples, “part(s)” and “%” represent “part(s) by mass” and “% by mass”, respectively, unless otherwise specified.

### Example 1

Preparation of Near-Infrared Absorbing Composition

Synthesis of Dyes

With reference to the above-described synthesis examples and known methods, dyes A1-1, 2, 6, 9, 12, 17, A2-2, 6, 7, 10, A3-1, 5, 11, A4-1, 2, 5, 8, 13, B1-2, 3, 4, 6, 9, C1-1, 4, 5, 7, 8, C2-9, 12, 13, 15, 18, 22, 23, 25, and 28 were synthesized.

Synthesis of Exemplary Compounds of Compound Having Structure Represented by General Formula (I) Exemplary compounds 7, 13, 19, 42, 54, 65, 72, and 77 of the compound having the structure represented by General Formula (I) were synthesized with reference to the known methods described above.

Synthesis of Compound Having Structure Represented by General Formula (D1) Compounds D-3, 19 and 43 having the structure represented by General Formula (D1) were synthesized with reference to the known methods described in Japanese Unexamined Patent Publication Nos. 2007-31425 and 2007-34264.

Preparation of Near-Infrared Absorbing Composition 1

A near-infrared absorbing composition 1 was prepared according to the following method.

Copper (II) acetate monohydrate (manufactured by Kanto Chemical Corporation) (2.0 g) were mixed with 82 g of tetrahydrofuran (THF) as a solvent and stirred for 3 hours. Then, undissolved copper acetate was removed by filtration to prepare a copper acetate solution. Hereinafter, copper (II) acetate monohydrate is also simply referred to as “copper acetate”.

Exemplified Compound 72 (1.75 g), which is a compound having the structure represented by General Formula (I), was dissolved in 7.0 g of tetrahydrofuran (THF) to prepare a solution. This solution was added to the above copper acetate solution over 30 minute with stirring to prepare a liquid A.

Next, 0.88 g of propylphosphonic acid (manufactured by Tokyo Chemical Industry Corporation) was dissolved in 7.0 g of tetrahydrofuran (THF) to prepare a liquid B.

The liquid B was added to the liquid A with stirring the liquid A, and then, Stirring was continued at room temperature for 16 hours to prepare a liquid C. Next, the liquid C and toluene 30 g were put into a flask. While being heated at 50 to 100° C. in an oil bath (manufactured by TOKYO RIKAKIKAI CO., LTD., model: OSB-2100), this was subjected to a solvent and acetic acid removal treatment for 30 minutes with a rotary evaporator (manufactured by TOKYO RIKAKIKAI CO., LTD., model: N-1000) to prepare a liquid D.

Further, the organic dyes shown below were dissolved in 36 g of diacetone alcohol. This was added to the liquid D to prepare a liquid E.

Dye A1-1: 2.00 mg

Dye C1-1: 2.20 mg

The liquid E was placed in a flask. While being heated at 55 to 90° C. in an oil bath (manufactured by TOKYO RIKAKIKAI CO., LTD., model: OSB-2100), the liquid E was subjected to a solvent-removal and acetic acid-removal treatment for 3 hours using a rotary evaporator (manufactured by TOKYO RIKAKIKAI CO., LTD., model: N-1000).

Thereafter, the amount of the solvent was adjusted so that the solid content concentration of the liquid E in the flask became 10% by mass, and this was used as a near-infrared absorbing composition 1.

Preparation of Near-Infrared Absorbing Composition 2

The organic dyes in the preparation of the near-infrared absorbing composition 1 was changed to the organic dyes shown in Table V. In addition, the compound S1 was used instead of the compound having the structure represented by General Formula (I). A near-infrared absorbing composition 2 was prepared by the same procedure except for the above matters. The structural formula and synthesis method of the compound S1 are described below.

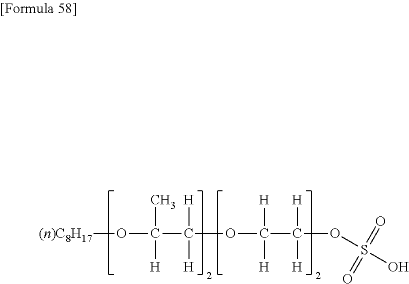

n-Octanol (130 g, 1.0 mol) was placed in an autoclave. Propylene oxide (116 g, 2.0 mol) was added thereto using potassium hydroxide as a catalyst under conditions of a pressure of 147 kPa and a temperature of 130° C. Thereafter, 88 g (2.0 mol) of ethyleneoxide was added thereto. Then, after confirming that no N-octanol remained, the above adduct was taken into a reactor. Chlorosulfonic acid (117 g, 1.0 mol) was added dropwise to a toluene solution of the adduct over about 1 hour to cause a reaction. Thereafter, the reaction product was washed with distilled water, and the solvent was distilled off under reduced pressure to obtain a compound S1.

Preparation of Near-Infrared Absorbing Compositions 3 to 13

The organic dyes in the preparation of the near-infrared absorbing composition 1 were changed to the organic dyes and the compounds having the structure represented by General Formula (I) shown in Table V. Near-infrared absorbing compositions 3 to 13 were prepared by the same procedure except for the above matters.

Preparation of Near-Infrared Absorbing Compositions 14 and 16 to 21

The organic dyes in the preparation of the near-infrared absorbing composition 1 was changed to the organic dyes and the compounds having the structure represented by General Formula (I) shown in Table VI. In addition, octylphosphonic acid was used instead of propylphosphonic acid. Near-infrared absorbing compositions 14 and 16 to 21 were prepared by the same procedure except for the above matters.

Preparation of Near-Infrared Absorbing Composition 15

The organic dyes in the preparation of the near-infrared absorbing composition 1 was changed to the organic dyes and the compounds having the structure represented by General Formula (I) shown in Table VI. In addition, octylphosphonic acid was used instead of propylphosphonic acid, and the addition amount thereof was reduced to 80%. A near-infrared absorbing composition 15 was prepared by the same procedure except for the above matters.

Preparation of Near-Infrared Absorbing Compositions 22 and 23

The organic dyes in the preparation of the near-infrared absorbing composition 1 was changed to the organic dyes and the compounds having the structure represented by General Formula (I) shown in Table VI. Further, octylphosphonic acid was used in place of propylphosphonic acid, and the compound having the structure represented by the general formula (D1) shown in Table VI was added. Near-infrared absorbing compositions 22 and 23 were prepared by the same procedure except for the above matters.

The procedure for adding the compound having the structure represented by General Formula (D1) is shown below.

Solution E was prepared by adding D-3 or D-19, which is a compound having the structure represented by General Formula (D1), to Solution D together with the organic dyes in an amount of 50% by mass of the organic dyes. The subsequent treatments were performed in the same procedure as in the preparation of the near-infrared absorbing composition 1.

Preparation of Near-Infrared Absorbing Compositions 24 to 35

The organic dyes in the preparation of the near-infrared absorbing composition 1 was changed to the organic dyes shown and the compounds having the structure represented by the General Formula (I) shown in Tables VI and VII. In addition, the compounds having the structure represented by General Formula (D1) shown in Tables VI and VII were added. Except for this, near-infrared absorbing compositions 24 to 35 were prepared by the same procedure. The compound having the structure represented by General Formula (D1) was added by the same procedure as described above.

Preparation of Near-Infrared Absorbing Composition 36

A near-infrared absorbing composition 36 was prepared according to the same procedure as in the preparation of the near-infrared absorbing composition 1, except that phenylphosphonic acid was used instead of propylphosphonic acid.

Preparation of Near-Infrared Absorbing Composition 37: Comparative Example

The organic dyes in the preparation of the near-infrared absorbing composition 1 was changed to the organic dye (diimmonium colorant: KAYASORB IRG-022) and the compound having the structure represented by General Formula (I) shown in Table VII. A near-infrared absorbing composition 37 was prepared by the same procedure except for the above matter.

Preparation of Near-Infrared Absorbing Composition 38: Comparative Example

The organic dyes in the preparation of the near-infrared absorbing composition 1 was changed to the organic dye (diimmonium colorant: KAYASORB IRG-022) and the compound having the structure represented by General Formula (I) shown in Table VII. The compound having the structure represented by the General Formula (D1) shown in Table VII was also added. A near-infrared absorbing composition 38 was prepared by the same procedure except for the above matters.

Preparation of Near-Infrared Absorbing Composition 39: Comparative Example

In the preparation of the near-infrared absorbing composition 1, propylphosphonic acid and the compound having the structure represented by General Formula (I) were not added. A near-infrared absorbing composition 39 was prepared by the same procedure except for the above matter.

Preparation of Near-Infrared Absorbing Composition 40: Comparative Example

The organic dyes used in the preparation of the near-infrared absorbing composition 1 were changed to the organic dyes ((a-18)) and (c-1) described in Japanese Patent No. 6331392) listed in Table VII. In addition, the compound having the structure represented by General Formula (I) was changed. A near-infrared absorbing composition 40 was prepared by the same procedure except for the above matters.

The organic dyes, the phosphonic acids, the compounds having the structure represented by General Formula (I), and the compounds having the structure represented by General Formula (D1), which are used in the preparation of the near-infrared absorbing composition, will be described below. In addition, in the examples, the amounts of phosphonic acid and the compound having the structure represented by the General Formula (I) added were respectively 0.76 mol and 0.28 mol with respect to 1 mol of cupper acetate.

* The amount of octylphosphonic acid added in Table VI was reduced to 80%.

TABLE V

| | Organic Dyes | | | | | | | | | | |
|---|---|---|---|---|---|---|---|---|---|---|---|
| | Group A | | | | Group B | Group C | | | | | |
| | A1 | A2 | A3 | A4 | B1 | C1 | C2 | | | | |
| | Amount | Amount | Amount | Amount | Amount | Amount | Amount | | General | | |
| Composition | Added | Added | Added | Added | Added | Added | Added | Phosphonic | Formula | | |
| No. | (mg) | (mg) | (mg) | (mg) | (mg) | (mg) | (mg) | Acid H1 | (I) | D1 | Remarks |
| 1 | A1-1 | — | — | — | — | C1-1 | — | Propylphosphonic | Exemplary | — | Inventive |
| | 2.0 | | | | | 2.2 | | acid | Compound 72 | | |
| 2 | A1-17 | — | — | — | — | C1-7 | — | Propylphosphonic | S1 | — | Inventive |
| | 2.0 | | | | | 2.2 | | acid | | | |
| 3 | A1-2 | — | — | — | — | — | C2-15 | Propylphosphonic | Exemplary | — | Inventive |
| | 2.0 | | | | | | 2.0 | acid | Compound 72 | | |
| 4 | A1-12 | — | — | A4-1 | — | — | C2-9 | Propylphosphonic | Exemplary | — | Inventive |
| | 1.8 | | | 0.1 | | | 2.0 | acid | Compound 72 | | |
| 5 | A1-2 | — | — | — | — | — | C2-23 | Propylphosphonic | Exemplary | — | Inventive |
| | 2.0 | | | | | | 2.0 | acid | Compound 19 | | |
| 6 | — | A2-6 | — | — | — | C1-1 | — | Propylphosphonic | Exemplary | — | Inventive |
| | | 1.0 | | | | 1.4 | | acid | Compound 7 | | |
| 7 | — | A2-2 | — | — | — | — | C2-15 | Propylphosphonic | Exemplary | — | Inventive |
| | | 1.5 | | | | | 1.0 | acid | Compound 13 | | |
| 8 | — | — | A3-1 | — | — | C1-5 | — | Propylphosphonic | Exemplary | — | Inventive |
| | | | 1.2 | | | 0.9 | | acid | Compound 54 | | |
| 9 | — | — | A3-1 | — | — | — | C2-15 | Propylphosphonic | Exemplary | — | Inventive |
| | | | 1.4 | | | | 1.0 | acid | Compound 65 | | |
| 10 | — | — | — | A4-1 | — | C1-8 | — | Propylphosphonic | Exemplary | — | Inventive |
| | | | | 1.2 | | 0.9 | | acid | Compound 54 | | |
| 11 | — | — | — | A4-5 | — | — | C2-15 | Propylphosphonic | Exemplary | — | Inventive |
| | | | | 0.6 | | | 1.5 | acid | Compound 72 | | |
| 12 | A1-2 | — | — | A4-1 | — | — | C2-23 | Propylphosphonic | Exemplary | — | Inventive |
| | 0.6 | | | 0.6 | | | 2.0 | acid | Compound 72 | | |
| 13 | — | A2-2 | — | A4-1 | — | — | C2-15 | Propylphosphonic | Exemplary | — | Inventive |
| | | 0.6 | | 0.8 | | | 1.0 | acid | Compound 42 | | |

TABLE VI

| | Organic Dyes | | | | | | | | | | |
|---|---|---|---|---|---|---|---|---|---|---|---|
| | Group A | | | | Group B | Group C | | | | | |
| | A1 | A2 | A3 | A4 | B1 | C1 | C2 | | | | |
| | Amount | Amount | Amount | Amount | Amount | Amount | Amount | | General | | |
| Composition | Added | Added | Added | Added | Added | Added | Added | Phosphonic | Formula | | |
| No. | (mg) | (mg) | (mg) | (mg) | (mg) | (mg) | (mg) | Acid H1 | (I) | D1 | Remarks |
| 14 | — | — | — | A4-8 | — | — | C2-15 | Octylphosphonic | Exemplary | — | Inventive |
| | | | | 1.8 | | | 0.8 | acid | Compound 42 | | |
| 15 | — | — | — | A4-8 | — | — | C2-15 | *Octylphosphonic | Exemplary | — | Inventive |
| | | | | 1.8 | | | 0.8 | acid | Compound 13 | | |
| 16 | — | — | — | — | B1-2 | C1-1 | — | Octylphosphonic | Exemplary | — | Inventive |
| | | | | | 1.8 | 1.0 | | acid | Compound 65 | | |
| 17 | — | — | — | — | B1-3 | — | C2-15 | Octylphosphonic | Exemplary | — | Inventive |
| | | | | | 1.0 | | 2.6 | acid | Compound 72 | | |
| 18 | — | — | — | — | B1-6 | — | C2-15 | Octylphosphonic | Exemplary | — | Inventive |
| | | | | | 1.5 | | 2.3 | acid | Compound 77 | | |
| 19 | — | — | — | — | B1-3 | — | C2-23 | Octylphosphonic | Exemplary | — | Inventive |
| | | | | | 1.2 | | 2.0 | acid | Compound 77 | | |
| 20 | — | — | — | — | B1-9 | — | C2-22 | Octylphosphonic | Exemplary | — | Inventive |
| | | | | | 1.2 | | 2.0 | acid | Compound 72 | | |
| 21 | — | — | — | — | B1-4 | — | C2-25 | Octylphosphonic | Exemplary | — | Inventive |
| | | | | | 1.2 | | 2.0 | acid | Compound 65 | | |
| 22 | A1-2 | — | — | — | — | — | C2-23 | Octylphosphonic | Exemplary | D-3 | Inventive |
| | 2.0 | | | | | | 2.0 | acid | Compound 72 | | |
| 23 | A1-6 | — | — | — | — | C1-7 | — | Octylphosphonic | Exemplary | D-19 | Inventive |
| | 2.0 | | | | | 2.2 | | acid | Compound 7 | | |
| 24 | A1-9 | — | — | — | — | — | C2-12 | Propylphosphonic | Exemplary | D-3 | Inventive |
| | 2.0 | | | | | | 2.0 | acid | Compound 72 | | |
| 25 | — | A2-2 | — | — | — | — | C2-15 | Propylphosphonic | Exemplary | D-43 | Inventive |
| | | 1.5 | | | | | 1.0 | acid | Compound 7 | | |
| 26 | — | A2-7 | — | — | — | C1-4 | — | Propylphosphonic | Exemplary | D-19 | Inventive |
| | | 1.5 | | | | 1.4 | | acid | Compound 19 | | |

TABLE VII

| | Organic Dyes | | | | | | | | | | |
|---|---|---|---|---|---|---|---|---|---|---|---|
| | Group A | | | | Group B | Group C | | | | | |
| | A1 | A2 | A3 | A4 | B1 | C1 | C2 | | | | |
| | Amount | Amount | Amount | Amount | Amount | Amount | Amount | | General | | |
| Composition | Added | Added | Added | Added | Added | Added | Added | Phosphonic | Formula | | |
| No. | (mg) | (mg) | (mg) | (mg) | (mg) | (mg) | (mg) | Acid H1 | (I) | D1 | Remarks |
| 27 | — | A2-10 | — | — | — | — | C2-28 | Propylphosphonic | Exemplary | D-3 | Inventive |
| | | 1.5 | | | | | 1.0 | acid | Compound 19 | | |
| 28 | — | — | A3-1 | — | — | — | C2-15 | Propylphosphonic | Exemplary | D-19 | Inventive |
| | | | 1.4 | | | | 1.0 | acid | Compound 72 | | |
| 29 | — | — | A3-11 | — | — | C1-1 | — | Propylphosphonic | Exemplary | D-3 | Inventive |
| | | | 1.4 | | | 0.9 | | acid | Compound 4 | | |
| 30 | — | — | A3-5 | — | — | — | C2-13 | Propylphosphonic | Exemplary | D-19 | Inventive |
| | | | 1.4 | | | | 1.0 | acid | Compound 72 | | |
| 31 | — | — | — | A4-1 | — | — | C2-15 | Propylphosphonic | Exemplary | D-3 | Inventive |
| | | | | 1.8 | | | 0.8 | acid | Compound 72 | | |
| 32 | — | — | — | A4-13 | — | C1-4 | — | Propylphosphonic | Exemplary | D-43 | Inventive |
| | | | | 1.2 | | 0.9 | | acid | Compound 65 | | |
| 33 | — | — | — | A4-2 | — | — | C2-18 | Propylphosphonic | Exemplary | D-19 | Inventive |
| | | | | 1.8 | | | 0.8 | acid | Compound 65 | | |
| 34 | — | — | — | — | B1-3 | C1-1 | — | Propylphosphonic | Exemplary | D-43 | Inventive |
| | | | | | 1.8 | 1.0 | | acid | Compound 42 | | |
| 35 | — | — | — | — | B1-9 | — | C2-23 | Propylphosphonic | Exemplary | D-19 | Inventive |
| | | | | | 1.2 | | 2.0 | acid | Compound 72 | | |
| 36 | A1-1 | — | — | — | — | C1-1 | — | Phenylphosphonic | Exemplary | — | Inventive |
| | 2.0 | | | | | 2.2 | | acid | Compound 72 | | |
| 37 | KAYASORB IRG-022 | | | | | | | Propylphosphonic | Exemplary | — | Comparison |
| | 3.6 | | | | | | | acid | Compound 54 | | |
| 38 | KAYASORB IRG-022 | | | | | | | Propylphosphonic | Exemplary | D-3 | Comparison |
| | 3.6 | | | | | | | acid | Compound 55 | | |
| 39 | A1-1 | — | — | — | — | C1-1 | — | — | — | — | Comparison |
| | 2.0 | | | | | 2.2 | | | | | |

| | | | | | |
|---|---|---|---|---|---|
| 40 | (a-18) and (c-1) described in JP 6331392B | Propylphosphonic | Exemplary | — | Comparison |
| | (a- 18)2.0, (c-1)2.2 | acid | Compound 72 | | |

Evaluation

The produced near-infrared absorbing compositions were subjected to the following measurements and evaluations.

Each of the prepared near-infrared absorbing compositions 1 to 40 was diluted with toluene such that the particle concentration (solid content concentration) of the metal complex was 1.0% by mass, thereby preparing each evaluation sample.

Light Transmittance

For each of the produced samples, the light transmissivity in the range of wavelengths of 450 to 1200 nm was measured by using a spectrophotometer V-780 manufactured by JASCO Corporation Inc, and the average light transmissivity in the range was calculated. The calculated average light transmittances in the wavelength range of 450 to 1200 nm were evaluated according to the following standards. In addition, the wavelength at which the transmittance in the range of 600 to 700 nm of each waveform were 50% was measured and defined as the cutoff wavelength.

Within the range of the wavelength of 450 nm or mom and 600 nm or less:

⊚⊚ (Two double circles): The average light transmittance in the range is 90% or mom.

⊚ (Double circle): The average light transmittance in the range is 88% or mom and less than 90%.

∘ (Circle): The average light transmittance in the range is 85% or mom and less than 88%.

Δ (Triangle): The average light transmittance in the range is 80% or more and less than 85%.

x (Cross mark): The average light transmittance in the range is less than 80%.

Within the range of wavelength of 700 nm to less than 1000 nm:

⊚ (Double circle): The average light transmittance in the range is less than 2%.

∘ (Circle): The average light transmittance in the range is 2% or more and less than 5%.

Δ (Triangle): The average light transmittance in the range is 5% or more and less than 10%.

x (Cross mark): The average light transmittance in the range is 10% or more.

Within the range of wavelength of 1000 nm to 1200 nm, inclusive:

⊚ (Double circle): The average light transmittance in the range is less than 2%.

∘ (Circle): The average light transmittance in the range is 2% or more and less than 5%.

Δ (Triangle): The average light transmittance in the range is 5% or more and less than 10%.

x (Cross mark): The average light transmittance in the range is 10% or more.

The evaluation results of Example 1 are collectively shown in Tables VIII-X together with the evaluation results of Example 2. The solvent was removed from each of the compositions, and the same measurements as described above were performed for a single-layer film. It was confirmed that the same results as in the liquid state were obtained.

### Example 2

Single-Layer Configuration Filter

Each of the near-infrared absorbing compositions 1 to 40 prepared above and a curable resin having a polysiloxane structure (KR-311 manufactured by Shin-Etsu Chemical Corporation) were mixed so that the solid content of the resin becomes 70 mass %, so that coating solutions for forming near-infrared-absorbing films were prepared.

Next, each of the coating liquids for forming a near-infrared-absorbing film was applied onto a glass plate by spin coating (the number of rotations: 300 rpm) to form a coating film. The coating film was prebaked on a hot plate at 50° C. for 60 minute. Next, the coating film was cured by a heating treatment at 150° C. for 2 hours on a hot plate, and thus a near-infrared absorbing filter having a single-layer configuration was produced.

The near-infrared absorbing filters were subjected to the following measurements and evaluations.

Evaluation

Light Resistance

Each of the produced samples was exposed for 120 hours in a xenon fade meter. The light resistance was calculated from the ratio of the reflection spectral densities at the maximum absorption wavelength in the visible region before and after the exposure, and was evaluated based on the following criteria.

Light resistance (%)=(Maximum absorption wavelength concentration of exposed sample/Maximum absorption wavelength concentration of unexposed sample)×100

⊚ (Double circle): The light resistance is 95% or more.

∘ (Circle): The light resistance is 90% or more and less than 95%.

Δ (Triangle): The light resistance is 80% or more and less than 90%.

x (Cross mark): The light resistance is less than 80%.

∘ and ⊚ (Circle and double circle) were evaluated as no problem in practical use.

Heat Resistance

Each of the produced samples was stored under the conditions of 85° C. and 10% RH or lower for 7 days. The heat resistance was calculated from the concentration ratio before and after the storage, and was evaluated based on the following criteria.

Heat resistance (%)=(Concentration after storage/Concentration before start of storage)×100

⊚ (Double circle): Heat resistance is 95% or more.

∘ (Circle): The heat resistance is 80% or mom and less than 95%.

Δ (Triangle): The heat resistance is 60% or more and less than 80%.

x (Cross mark): The heat resistance was less than 60%.

∘ and ∘ (Circle and double circle) were evaluated as no problem in practical use.

The evaluation results of Examples 1 and 2 described above are collectively shown in the following Tables VIII to X.

The average light transmittances and the cutoff wavelengths shown in the tables were measured according to the method and the conditions described in Example 1. The light transmittance shown in Tables VIII to X below was evaluated from the values obtained by correcting reflection on the interface or the like of the glass substrate by the above-described standards.

TABLE VIII

| | Average Light Transmittance | | | Cutoff | | | |
|---|---|---|---|---|---|---|---|
| Composition | 450- | 700- | 1000- | Wavelength | Heat | Light | |
| No. | 600 nm | 1000 nm | 1200 nm | (nm) | Resistance | Resistance | Remarks |
| 1 | ⊚ | ◯ | ◯ | 646 | ⊚ | ◯ | Inventive |
| 2 | ⊚ | Δ | Δ | 646 | ◯ | ◯ | Inventive |
| 3 | ⊚ | ◯ | ◯ | 628 | ◯ | ◯ | Inventive |
| 4 | ◯ | ⊚ | ◯ | 626 | ⊚ | ◯ | Inventive |
| 5 | ⊚⊚ | ⊚ | ◯ | 637 | ⊚ | ◯ | Inventive |
| 6 | ⊚ | ◯ | ◯ | 635 | ◯ | ◯ | Inventive |
| 7 | ⊚ | ◯ | ◯ | 623 | ⊚ | ◯ | Inventive |
| 8 | ⊚ | ◯ | ◯ | 649 | ⊚ | ◯ | Inventive |
| 9 | ⊚ | ⊚ | ◯ | 639 | ⊚ | ◯ | Inventive |
| 10 | ⊚ | ◯ | ◯ | 639 | ◯ | ◯ | Inventive |
| 11 | ⊚ | ◯ | ◯ | 636 | ◯ | ◯ | Inventive |
| 12 | ⊚⊚ | ⊚ | ◯ | 636 | ⊚ | ◯ | Inventive |
| 13 | ⊚ | ⊚ | ◯ | 626 | ⊚ | ◯ | Inventive |

TABLE IX

| | Average Light Transmittance | | | Cutoff | | | |
|---|---|---|---|---|---|---|---|
| Composition | 450- | 700- | 1000- | Wavelength | Heat | Light | |
| No. | 600 nm | 1000 nm | 1200 nm | (nm) | Resistance | Resistance | Remarks |
| 14 | ⊚ | ⊚ | ◯ | 624 | ◯ | ◯ | Inventive |
| 15 | ⊚ | ◯ | Δ | 625 | Δ | ◯ | Inventive |
| 16 | ⊚ | ◯ | ◯ | 628 | ◯ | ◯ | Inventive |
| 17 | ◯ | ⊚ | ◯ | 617 | ⊚ | ◯ | Inventive |
| 18 | ◯ | ⊚ | ◯ | 615 | ◯ | ◯ | Inventive |
| 19 | ⊚ | ⊚ | ◯ | 628 | ⊚ | ◯ | Inventive |
| 20 | ⊚ | ⊚ | ◯ | 626 | ◯ | ⊚ | Inventive |
| 21 | ⊚ | ⊚ | ◯ | 630 | ⊚ | ⊚ | Inventive |
| 22 | ⊚⊚ | ⊚ | ◯ | 628 | ⊚ | ⊚ | Inventive |
| 23 | ◯ | ◯ | ◯ | 640 | ◯ | ⊚ | Inventive |
| 24 | ⊚ | ◯ | ◯ | 634 | ⊚ | ⊚ | Inventive |
| 25 | ⊚ | ◯ | ◯ | 623 | ◯ | ⊚ | Inventive |
| 26 | ◯ | ◯ | ◯ | 630 | ◯ | ◯ | Inventive |

TABLE X

| | Average Light Transmittance | | | Cutoff | | | |
|---|---|---|---|---|---|---|---|
| Composition | 450- | 700- | 1000- | Wavelength | Heat | Light | |
| No. | 600 nm | 1000 nm | 1200 nm | (nm) | Resistance | Resistance | Remarks |
| 27 | ◯ | ◯ | ◯ | 628 | ◯ | ⊚ | Inventive |
| 28 | ⊚ | ⊚ | ◯ | 639 | ⊚ | ⊚ | Inventive |
| 29 | ◯ | ◯ | ◯ | 642 | ⊚ | ◯ | Inventive |
| 30 | ⊚ | ◯ | ◯ | 635 | ⊚ | ⊚ | Inventive |
| 31 | ⊚ | ⊚ | ◯ | 624 | ⊚ | ⊚ | Inventive |
| 32 | ⊚ | ⊚ | ◯ | 628 | ◯ | ⊚ | Inventive |
| 33 | ⊚ | ⊚ | ◯ | 630 | ⊚ | ⊚ | Inventive |
| 34 | ⊚ | ◯ | ◯ | 628 | ◯ | ⊚ | Inventive |
| 35 | ⊚ | ⊚ | ◯ | 628 | ⊚ | ⊚ | Inventive |
| 36 | ◯ | ◯ | Δ | 615 | Δ | ◯ | Inventive |
| 37 | Δ | ◯ | ◯ | 625 | X | X | Comparison |
| 38 | Δ | ◯ | ◯ | 625 | X | Δ | Comparison |
| 39 | ⊚ | X | X | 645 | ◯ | ◯ | Comparison |
| 40 | ⊚ | X | ◯ | 616 | X | Δ | Comparison |

### Example 3

Production And Evaluation of Two-Layer Configuration Filter

A coating liquid for an organic dye-containing layer was prepared as follows. A1-1: 2.00 mg and C1-1: 2.20 mg were added to 36 g of diacetone alcohol, and the mixture was stirred for 1 hour. Polyvinyl butyral (2 g) (S-LEC KS-10 manufactured by Sumitomo Chemical Co., Ltd) was added thereto, and the mixture was stirred for 1 hour. Thereafter, tolylene 2,4-diisocyanate 1 g was further added thereto, and the mixture was further stirred to obtain the coating liquid for the organic dye-containing layer.

The coating liquid for the organic dye-containing layer was applied onto a glass substrate by spin coating (rotation speed: 500 rpm) to form a coating film. The coating film was heated at 140° C. for 60 minutes to cure the coating film, thereby forming the organic dye-containing layer. The thickness of the organic dye-containing layer was about 2 m.

A coating liquid for an intermediate protection layer was prepared as follows. To 11.5 g of ethanol, 2.83 g of glycidoxypropyltrimethoxysilane, 0.11 g of epoxy resin (SR-6GL, manufactured by Hisaka Yakuhin Kogyo Co., Ltd), 5.68 g of tetraethoxysilane, 0.06 g of an ethanol-diluted solution of nitric acid (nitric acid concentration: 10 wt %) and 5.5 g of water were added in this order. The mixture was stirred for about 1 hour to obtain the coating liquid for the intermediate protection layer.

The coating liquid for the intermediate protection layer was applied onto the organic dye-containing layer by spin coating (the number of rotations: 300 rpm) to form a coating film. The coating film was subjected to a heat treatment at 150° C. for 20 minutes to cure the coating film, thereby forming the intermediate protection layer.

As a coating liquid for a copper phosphonate-containing layer, the liquid D before the addition of the organic dyes in the near-infrared absorbing composition 1 of Example 1 can be used, and the liquid D was prepared in the same procedure. Next, the liquid D and a curable resin having a polysiloxane structure (KR-311 manufactured by Shin-Etsu Chemical Corporation) were mixed so that the solid content of the resin became 70 mass %. The coating liquid for the copper phosphonate-containing layer was thus obtained.

The coating liquid for the copper phosphonate-containing layer was applied onto the intermediate protection layer by spin coating (the rotation speed: 300 rpm) to form a coating film. The coating film was prebaked on a hot plate at 50° C. for 60 minutes. Next, the coating film was cured by a heating treatment on a hot plate at 150° C. for 2 hours to produce a near-infrared absorbing filter having a two-layer configuration (not including an intermediate layer).

For the near-infrared absorbing filter, the same measurement and evaluation as in Examples 1 and 2 were performed, and it was confirmed that the same results were obtained.

From the results in Tables VIII to X, the following facts are clear. The near-infrared ray absorbing composition and the near-infrared ray absorbing film of the present invention are excellent in both transparency in the visible light region and absorptivity in the near-infrared region. In addition, the near-infrared absorbing filter produced from the near-infrared absorbing composition of the present invention is excellent in heat resistance over time and furthermore excellent in light resistance.

### INDUSTRIAL APPLICABILITY

The near-infrared absorbing composition of the present invention has both transmittance in the visible light region and absorptivity in the near-infrared region, and is excellent in heat resistance and light resistance over time. In addition, by using the infrared absorbing composition, it is possible to provide a near-infrared absorbing film, a near-infrared absorbing filter, and an image sensor for a solid-state image sensing element, which achieve both transmittance in the visible light region and absorption in the near-infrared region and are excellent in heat resistance and light resistance over time.

### REFERENCE SIGNS LIST

1 Near-infrared absorbing film
2 Copper phosphonate-containing layer
3 Organic dye-containing layer
11 Near-infrared absorbing filter
12 Antireflection film
13 Copper phosphonate-containing layer
14 Intermediate protection layer
15 Organic dye-containing layer
16 Substrate
101 Camera module
102 Adhesive
103 Glass substrate
104 Imaging lens
105 Lens holder
106 Light and electromagnetic shield
107 Adhesive
108 Flattening layer
109 Near-infrared absorbing film (near-infrared absorbing filter)
110 Solid-state imaging element substrate
111 Solder ball
112 Circuit board
113 Imaging element portion

1. A near-infrared absorbing composition comprising an organic dye and a metal compound, wherein
the organic dye includes:
at least one of a squarylium dye (A) or a cyanine dye (B) each having an absorption maximum in a range of 680 to 740 nm, the squarylium dye (A) being a compound having a structure represented by any one of General Formulae (A1) to (A4) (respectively, a dye A1, a dye A2, a dye A3, and a dye A4), the cyanine dye (B) being a compound having a structure represented by the following General Formula (B1) (a dye B1); and
a cyanine dye (C) having an absorption maximum at 760 nm or more, the cyanine dye (C) being a compound having a structure represented by any one of General Formulae (C1) or (C2) (a dye C1 or a dye C2, respectively), and
the metal compound includes at least a phosphonic acid and a copper ion, or a copper phosphonate complex formed from a phosphonic acid and a copper ion,
Squarylium Dye (A) 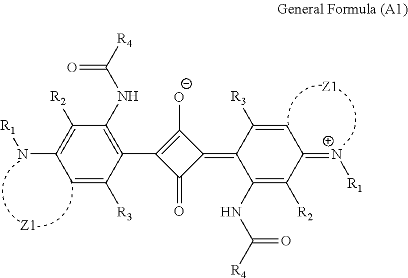
in the formula, R₁ represents an alkyl, aryl, or heterocyclic group; R₂ and R₃ each independently represent a hydrogen atom, a halogen atom, or an alkyl group; R₄ represents an alkyl, alkoxy, aryl or heterocyclic group having 1 to 4 carbon atoms; and Z1 represents an atomic group necessary for forming a 5- or 6-membered ring, 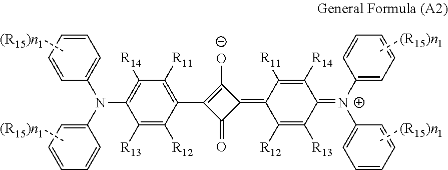
in the formula, R₁₁ and R₁₂ each independently represent a hydrogen atom, a hydroxy group, —NHCOR₁₆, or —NHSO₂R₁₇, and are not hydrogen atoms at the same time; R₁₃ and R₁₄ each independently represent a hydrogen atom, a halogen atom, or an alkyl group; R₁₅ represents a substituent; n₁ represents an integer of 0 to 5; and R₁₆ and R₁₇ each independently represent an alkyl, aryl, or heterocyclic group having 1 to 4 carbon atoms, 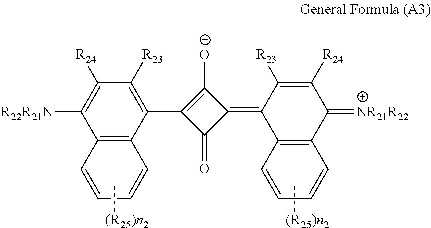
in the formula, R₂₁ and R₂₂ each independently represent a hydrogen atom, an alkyl group, an aryl group, or a heterocyclic group; R₂₃ each independently represents a hydroxy group, —NHCOR₂₆, or —NHSO₂R₂₇; R₂₄ each independently represents a hydrogen atom or a substituent; R₂₅ each independently represents a substituent; n₂ each represents an integer of 0 to 4; and R₂₆ and R₂₇ each independently represent an alkyl, aryl, or heterocyclic group having 1 to 4 carbon atoms, 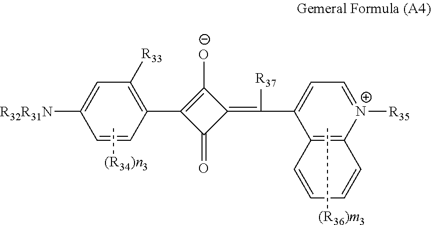
in the formula, R₃₁ and R₃₂ each independently represent a hydrogen atom, an alkyl group, an aryl group, or a heterocyclic group; R₃₃ represents a hydroxy group, —NHCOR₃₈ or —NHSO₂R₃₉; R₃₄ and R₃₆ each independently represent a halogen atom or a substituent; R₃₅ represents an alkyl, aryl or heterocyclic group; n₃ represents an integer of 0 to 3; m₃ represents an integer of 0 to 6; R₃₇ represents a hydrogen atom, a halogen atom, or an alkyl group; and R₃₈ and R₃₉ each independently represent an alkyl, aryl, or heterocyclic group having 1 to 4 carbon atoms,
Cyanine Dye (B) 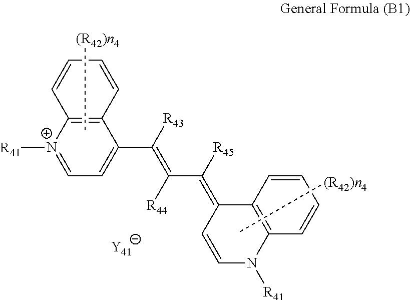
in the formula, R₄₁ each independently represents an alkyl, aryl, or heterocyclic group; R₄₂ each independently represents a halogen atom or a substituent; R₄₃ to R₄₅ each independently represent a hydrogen atom, a halogen atom, an alkyl group, or an aryl group; n₄ each independently represents an integer of 0 to 6; and Y₄₁ represents a halogen ion or an anionic atomic group,
Cyanine Dye (C) 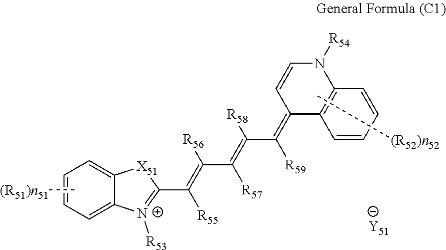
in the formula, R₅₁ and R₅₂ each independently represent a halogen atom or a substituent, and adjacent substituents may form a 5- or 6-membered ring; n₅₁ and n₅₂ represent integers of 0 to 4 and 0 to 5, respectively; R₅₃ and R₅₄ each independently represent an alkyl, aryl, or heterocyclic group; R₅₅ to R₅₉ each independently represent a hydrogen atom, a halogen atom, an alkyl group, an aryl groups, or a heterocyclic group; R₅₅ and R₅₇, R₅₆ and R₅₈, or R₅₇ and R₅₉ may be bound to each other to form a 5- or 6-membered ring; X₅₁ represents —S— or —CR₅₁₁R₅₁₂; Y₅₁ represents an anionic atom or an anionic atomic group; and R₅₁₁ and R₅₁₂ each independently represent a hydrogen atom, an alkyl group, or an aryl group, 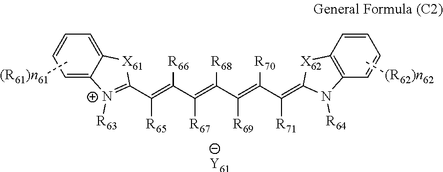
in the formula, R₆₁ and R₆₂ each independently represent a halogen atom or a substituent, and adjacent substituents may form a 5- or 6-membered ring; n₆₁ and n₆₂ each independently represent an integer of 0 to 4; R₆₃ and R₆₄ each independently represent an alkyl group, an aryl group, or a heterocyclic group; R₆₅ to R₇₁ each independently represent a hydrogen atom, a halogen atom, an alkyl group, an aryl group, or a heterocyclic group; R₆₅ and R₆₇, R₆₆ and R₆₈, R₆₇ and R₆₉, R₆₈ and R₇₀, or R₆₉ and R₇₁ may be bound to each other to form a 5- or 6-membered ring; X₆₁ and X₆₂ each independently represent —O—, —S—, or —CR₆₁₁R₆₁₂—; Y₆₁ represents an anionic atom or an anionic atomic group; and R₆₁₁ and R₆₁₂ each independently represent a hydrogen atom or an alkyl group.

2. The near-infrared absorption composition according to claim 1, wherein
the organic dye includes at least a combination of the dye A1 and the dye C2 or a combination of the dye A4 and the dye C2.

3. The near-infrared absorbing composition according to claim 1, wherein
the organic dye a includes at least a combination of the dye B1 and the dye C2.

4. The near-infrared absorbing composition according to claim 1, wherein
the phosphonic acid is an alkylphosphonic acid, and
the metal compound includes a compound having a structure represented by the following general formula (I) and a copper ion, or a copper complex formed from the compound having the structure represented by the following general formula (I) and a copper ion, 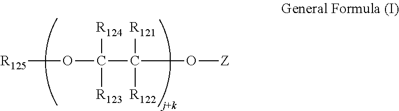
in the General Formula (I), R₁₂₅ represents an alkyl group having 1 to 20 carbon atoms or an aryl group having 6 to 20 carbon atoms; R₁₂₅ may further have a substituent; and Z represents a structural unit selected from the following Formulae (Z-1) or (Z-2), 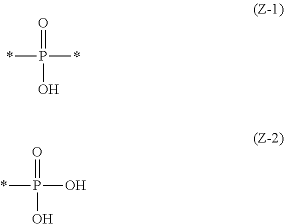
“*” in Formulae (Z-1) and (Z-2) represents a binding site that binds to 0 of General Formula (I);
R₁₂₁ to R₁₂₄ each independently represent a hydrogen atom or an alkyl group having 1 to 4 carbon atoms;
provided that the compound having the structure represented by General Formula (I) simultaneously has at least one moiety satisfying the following Condition (i) and at least one moiety satisfying the following Condition (ii),
Condition (i): R₁₂₁ to R₁₂₄ are all hydrogen atoms, and
Condition (ii): at least one of R₁₂₁ to R₁₂₄ is an alkyl group having 1 to 4 carbon atoms,
in the above General Formula (I), j represents the number of moieties satisfying the above Condition (i), which is a number from 1 to 10; and k represents the number of moieties satisfying the above Condition (ii) and is a number from 1 to 10.

5. The near-infrared absorbing composition according to claim 1, wherein
the metal compound includes a compound having a structure represented by the following General Formula (D1), 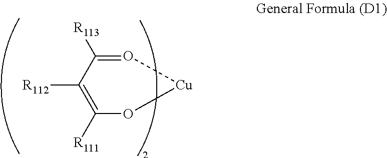
in the formula, R₁₁₁ and R₁₁₃ each independently represent an alkyl, alkoxy, amino, aryl, or heterocyclic group; R₁₁₂ represents a hydrogen or halogen atom, or an alkyl, aryl, heterocyclic, carbonyl or cyano group, each of which may have a substituent.

6. A near-infrared absorbing film, comprising:
the near-infrared absorbing composition according to claim 1.

7. A near-infrared absorbing film, comprising:
an organic dye-containing layer containing an organic dye; and
a copper phosphonate-containing layer containing a phosphonic acid and a copper ion, or a copper phosphonate complex formed from a phosphonic acid and a copper ion, wherein
the organic dye includes:
at least one of a squarylium dye (A) and a cyanine dye (B) each having a maximum absorption wavelength in a range of 680 to 740 nm, the squarylium dye (A) being a compound having a structure represented by any one of General Formulae (A1) to (A4) (respectively, a dye A1, a dye A2, a dye A3, and a dye A4), the cyanine dye (B) being a compound having a structure represented by the following General Formula (B1) (a dye B1); and
a cyanine dye (C) having an absorption maximum wavelength at 760 nm or more, the cyanine dye (C) being a compound having a structure represented by any one of General Formulae (C1) or (C2) (a dye C1 or a dye C2, respectively),
Squarylium Dye (A) 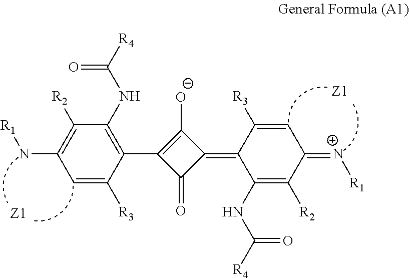
in the formula, R₁ represents an alkyl, aryl, or heterocyclic group; R₂ and R₃ each independently represent a hydrogen atom, a halogen atom, or an alkyl group; R₄ represents an alkyl, alkoxy, aryl or heterocyclic group having 1 to 4 carbon atoms; and Z1 represents an atomic group necessary for forming a 5- or 6-membered ring, 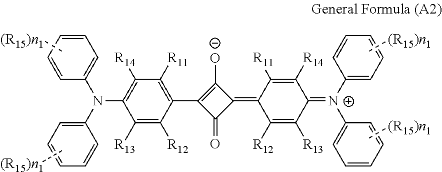
in the formula, R₁₁ and R₁₂ each independently represent a hydrogen atom, a hydroxy group, —NHCOR₁₆, or —NHSO₂R₁₇, and are not hydrogen atoms at the same time; R₁₃ and R₁₄ each independently represent a hydrogen atom, a halogen atom, or an alkyl group; R₁₅ represents a substituent; n₁ represents an integer of 0 to 5; and R₁₆ and R₁₇ each independently represent an alkyl, aryl, or heterocyclic group having 1 to 4 carbon atoms, 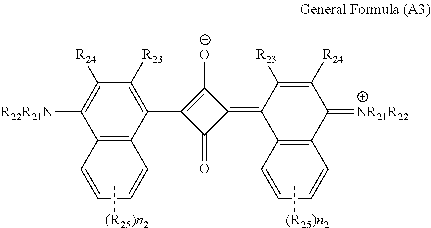
in the formula, R₂₁ and R₂₂ each independently represent a hydrogen atom, an alkyl group, an aryl group, or a heterocyclic group; R₂₃ each independently represents a hydroxy group, —NHCOR₂₆, or —NHSO₂R₂₇; R₂₄ each independently represents a hydrogen atom or a substituent; R₂₅ each independently represents a substituent; n₂ each represents an integer of 0 to 4; and R₂₆ and R₂₇ each independently represent an alkyl, aryl, or heterocyclic group having 1 to 4 carbon atoms, 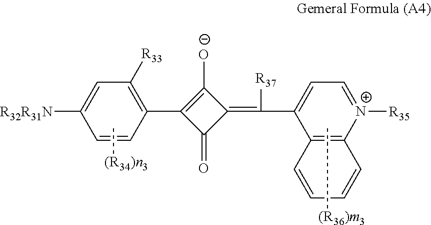
in the formula, R₃₁ and R₃₂ each independently represent a hydrogen atom, an alkyl group, an aryl group, or a heterocyclic group; R₃₃ represents a hydroxy group, —NHCOR₃₈ or —NHSO₂R₃₉; R₃₄ and R₃₆ each independently represent a halogen atom or a substituent; R₃₅ represents an alkyl, aryl or heterocyclic group; n₃ represents an integer of 0 to 3; m₃ represents an integer of 0 to 6; R₃₇ represents a hydrogen atom, a halogen atom, or an alkyl group; and R₃₈ and R₃₉ each independently represent an alkyl, aryl, or heterocyclic group having 1 to 4 carbon atoms,
Cyanine Dye (B) 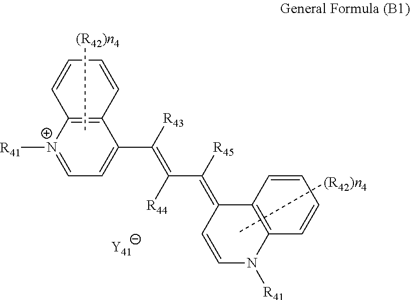
in the formula, R₄₁ each independently represents an alkyl, aryl, or heterocyclic group; R₄₂ each independently represents a halogen atom or a substituent; R₄₃ to R₄₅ each independently represent a hydrogen atom, a halogen atom, an alkyl group, or an aryl group; n₄ each independently represents an integer of 0 to 6; and Y₄₁ represents a halogen ion or an anionic atomic group,
Cyanine Dye (C) 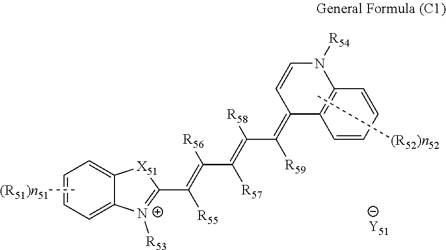
in the formula, R₅₁ and R₅₂ each independently represent a halogen atom or a substituent, and adjacent substituents may form a 5- or 6-membered ring; n₅₁ and n₅₂ represent integers of 0 to 4 and 0 to 5, respectively; R₅₃ and R₅₄ each independently represent an alkyl, aryl, or heterocyclic group; R₅₅ to R₅₉ each independently represent a hydrogen atom, a halogen atom, an alkyl group, an aryl groups, or a heterocyclic group; R₅₅ and R₅₇, R₅₆ and R₅₈, or R₅₇ and R₅₉ may be bound to each other to form a 5- or 6-membered ring; X₅₁ represents —S— or —CR₅₁₁R₅₁₂; Y₅₁ represents an anionic atom or an anionic atomic group; and R₅₁₁ and R₅₁₂ each independently represent a hydrogen atom, an alkyl group, or an aryl group, 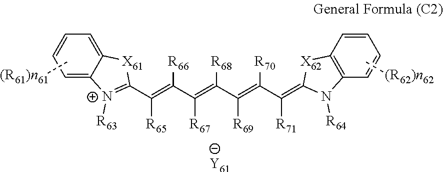
in the formula, R₆₁ and R₆₂ each independently represent a halogen atom or a substituent, and adjacent substituents may form a 5- or 6-membered ring; n₆₁ and n₆₂ each independently represent an integer of 0 to 4; R₆₃ and R₆₄ each independently represent an alkyl group, an aryl group, or a heterocyclic group; R₆₅ to R₇₁ each independently represent a hydrogen atom, a halogen atom, an alkyl group, an aryl group, or a heterocyclic group; R₆₅ and R₆₇, R₆₆ and R₆₈, R₆₇ and R₆₉, R₆₈ and R₇₀, or R₆₉ and R₇₁ may be bound to each other to form a 5- or 6-membered ring; X₆₁ and X₆₂ each independently represent —O—, —S—, or —CR₆₁₁R₆₁₂—; Y₆₁ represents an anionic atom or an anionic atomic group; and R₆₁₁ and R₆₁₂ each independently represent a hydrogen atom or an alkyl group.

8. A near-infrared absorbing filter, comprising:
the near-infrared absorbing film according to claim 6, wherein
the near-infrared absorbing film has a film thickness within a range of 30 to 120 μm, and
the near-infrared absorbing film has a light transmittance that satisfies all of the following Conditions (1) to (4):
(1) an average light transmittance within a wavelength range of 450 nm or more and 600 nm or less being 85% or more;
(2) an average light transmittance within a wavelength range of 700 nm or more and less than 1000 nm being less than 2%;
(3) an average light transmittance within a wavelength range of 1000 nm or more and 1200 nm or less being less than 5%; and
(4) a cutoff wavelength at which the light transmittance is 50% in a wavelength range of 600 to 700 nm being within a range of 620 to 660 nm.

9. An image sensor for a solid-state imaging element, comprising:
the near-infrared absorbing filter according to claim 8.

10. A near-infrared absorbing filter, comprising:
the near-infrared absorbing film according to claim 7, wherein
the near-infrared absorbing film has a film thickness within a range of 30 to 120 μm, and
the near-infrared absorbing film has a light transmittance that satisfies all of the following Conditions (1) to (4):
(1) an average light transmittance within a wavelength range of 450 nm or more and 600 nm or less being 85% or more;
(2) an average light transmittance within a wavelength range of 700 nm or more and less than 1000 nm being less than 2%;
(3) an average light transmittance within a wavelength range of 1000 nm or more and 1200 nm or less being less than 5%; and
(4) a cutoff wavelength at which the light transmittance is 50% in a wavelength range of 600 to 700 nm being within a range of 620 to 660 nm.

11. An image sensor for a solid-state imaging element, comprising:
the near-infrared absorbing filter according to claim 10.
